(19) United States
(12) Patent Application Publication
(10) Pub. No.: US 2020/0393764 A1
(43) Pub. Date: Dec. 17, 2020

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, METHOD FOR MANUFACTURING ELECTRONIC DEVICE, AND POLYESTER

(71) Applicant: FUJIFILM Corporation, Tokyo (JP)

(72) Inventor: Atsuyasu NOZAKI, Haibara-gun (JP)

(73) Assignee: FUJIFILM Corporation, Tokyo (JP)

(21) Appl. No.: 17/004,484

(22) Filed: Aug. 27, 2020

Related U.S. Application Data
(63) Continuation of application No. PCT/JP2019/003846, filed on Feb. 4, 2019.

(30) Foreign Application Priority Data
Mar. 30, 2018 (JP) 2018-070297

(51) Int. Cl. G03F 7/039; C08G 63/682; G03F 7/004; G03F 7/32

(52) U.S. Cl. CPC G03F 7/0392; C08G 63/682; G03F 7/0048; G03F 7/32; G03F 7/0045

(57) ABSTRACT

An actinic ray-sensitive or radiation-sensitive resin composition includes a resin having a group that decomposes by the action of an acid to increase a polarity, a polyester having an acid-decomposable group, and a photoacid generator.

### CROSS-REFERENCE TO RELATED APPLICATIONS

This application is a Continuation of PCT International Application No. PCT/JP2019/003846 filed on Feb. 4, 2019, which claims priority under 35 U.S.C § 119(a) to Japanese Patent Application No. 2018-070297 filed on Mar. 30, 2018. Each of the above application(s) is hereby expressly incorporated by reference, in its entirety, into the present application.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, a method for manufacturing an electronic device, and a polyester.

### 2. Description of the Related Art

Since the advent of a resist for a KrF excimer laser (248 nm), a pattern forming method utilizing chemical amplification has been used in order to compensate for sensitivity reduction due to light absorption. For example, in a positive tone chemical amplification method, first, a photoacid generator included in the exposed area decomposes upon irradiation with light to generate an acid. Then, in a post-exposure baking (PEB) process and the like, an alkali-insoluble group included in a photosensitive composition is changed into an alkali-soluble group by the catalytic action of an acid thus generated. Thereafter, development is performed using, for example, an alkali solution. As a result, the exposed area is removed to obtain a desired pattern.

In the method, as an alkali developer, various types of alkali developers have been proposed. For example, as the alkali developer, a 2.38%-by-mass aqueous alkali developer of tetramethylammonium hydroxide (aqueous TMAH solution) has been generally used.

Miniaturization of a semiconductor device has leaded to a progress in shortening the wavelength of an exposure light source and increasing the numerical aperture (higher NA) of a projection lens, and an exposure machine using an ArF excimer laser having a wavelength of 193 nm as the light source is currently developed. As a technique for further increasing a resolving power, a method in which a space between a projection lens and a sample is filled with a high-refractive-index liquid (hereinafter sometimes referred to as an “immersion liquid”) (that is, a liquid immersion method) has been advocated.

For example, JP2012-242800A describes a positive tone resist composition containing a resin having a solubility increased in an alkali developer by the action of an acid, a photoacid generator, and a repeating unit derived from an acrylic ester, in which the repeating unit includes a fluorine atom.

JP2017-090674A describes a positive tone resist composition containing a resin having a solubility increased in an alkali developer by the action of an acid, a photoacid generator, and a polymer which includes a linking group which is hydrolyzed by the action of the alkali developer in the main chain and has a fluorine atom.

### SUMMARY OF THE INVENTION

In recent years, along with a demand for improving the productivity of various electronic devices, there has been a demand for forming an intended resist pattern in a shorter period of time also in the formation of a resist pattern.

Therefore, the present inventors have considered improvement of a scanning speed in an exposing step using a liquid immersion exposure apparatus as one of methods for shortening a time for forming a resist pattern, and have thus found that it is very difficult to suppress various defects and improve line-width roughness (LWR) performance while maintaining a high followability of an immersion liquid to an exposure apparatus in a case where the scanning speed for exposure is ultrahigh.

It is an object of the present invention to provide an actinic ray-sensitive or radiation-sensitive resin composition which has a high followability of an immersion liquid (typically ultrapure water) to an exposure apparatus during exposure (that is, has a large dynamic receding contact angle of an actinic ray-sensitive or radiation-sensitive film with respect to water) even in a case where the scanning speed for exposure is ultrahigh (for example, 700 mm/sec or more), can increase the hydrophilicity of the film after post-exposure baking (that is, can decrease the dynamic receding contact angle of the film with respect to water after post-exposure baking), and has reduced development defects and excellent LWR performance; an actinic ray-sensitive or radiation-sensitive film, a pattern forming method, and a method for manufacturing an electronic device, each using the actinic ray-sensitive or radiation-sensitive resin composition; and a polyester which can be used in the actinic ray-sensitive or radiation-sensitive resin composition.

Since the related art, a resist composition including a resin having a repeating unit derived from an acrylic ester, in which the repeating unit includes a fluorine atom, as an additive polymer in a resist composition (also referred to as an “acrylic fluorine-containing resin”) has been known, as in JP2012-242800A. It is known that since the acrylic fluorine-containing resin is unevenly distributed on the surface of the resist film, it is possible to increase a dynamic receding contact angle (also referred to as a “DRCA”) of water in the resist film, as compared with a case where the acrylic fluorine-containing resin is not added.

In the present invention, it has been found that by allowing the resist composition to contain a polyester, it is possible to further increase the DRCA as compared with a case where the acrylic fluorine-containing resin is used. A reason therefor is presumed to be that in a case where a resin (also referred to as an “acrylic resin”) having a repeating unit derived from a (meth)acrylic ester is used as the resin (A), the polyester has high separability from the acrylic resin (it easily undergoes phase separation), it is more easily unevenly distributed on the surface of a film than the acrylic fluorine-containing resin, and a high DRCA can be obtained even with a small addition amount.

Furthermore, the present inventors have found that a resist film formed of the above-mentioned positive tone resist composition including a polymer (polyester) which includes a linking group to be hydrolyzed by the action of an alkali developer in the main chain and has a fluorine atom in JP2017-090674A may improve DRCA in some cases, as compared with a resist film including the above-mentioned acrylic fluorine-containing resin, whereas in a case where development is performed with an alkali developer, there are problems such as a high occurrence of defects and deterioration in LWR performance.

A reason therefor is considered to be that by enhancing the hydrophobicity of the resist film (water repellency) by the addition of the polyester to the resist composition, the DRCA is improved and the water followability during liquid immersion exposure is improved, whereas in a case where the hydrophobicity of the resist film in the exposed area remains high even after post-exposure baking, the affinity for the alkali developer is low and thus, defects easily occur in the resist pattern after development. In particular, in a case of a positive tone resist composition, the defects easily occur in the unexposed area. As one means for suppressing the defects, a method of making the surface hydrophilic after liquid immersion exposure and baking is considered. That is, in order to solve the above-mentioned problems, it is important to provide a technique for making the surface hydrophobic (water-repellent) during liquid immersion exposure, while making the surface hydrophilic during development.

Moreover, the amount of a resin (also referred to as an “additive polymer”) remaining in the resist film, in which the resin is used to make the film surface hydrophobic, increases in proportion to the addition amount. Since the remaining additive polymer has high water repellency, it is considered that as the additive polymer remains on the surface of the resist pattern, the larger the residual amount, the worse the LWR. Therefore, it is considered that the LWR can be enhanced by lowering the addition amount of the additive polymer. In addition, it is considered that in a case where the additive polymer has a high affinity for an alkali developer during development, it is easily removed during development, and thus, the LWR can be enhanced.

Since the polyester (B) of the present invention has an acid-decomposable group (that is, it is acid-decomposable), it decomposes by an acid generated from a photoacid generator after post-exposure baking in the exposed area, the affinity for an alkali developer the solution increases, and defects are less likely to occur during alkali development. This can be confirmed by a phenomenon that DRCA which was high before the exposure is lowered after the post-exposure baking.

In addition, since the polyester (B) of the embodiment of the present invention is acid-decomposable, it decomposes by the acid generated from a photoacid generator after post-exposure baking in the exposed area, the affinity for an alkali developer the solution increases and the polyester (B) is easily removed during alkali development, and thus, the LWR performance is excellent.

That is, the present inventors have found that the problems can be solved by the following configurations.

[1] An actinic ray-sensitive or radiation-sensitive resin composition comprising:

(A) a resin having a group that decomposes by the action of an acid to increase a polarity;

(B) a polyester having an acid-decomposable group; and

(C) a photoacid generator.

[2] The actinic ray-sensitive or radiation-sensitive resin composition as described in [1],

in which a content of the polyester (B) is from 0.1% by mass to 15% by mass with respect to a total solid content of the actinic ray-sensitive or radiation-sensitive resin composition.

[3] The actinic ray-sensitive or radiation-sensitive resin composition as described in [1] or [2],

in which the polyester (B) has at least one group represented by any of General Formulae (RZ-1) to (RZ-4).

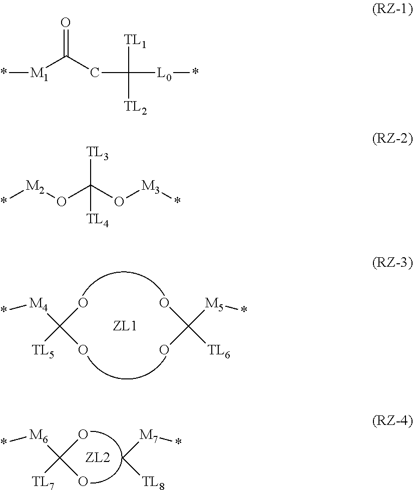

In General Formula (RZ-1), M₁ represents a single bond or a divalent linking group, TL₁ and TL₂ each independently represent a hydrogen atom, an alkyl group, a cycloalkyl group, an aryl group, or a halogen atom, and TL₁ and TL₂ may be bonded to each other to form a ring. L₀ represents a single bond or an alkylene group. L₀ and any one of TL₁ or TL₂ may be bonded to each other to form a ring. * represents a bonding position.

In General Formula (RZ-2), M₂ and M₃ each independently represent a single bond or a divalent linking group, TL₃ and TL₄ each independently represent a hydrogen atom, an alkyl group, a cycloalkyl group, or an aryl group, and TL₃ and TL₄ may be bonded to each other to form a ring. * represents a bonding position.

In General Formula (RZ-3), M₄ and M₅ each independently represent a single bond or a divalent linking group, and TL₅ and TL₆ each independently represent a hydrogen atom, an alkyl group, a cycloalkyl group, an aryl group, or a halogen atom. ZL1 represents a ring structure. ZL1 may represent a spirocyclic structure. * represents a bonding position.

In General Formula (RZ-4), M₆ and M₇ each independently represent a single bond or a divalent linking group, and TL₇ and TL₈ each independently represent a hydrogen atom, an alkyl group, a cycloalkyl group, an aryl group, or a halogen atom. ZL2 represents a ring structure. ZL2 may represent a spirocyclic structure. * represents a bonding position.

[4] The actinic ray-sensitive or radiation-sensitive resin composition as described in any one of [1] to [3],

in which the polyester (B) has at least one group represented by any of General Formulae (QZ-1) to (QZ-4).

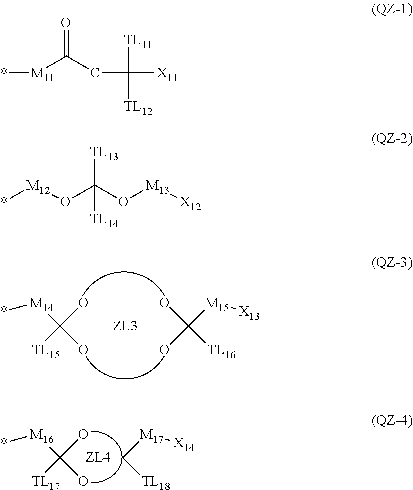

In General Formula (QZ-1), M₁₁ represents a single bond or a divalent linking group, TL₁₁ and TL₁₂ each independently represent a hydrogen atom, an alkyl group, a cycloalkyl group, an aryl group, or a halogen atom, and TL₁₁ and TL₁₂ may be bonded to each other to form a ring. X₁₁ represents a hydrogen atom, a halogen atom, or a monovalent organic group. X₁₁ may be bonded to at least one of TL₁₁ or TL₁₂ to form a ring. * represents a bonding position.

In General Formula (QZ-2), M₁₂ and M₁₃ each independently represent a single bond or a divalent linking group, TL₁₃ and TL₁₄ each independently represent a hydrogen atom, an alkyl group, a cycloalkyl group, or an aryl group, and TL₁₃ and TL₁₄ may be bonded to each other to form a ring. X₁₂ represents a hydrogen atom, a halogen atom, or a monovalent organic group. X₁₂ may be bonded to at least one of TL₁₃ or TL₁₄ to form a ring. * represents a bonding position.

In General Formula (QZ-3), M₁₄ and M₁₅ each independently represent a single bond or a divalent linking group, and TL₁₅ and TL₁₆ each independently represent a hydrogen atom, an alkyl group, a cycloalkyl group, an aryl group, or a halogen atom. ZL3 represents a ring structure. ZL3 may represent a spirocyclic structure. X₁₃ represents a hydrogen atom, a halogen atom, or a monovalent organic group. * represents a bonding position.

In General Formula (QZ-4), M₁₆ and M₁₇ each independently represent a single bond or a divalent linking group, and TL₁₇ and T₁₈ each independently represent a hydrogen atom, an alkyl group, a cycloalkyl group, an aryl group, or a halogen atom. ZL4 represents a ring structure. ZL4 may represent a spirocyclic structure. X₁₄ represents a hydrogen atom, a halogen atom, or a monovalent organic group. * represents a bonding position.

[5] The actinic ray-sensitive or radiation-sensitive resin composition as described in any one of [1] to [4],

in which the polyester (B) has a group represented by General Formula (EZ-1) in a side chain.

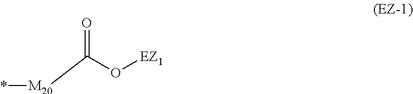

In General Formula (EZ-1), M₂₀ represents a single bond or a divalent linking group, and EZ₁ represents a monovalent organic group having an electron-withdrawing property.

[6] The actinic ray-sensitive or radiation-sensitive resin composition as described in any one of [1] to [5],

in which the polyester (B) is represented by General Formula (1).

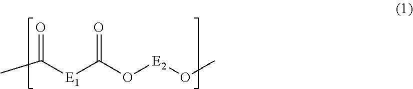

In General Formula (1), E₁ and E₂ each independently represent a chained aliphatic group which may include a heteroatom, an alicyclic group which may include a heteroatom, an aromatic group, or a group formed by combination thereof.

[7] The actinic ray-sensitive or radiation-sensitive resin composition as described in [6],

in which E₁ and E₂ in General Formula (1) are each independently a group represented by any of General Formulae (1a) to (1e).

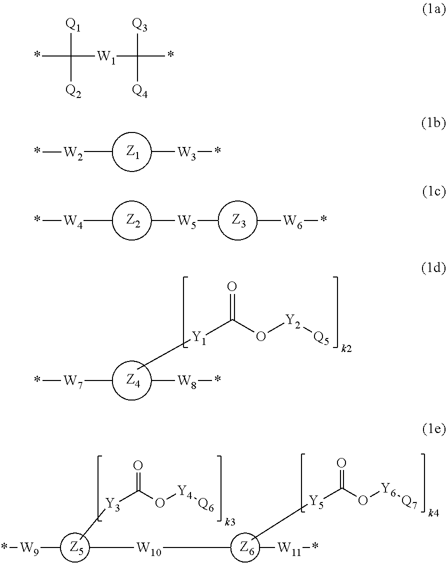

In General Formula (1a), Q₁ to Q₄ each independently represent a hydrogen atom, a halogen atom, or an alkyl group, and W₁ represents a single bond, an alkylene group, or a cycloalkylene group.

In General Formula (1b), W₂ and W₃ each independently represent a single bond, an alkylene group, or a cycloalkylene group, and Z₁ represents a cycloalkylene group, a spirocyclic group which may include a heteroatom, or an arylene group.

In General Formula (1c), W₄, W₅, and W₆ each independently represent a single bond, an alkylene group, or a cycloalkylene group, and Z₂ and Z₃ each independently represent a cycloalkylene group, a spirocyclic group which may include a heteroatom, or an arylene group.

In General Formula (1d), W₇ and W₈ each independently represent a single bond, an alkylene group, or a cycloalkylene group, Z₄ represents a cycloalkylene group, a spirocyclic group which may include a heteroatom, or an arylene group, Y₁ and Y₂ each independently represent a single bond or a divalent linking group, Q₅ represents a hydrogen atom, an alkyl group, a cycloalkyl group, or an aryl group, and k2 represents an integer of 1 or more. In a case where k2 represents an integer of 2 or more, a plurality of Y₁'s, a plurality of Y₂'s, and a plurality of Q₅'s may be the same as or different from each other.

In General Formula (1e), W₉, W₁₀, and W₁₁ each independently represent a single bond, an alkylene group, or a cycloalkylene group, Z₅ and Z₆ each independently represent a cycloalkylene group, a spirocyclic group which may include a heteroatom, or an arylene group, Y₃, Y₄, Y₅, and Y₆ each independently represent a single bond or a divalent linking group, Q₆ and Q₇ each independently represent a hydrogen atom, an alkyl group, a cycloalkyl group, or an aryl group, and k3 and k4 each independently represent an integer of 1 or more. In a case where k3 represents an integer of 2 or more, a plurality of Y₃'s, a plurality of Y₄'s, and a plurality of Q₆'s may be the same as or different from each other. In a case where k4 represents an integer of 2 or more, a plurality of Y₅'s, a plurality of Y₆'s, and a plurality of Q₇'s may be the same as or different from each other.

[8] The actinic ray-sensitive or radiation-sensitive resin composition as described in any one of [1] to [7],

in which the polyester (B) contains a fluorine atom.

[9] An actinic ray-sensitive or radiation-sensitive film formed of the actinic ray-sensitive or radiation-sensitive resin composition as described in any one of [1] to [8].

[10] A pattern forming method comprising:

a step of forming an actinic ray-sensitive or radiation-sensitive film with the actinic ray-sensitive or radiation-sensitive resin composition as described in [1] to [8];

a step of irradiating the actinic ray-sensitive or radiation-sensitive film with actinic rays or radiation; and

a step of developing the actinic ray-sensitive or radiation-sensitive film irradiated with the actinic rays or radiation using a developer.

[11] The pattern forming method as described in [10],

in which the developer is an alkali developer or a developer including an organic solvent.

[12] A method for manufacturing an electronic device, comprising the pattern forming method as described in [10] or [11].

[13] A polyester comprising at least one group represented by any of General Formulae (RZ-1) to (RZ-4).

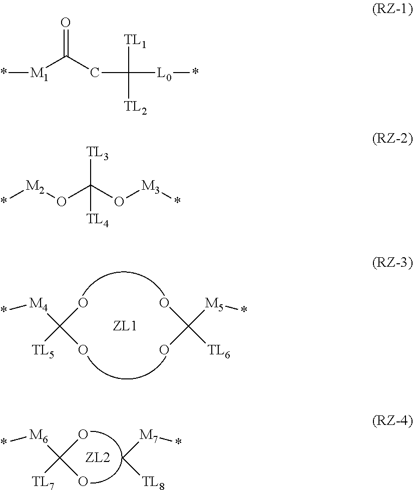

In General Formula (RZ-1), M₁ represents an oxygen atom, CR^{Z1}R^{Z2} or NR^{Z3}, R^{Z1}, R^{Z2}, and R^{Z3} each independently represent a hydrogen atom, an alkyl group, or a halogen atom, and R^{Z1} and R^{Z2} may be bonded to each other to form a ring. TL₁ and TL₂ each independently represent a hydrogen atom, an alkyl group, a cycloalkyl group, an aryl group, or a halogen atom, and TL₁ and TL₂ may be bonded to each other to form a ring. L₀ represents a single bond or an alkylene group. L₀ and any one of TL₁ or TL₂ may be bonded to each other to form a ring. * represents a bonding position.

In General Formula (RZ-2), M₂ and M₃ each independently represent a single bond or a divalent linking group, TL₃ and TL₄ each independently represent a hydrogen atom, an alkyl group, a cycloalkyl group, or an aryl group, and TL₃ and TL₄ may be bonded to each other to form a ring. * represents a bonding position.

In General Formula (RZ-3), M₄ and M₅ each independently represent a single bond or a divalent linking group, and TL₅ and TL₆ each independently represent a hydrogen atom, an alkyl group, a cycloalkyl group, an aryl group, or a halogen atom. ZL1 represents a ring structure. ZL1 may represent a spirocyclic structure. * represents a bonding position.

In General Formula (RZ-4), M₆ and M₇ each independently represent a single bond or a divalent linking group, and TL₇ and TL₈ each independently represent a hydrogen atom, an alkyl group, a cycloalkyl group, an aryl group, or a halogen atom. ZL2 represents a ring structure. ZL2 may represent a spirocyclic structure. * represents a bonding position. [14] A polyester having at least one group represented by any of General Formula (QZ-1) to (QZ-4).

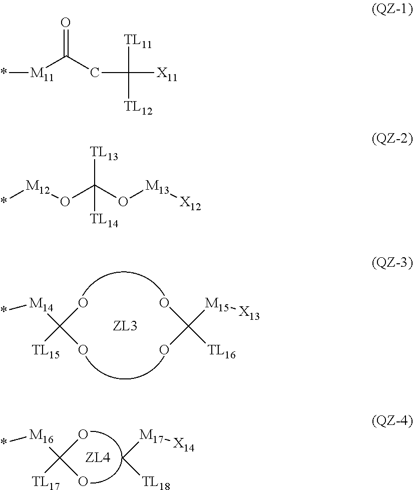

In General Formula (QZ-1), X₁₀ represents a single bond or a divalent linking group, M₁₁ represents an oxygen atom, CR^{Z4}R^{Z5}, or NR²⁶, and R^{Z4}, R^{Z5}, and R^{Z6} each independently represent a hydrogen atom, an alkyl group, or a halogen atom, and R^{Z4} and R^{Z5} may be bonded to each other to form a ring. TL₁₁ and TL₁₂ each independently represent a hydrogen atom, an alkyl group, a cycloalkyl group, an aryl group, or a halogen atom, and TL₁₁ and TL₁₂ may be bonded to each other to form a ring. X₁₁ represents a hydrogen atom, a halogen atom, or a monovalent organic group. X₁₁ may be bonded to at least one of TL₁₁ or TL₁₂ to form a ring. * represents a bonding position.

In General Formula (QZ-2), M₁₂ and M₁₃ each independently represent a single bond or a divalent linking group, TL₁₃ and TL₁₄ each independently represent a hydrogen atom, an alkyl group, a cycloalkyl group, or an aryl group, and TL₁₃ and TL₁₄ may be bonded to each other to form a ring. X₁₂ represents a hydrogen atom, a halogen atom, or a monovalent organic group. X₁₂ may be bonded to at least one of TL₁₃ or TL₁₄ to form a ring. * represents a bonding position.

In General Formula (QZ-3), M₁₄ and M₁₅ each independently represent a single bond or a divalent linking group, and TL₁₅ and TL₁₆ each independently represent a hydrogen atom, an alkyl group, a cycloalkyl group, an aryl group, or a halogen atom. ZL3 represents a ring structure. ZL3 may represent a spirocyclic structure. X₁₃ represents a hydrogen atom, a halogen atom, or a monovalent organic group. * represents a bonding position.

In General Formula (QZ-4), M₁₆ and M₁₇ each independently represent a single bond or a divalent linking group, and TL₁₇ and TL₁₈ each independently represent a hydrogen atom, an alkyl group, a cycloalkyl group, an aryl group, or a halogen atom. ZL4 represents a ring structure. ZL4 may represent a spirocyclic structure. X₁₄ represents a hydrogen atom, a halogen atom, or a monovalent organic group. * represents a bonding position.

[15] A polyester having a group represented by General Formula (EZ-1) in a side chain.

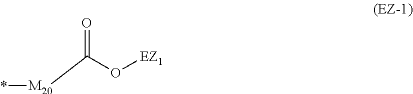

In General Formula (EZ-1), M₂₀ represents a single bond or a divalent linking group, and EZ₁ represents a monovalent organic group having an electron-withdrawing property.

According to the present invention, it is possible to provide an actinic ray-sensitive or radiation-sensitive resin composition which has a high followability of an immersion liquid (typically ultrapure water) to an exposure apparatus during exposure (that is, having a large dynamic receding contact angle of an actinic ray-sensitive or radiation-sensitive film with respect to water) even in a case where a scanning speed for exposure is ultrahigh (for example, 700 mm/sec or more), can increase the hydrophilicity of a film after post-exposure baking (that is, decrease the dynamic receding contact angle of the film with respect to water after post-exposure baking), and has reduced development defects and excellent LWR performance; an actinic ray-sensitive or radiation-sensitive film, a pattern forming method, and a method for manufacturing an electronic device, each using the actinic ray-sensitive or radiation-sensitive resin composition; and a polyester which can be used in the actinic ray-sensitive or radiation-sensitive resin composition.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

In citations for a group (atomic group) in the present specification, in a case where the group is cited without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

“Actinic rays” or “radiation” in the present specification means, for example, a bright line spectrum of a mercury lamp, far ultraviolet rays typified by an excimer laser, extreme ultraviolet rays (EUV light), X-rays, electron beams (EB), or the like. “Light” in the present specification means actinic rays or radiation.

Unless otherwise specified, “exposure” in the present specification encompasses not only exposure by a bright line spectrum of a mercury lamp, far ultraviolet rays typified by an excimer laser, extreme ultraviolet rays, X-rays, EUV, or the like, but also lithography by particle rays such as electron beams and ion beams.

In the present specification, a numerical range expressed using “to” is used in a meaning of a range that includes the preceding and succeeding numerical values of “to” as the lower limit value and the upper limit value, respectively.

In the present specification, (meth)acrylate represents acrylate and methacrylate, and (meth)acryl represents acryl and methacryl.

In the present specification, the weight-average molecular weight (Mw), the number-average molecular weight (Mn), and the dispersity (also referred to as a molecular weight distribution) (Mw/Mn) of a resin are each defined as a value converted in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, detector: differential refractive index detector) using a GPC apparatus (HLC-8120 GPC manufactured by Tosoh Corporation).

[Actinic Ray-Sensitive or Radiation-Sensitive Resin Composition]

The actinic ray-sensitive or radiation-sensitive resin composition of an embodiment of the present invention (hereinafter also simply referred to as the “composition of the embodiment of the present invention”) will be described.

The composition of the embodiment of the present invention includes (A) a resin having a group that decomposes by the action of an acid to increase a polarity, (B) a polyester, and (C) a photoacid generator.

The actinic ray-sensitive or radiation-sensitive resin composition of the embodiment of the present invention is preferably a resist composition, and may be either a positive resist composition or a negative resist composition. In addition, the composition may be either a resist composition for alkali development or a resist composition for organic solvent development.

The resist composition of the embodiment of the present invention is typically a chemically amplified resist composition.

Hereinafter, the components included in the actinic ray-sensitive or radiation-sensitive resin composition of the embodiment of the present invention will be described in detail.

<Resin (A)>

The actinic ray-sensitive or radiation-sensitive resin composition of the embodiment of the present invention contains a resin (hereinafter also referred to as an “acid-decomposable resin” or a resin (A)) having a group (hereinafter also referred to as an “acid-decomposable group”) that decomposes by the action of an acid to increase a polarity.

In this case, in the pattern forming method of an embodiment of the present invention which will be described later, typically, in a case where an alkali developer is adopted as the developer, a positive tone pattern is suitably formed, and in a case where an organic developer is adopted as the developer, a negative tone pattern is suitably formed.

The resin (A) preferably has a repeating unit having an acid-decomposable group.

The resin (A) is preferably a polymer obtained by polymerizing monomers having an ethylenically unsaturated double bond.

As the resin (A), a known resin can be appropriately used. For example, the known resins disclosed in paragraphs <0055> to <0191> of the specification of US2016/0274458A1, paragraphs <0035> to <0085> of the specification of US2015/0004544A1, and paragraphs <0045> to <0090> of the specification of US2016/0147150A1 can be suitably used as the resin (A).

The acid-decomposable group preferably has a structure in which a polar group is protected with a group (leaving group) that leaves through decomposition by the action of an acid.

Examples of the polar group include an acidic group (a group which dissociates in a 2.38%-by-mass aqueous tetramethylammonium hydroxide solution), such as a carboxyl group, a phenolic hydroxyl group, a fluorinated alcohol group, a sulfonic acid group, a sulfonamido group, a sulfonylimido group, an (alkylsulfonyl)(alkylcarbonyl)methylene group, an (alkyl sulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, and an alcoholic hydroxyl group.

Moreover, the alcoholic hydroxyl group refers to a hydroxyl group bonded to a hydrocarbon group, which is a hydroxyl group other than a hydroxyl group (phenolic hydroxyl group) directly bonded to an aromatic ring, from which an aliphatic alcohol (for example, a hexafluoroisopropanol group) having the α-position substituted with an electron-withdrawing group such as a fluorine atom is excluded as a hydroxyl group. The alcoholic hydroxyl group is preferably a hydroxyl group having an acid dissociation constant (pKa) from 12 to 20.

Preferred examples of the polar group include a carboxyl group, a phenolic hydroxyl group, a fluorinated alcohol group (preferably a hexafluoroisopropanol group), and a sulfonic acid group.

The group which is preferable as the acid-decomposable group is a group in which a hydrogen atom is substituted with a group (leaving group) that leaves by the action of an acid.

Examples of the group (leaving group) that leaves by the action of an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently an alkyl group, a cycloalkyl group, an aryl group, an aralkyl group, or an alkenyl group. R₃₆ and R₃₇ may be bonded to each other to form a ring.

R₀ₗ and R₀₂ each independently represent a hydrogen atom, an alkyl group, a cycloalkyl group, an aryl group, an aralkyl group, or an alkenyl group.

As the alkyl group as each of R₃₆ to R₃₉, R₀₁, and R₀₂, an alkyl group having 1 to 8 carbon atoms is preferable, and examples thereof include a methyl group, an ethyl group, a propyl group, an n-butyl group, a sec-butyl group, a hexyl group, and an octyl group.

The cycloalkyl group as each of R₃₆ to R₃₉, R₀₁, and R₀₂ may be either monocyclic or polycyclic. As the monocyclic group, a cycloalkyl group having 3 to 8 carbon atoms is preferable, and examples thereof include a cyclopropyl group, a cyclobutyl group, a cyclopentyl group, a cyclohexyl group, and a cyclooctyl group. As the polycyclic group, a cycloalkyl group having 6 to 20 carbon atoms is preferable, and examples thereof include an adamantyl group, a norbornyl group, an isobornyl group, a camphanyl group, a dicyclopentyl group, an α-pinel group, a tricyclodecanyl group, a tetracyclododecyl group, and an androstanyl group. Further, at least one carbon atom in the cycloalkyl group may be substituted with a heteroatom such as an oxygen atom.

The aryl group as each of R₃₆ to R₃₉, R₀₁, and R₀₂ is preferably an aryl group having 6 to 10 carbon atoms, and examples thereof include a phenyl group, a naphthyl group, and an anthryl group.

As the aralkyl group of each of R₃₆ to R₃₉, R₀₁, and R₀₂, an aralkyl group having 7 to 12 carbon atoms is preferable, and examples thereof include a benzyl group, a phenethyl group, and a naphthylmethyl group.

As the alkenyl group of each of R₃₆ to R₃₉, R₀₁, and R₀₂, an alkenyl group having 2 to 8 carbon atoms is preferable, and examples thereof include a vinyl group, an allyl group, a butenyl group, and a cyclohexenyl group.

The ring formed by the mutual bonding of R₃₆ and R₃₇ is preferably a (monocyclic or polycyclic) cycloalkyl group. As the cycloalkyl group, a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group are preferable.

As the acid-decomposable group, a cumyl ester group, an enol ester group, an acetal ester group, a tertiary alkyl ester group, or the like is preferable, and the acetal ester group or the tertiary alkyl ester group is more preferable.

The resin (A) preferably has a repeating unit represented by General Formula (AI) as a repeating unit having an acid-decomposable group.

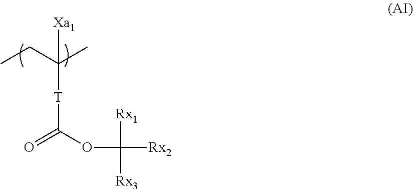

In General Formula (AI),

Xa₁ represents a hydrogen atom, a halogen atom, or a monovalent organic group.

T represents a single bond or a divalent linking group.

Rx₁ to Rx₃ each independently represent an alkyl group or a cycloalkyl group.

Any two of Rx₁, . . . , or Rx₃ may or may not be bonded to each other to form a ring structure.

Examples of the divalent linking group of T include an alkylene group, an arylene group, —COO-Rt-, and —O-Rt-. In the formulae, Rt represents an alkylene group, a cycloalkylene group, or an arylene group.

T is preferably the single bond or —COO-Rt-. Rt is preferably a chained alkylene group having 1 to 5 carbon atoms, and more preferably —CH₂—, —(CH₂)₂—, or —(CH₂)₃—. T is more preferably a single bond.

Xa₁ is preferably a hydrogen atom or an alkyl group.

The alkyl group of Xa₁ may have a substituent, and examples of the substituent include a hydroxyl group and a halogen atom (preferably a fluorine atom).

The alkyl group of Xa₁ preferably has 1 to 4 carbon atoms, and examples thereof include a methyl group, an ethyl group, a propyl group, a hydroxymethyl group, and a trifluoromethyl group. The alkyl group of Xa₁ is preferably a methyl group.

The alkyl group of each of Rx₁, Rx₂, and Rx₃ may be linear or branched, and is preferably a methyl group, an ethyl group, an n-propyl group, an isopropyl group, an n-butyl group, an isobutyl group, a t-butyl group, or the like. The alkyl group preferably has 1 to 10 carbon atoms, more preferably has 1 to 5 carbon atoms, and still more preferably has 1 to 3 carbon atoms. In the alkyl groups of each of Rx₁, Rx₂, and Rx₃, a part of carbon-carbon bonds may be a double bond.

As the cycloalkyl group of each of Rx₁, Rx₂, and Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As a ring structure formed by the bonding of two of Rx₁, Rx₂, and Rx₃, a monocyclic cycloalkane ring such as a cyclopentyl ring, a cyclohexyl ring, a cycloheptyl ring, and a cyclooctane ring, or a polycyclic cycloalkyl ring such as a norbornane ring, a tetracyclodecane ring, a tetracyclododecane ring, and an adamantane ring is preferable. The cyclopentyl ring, the cyclohexyl ring, or the adamantane ring is more preferable. As the ring structure formed by the bonding of two of Rx₁, Rx₂, and Rx₃, the structures shown below are also preferable.

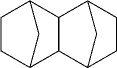 [SMILES: C1CC2CC1C1C3CCC(C3)C21]

Specific examples of a monomer corresponding to the repeating unit represented by General Formula (AI) are shown below, but the present invention is not limited to these specific examples. The following specific examples correspond to the case where Xa₁ in General Formula (AI) is a methyl group, but Xa₁ can be optionally substituted with a hydrogen atom, a halogen atom, or a monovalent organic group.

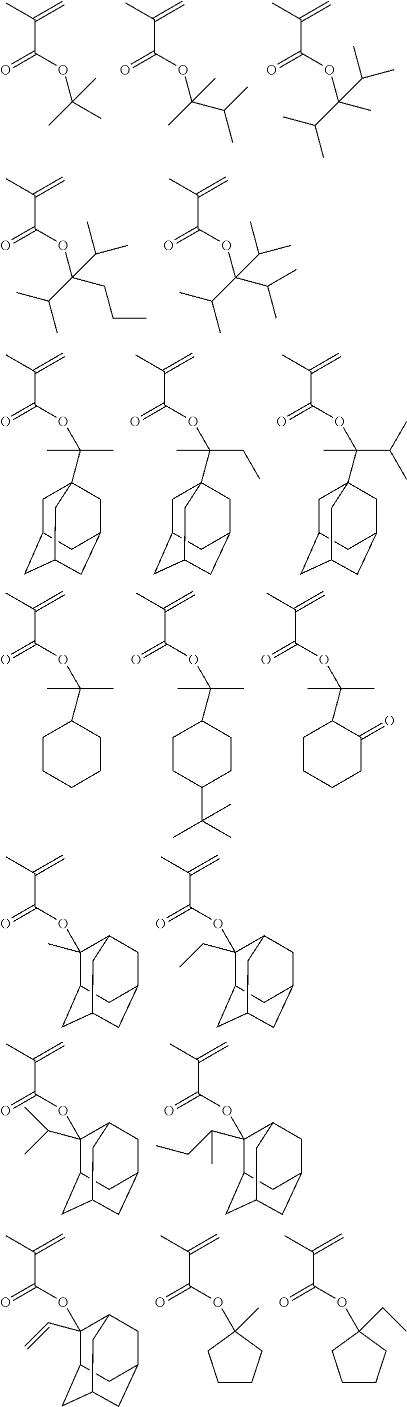

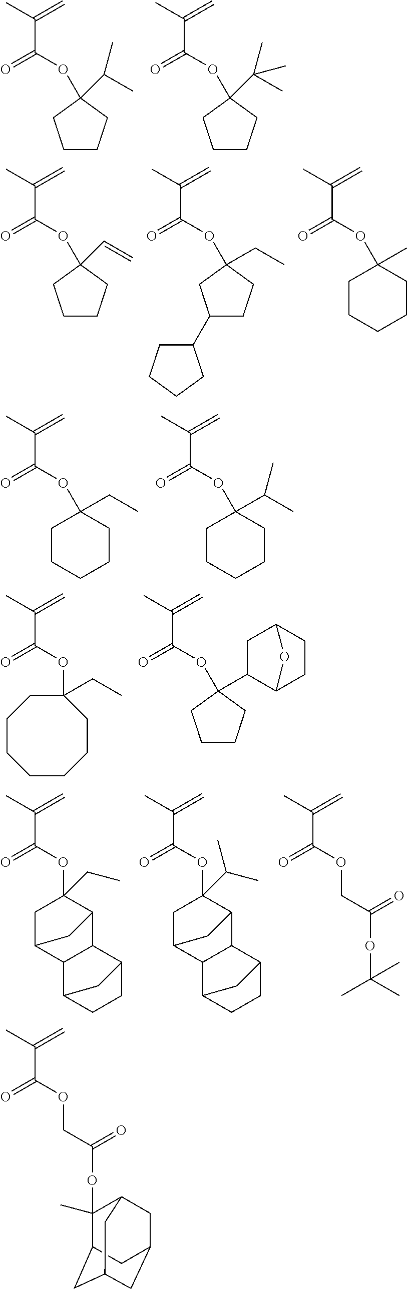

It is also preferable that the resin (A) has the repeating unit described in paragraphs <0336> to <0369> of the specification of US2016/0070167A1 as the repeating unit having an acid-decomposable group.

Furthermore, the resin (A) may have a repeating unit including a group that decomposes by the action of an acid to produce an alcoholic hydroxyl group described in paragraphs <0363> and <0364> of the specification of US2016/0070167A1 as a repeating unit having an acid-decomposable group.

The resin (A) may include repeating units having an acid-decomposable group singly or in combination of two or more kinds thereof.

A content of the repeating unit having an acid-decomposable group included in the resin (A) (in a case where the repeating units having an acid-decomposable group are present in a plural number, a total content thereof) is preferably 10% to 90% by mole, more preferably 20% to 80% by mole, and still more preferably 30% to 70% by mole, with respect to all the repeating units of the resin (A).

The resin (A) preferably has a repeating unit having at least one selected from the group consisting of a lactone structure, a sultone structure, and a carbonate structure.

As the lactone structure or the sultone structure, any one having a lactone structure or a sultone structure can be used, but the lactone structure or the sultone structure is preferably a 5- to 7-membered ring lactone structure or a 5- to 7-membered ring sultone structure, and more preferably a 5- to 7-membered ring lactone structure to which another ring structure is fused so as to form a bicyclo structure or a spiro structure, or a 5- to 7-membered ring sultone structure to which another ring structure is fused so as to form a bicyclo structure or a spiro structure. A repeating unit having a lactone structure represented by any of General Formulae (LC1-1) to (LC1-21) or a sultone structure represented by any of General Formulae (SL1-1) to (SL1-3) is more preferably contained. Further, a lactone structure or sultone structure may be bonded directly to the main chain. Preferred structures are (LC1-1), (LC1-4), (LC1-5), (LC1-8), (LC1-16), (LC1-21), and (SL1-1).

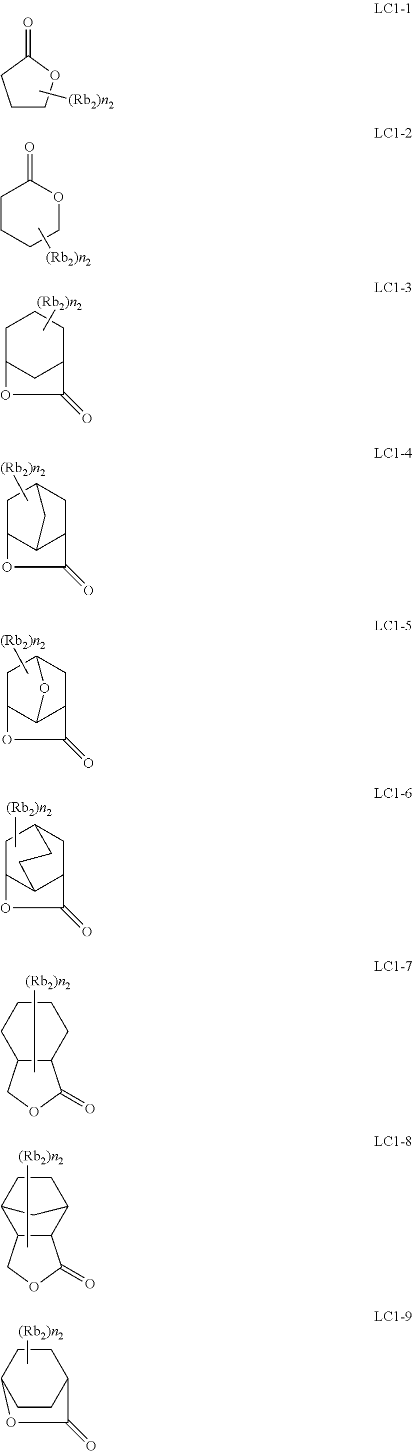

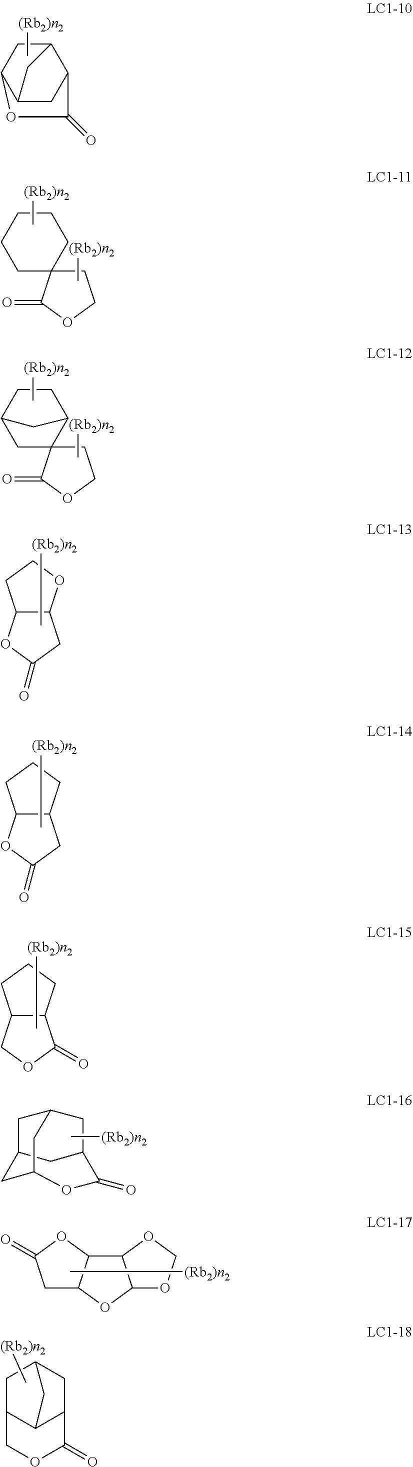

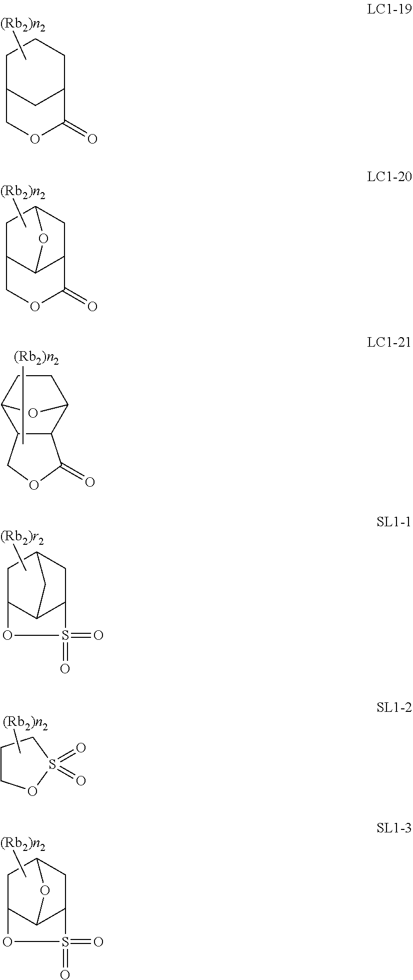

The lactone structural portion or the sultone structural portion may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. More preferred examples thereof are an alkyl group having 1 to 4 carbon atoms, a cyano group, and an acid-decomposable group. n₂ represents an integer of 0 to 4. In a case where n₂ is 2 or more, the substituents (Rb₂) which are present in a plural number may be the same as or different from each other. Further, the substituents (Rb₂) which are present in a plural number may be bonded to each other to form a ring.

The repeating unit having a lactone structure or sultone structure is preferably a repeating unit represented by General Formula (III).

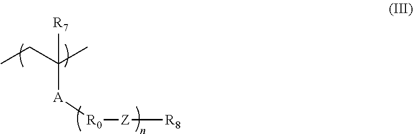

In General Formula (III),

A represents an ester bond (a group represented by —COO—) or an amide bond (a group represented by —CONH—).

n is the number of repetitions of the structure represented by —R₀—Z—, represents an integer of 0 to 5, and is preferably 0 or 1, and more preferably 0. In a case where n is 0, —R₀—Z— is not present and a single bond is formed.

R₀ represents an alkylene group, a cycloalkylene group, or a combination thereof. In a case where R₀'s are present in a plural number, R₀'s each independently represent an alkylene group, a cycloalkylene group, or a combination thereof.

Z represents a single bond, an ether bond, an ester bond, an amide bond, a urethane bond, or a urea bond. In a case where Z's are present in a plural number, Z's each independently represent a single bond, an ether bond, an ester bond, an amide bond, a urethane bond, or a urea bond.

R₈ represents a monovalent organic group having a lactone structure or sultone structure.

R₇ represents a hydrogen atom, a halogen atom, or a monovalent organic group (preferably a methyl group).

The alkylene group or the cycloalkylene group of R₀ may have a substituent.

Z is preferably an ether bond or an ester bond, and more preferably an ester bond.

Specific examples of a monomer corresponding to the repeating unit represented by General Formula (III) and specific examples of a monomer corresponding to the repeating unit represented by General Formula (A-1) are shown below, but the present invention is not limited to such specific examples. The following specific examples correspond to a case where R₇ in General Formula (III) and R_{A}¹ in General Formula (A-1) are each a methyl group, but R₇ and R_{A}¹ can be optionally substituted with a hydrogen atom, a halogen atom, or a monovalent organic group.

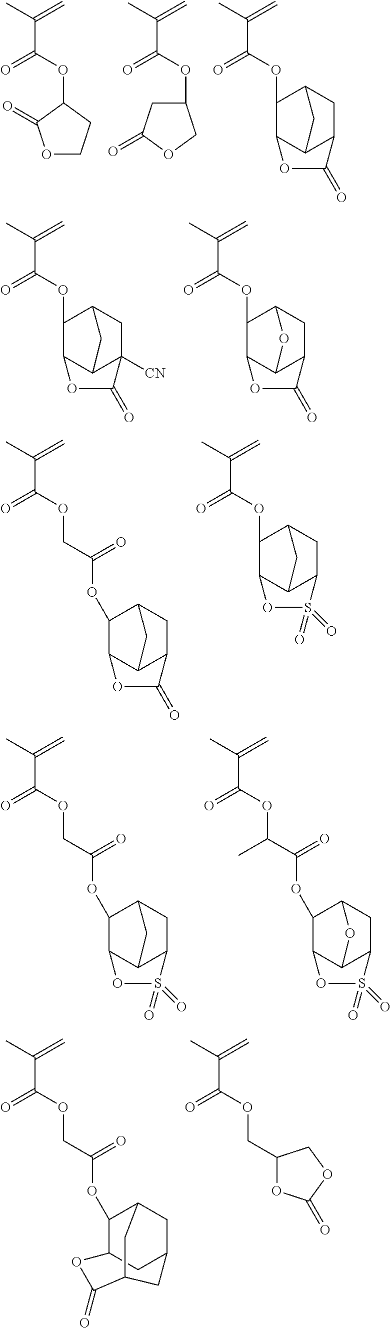

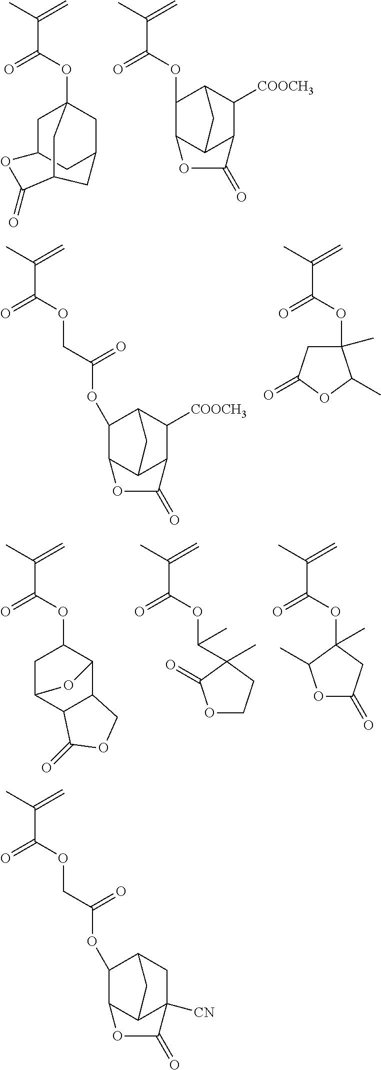

In addition to the monomers, monomers shown below are also suitably used as a raw material for the resin (A).

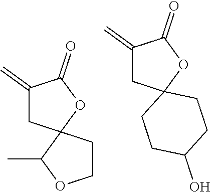

The resin (A) may have a repeating unit having a carbonate structure. The carbonate structure is preferably a cyclic carbonate structure.

The repeating unit having a cyclic carbonate structure is preferably a repeating unit represented by General Formula (A-1).

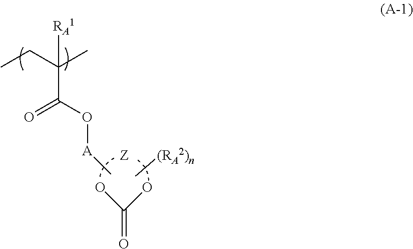

In General Formula (A-1), R_{A}¹ represents a hydrogen atom, a halogen atom, or a monovalent organic group (preferably a methyl group).

n represents an integer of 0 or more.

R_{A}² represents a substituent. In a case where n is 2 or more, R_{A}²'s each independently represent a substituent.

A represents a single bond or a divalent linking group.

Z represents an atomic group that forms a monocyclic or polycyclic structure together with the group represented by —O—C(═O)—O— in the formula.

The resin (A) preferably includes the repeating unit described in paragraphs <0370> to <0414> of the specification of US2016/0070167A1 as a repeating unit having at least one selected from the group consisting of a lactone structure, a sultone structure, and a carbonate structure.

The resin (A) may include only one kind of a repeating unit having at least one selected from the group consisting of a lactone structure, a sultone structure, and a carbonate structure, or two or more kinds of the repeating units in combination may be used.

A content of the repeating unit having at least one type selected from the group consisting of a lactone structure, a sultone structure, and a carbonate structure included in the resin (A) (in a case where the repeating units having at least one selected from the group consisting of a lactone structure, a sultone structure, and a carbonate structure are present in a plural number, a total content thereof) is preferably 5% to 70% by mole, more preferably 10% to 65% by mole, and still more preferably 20% to 60% by mole, with respect to all the repeating units in the resin (A).

The resin (A) preferably has a repeating unit having a polar group.

Examples of the polar group include a hydroxyl group, a cyano group, a carboxyl group, and a fluorinated alcohol group.

The repeating unit having a polar group is preferably a repeating unit having an alicyclic hydrocarbon structure substituted with a polar group. Further, the repeating unit having a polar group preferably does not have an acid-decomposable group. The alicyclic hydrocarbon structure in the alicyclic hydrocarbon structure substituted with a polar group is preferably an adamantyl group or a norbornane group.

Specific examples of a monomer corresponding to the repeating unit having a polar group are shown below, but the present invention is not limited to these specific examples.

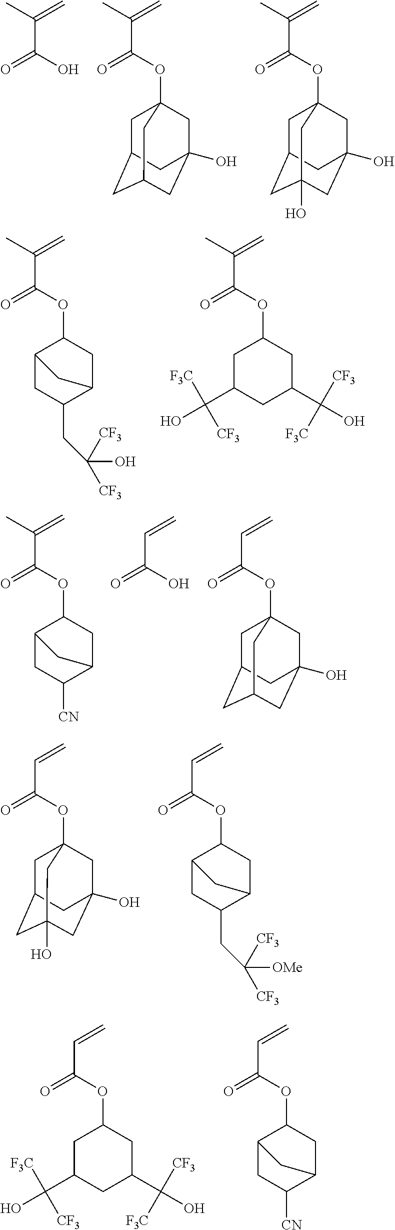

In addition to these, specific examples of the repeating unit having a polar group include the repeating units disclosed in paragraphs <0415> to <0433> of the specification of US2016/0070167A1.

The resin (A) may include the repeating unit having a polar group singly or in combination of two or more kinds thereof.

A content of the repeating unit having a polar group is preferably 5% to 40% by mole, more preferably 5% to 30% by mole, and still more preferably 10% to 25% by mole, with respect to all the repeating units in the resin (A).

The resin (A) can further have a repeating unit having neither an acid-decomposable group nor a polar group. The repeating unit having neither an acid-decomposable group nor a polar group preferably has an alicyclic hydrocarbon structure. Examples of the repeating unit having neither an acid-decomposable group nor a polar group include the repeating units described in paragraphs <0236> and <0237> of the specification of US2016/0026083A1. Preferred examples of a monomer corresponding to the repeating unit having neither an acid-decomposable group nor a polar group are shown below.

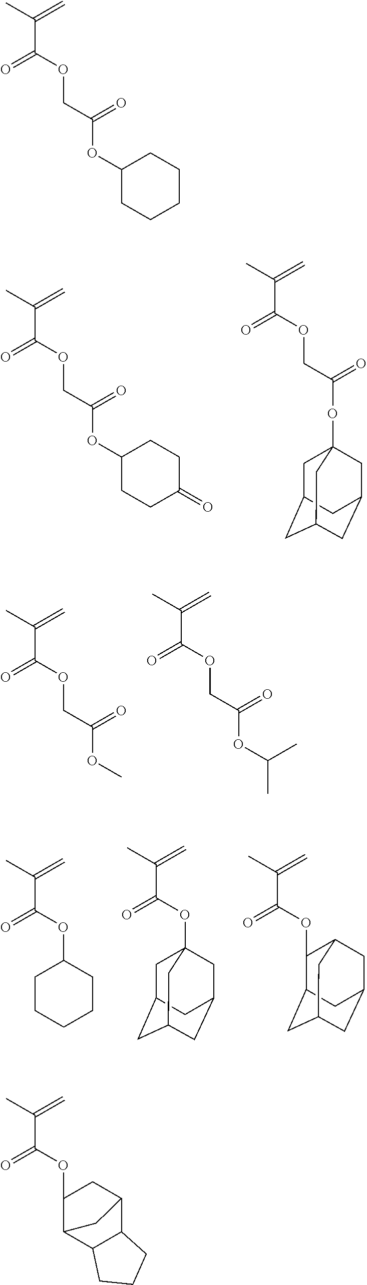

In addition to these, specific examples of the repeating unit having neither an acid-decomposable group nor a polar group include the repeating unit disclosed in paragraph <0433> of the specification of US2016/0070167A1.

The resin (A) may include only one kind of the repeating units having neither an acid-decomposable group nor a polar group, or may include two or more kinds thereof in combination.

A content of the repeating unit having neither an acid-decomposable group nor a polar group is preferably 5% to 40% by mole, more preferably 5% to 30% by mole, and still more preferably 5% to 25% by mole, with respect to all the repeating units in the resin (A).

The resin (A) may have a variety of repeating structural units, in addition to the above-mentioned repeating structural units, for the purpose of adjusting dry etching resistance, suitability for a standard developer, adhesiveness to a substrate, and a resist profile, and resolving power, heat resistance, sensitivity, and the like which are general characteristics required for a resist. Examples of such a repeating structural unit include a repeating structural unit corresponding to a monomer, but are not limited thereto.

Examples of the monomer include a compound having one addition-polymerizable unsaturated bond, selected from acrylic esters, methacrylic esters, acrylamides, methacrylamides, allyl compounds, vinyl ethers, and vinyl esters.

In addition to these, any of addition-polymerizable unsaturated compounds that are copolymerizable with a monomer corresponding to the various repeating structural units may be copolymerized.

In the resin (A), a content molar ratio of each repeating structural unit is appropriately set in order to adjust various performances.

In a case where the composition of the embodiment of the present invention is for ArF exposure, it is preferable that the resin (A) does not substantially have an aromatic group from the viewpoint of permeability of ArF light. More specifically, the repeating unit having an aromatic group is preferably 5% by mole or less, more preferably 3% by mole or less, and ideally 0% by mole in all the repeating units in the resin (A), that is, it is still more preferable that the repeating unit having an aromatic group is not included. In addition, the resin (A) preferably has a monocyclic or polycyclic alicyclic hydrocarbon structure.

In the resin (A), all the repeating units are preferably constituted with (meth)acrylate-based repeating units. In this case, any of a resin in which all of the repeating units are methacrylate-based repeating units, a resin in which all of the repeating units are acrylate-based repeating units, and a resin in which all of the repeating units are methacrylate-based repeating units and acrylate-based repeating units can be used, but it is preferable that the amount of the acrylate-based repeating units is 50% by mole or less with respect to all the repeating units of the resin (A).

In a case where the composition of the embodiment of the present invention is for KrF exposure, EB exposure, or EUV exposure, it is preferable that the resin (A) includes a repeating unit having an aromatic hydrocarbon group. It is more preferable that the resin (A) includes a repeating unit including a phenolic hydroxyl group. Examples of the repeating unit including a phenolic hydroxyl group include a hydroxystyrene repeating unit and a hydroxystyrene (meth)acrylate repeating unit.

In a case where the composition of the embodiment of the present invention is for KrF exposure, EB exposure, or EUV exposure, it is preferable that the resin (A) has a structure in which a hydrogen atom of the phenolic hydroxyl group is protected with a group (leaving group) that leaves through decomposition by the action of an acid.

A content of the repeating unit having an aromatic hydrocarbon group included in the resin (A) is preferably 30% to 100% by mole, more preferably 40% to 100% by mole, and still more preferably 50% to 100% by mole, with respect to all the repeating units in the resin (A).

The weight-average molecular weight of the resin (A) is preferably 1,000 to 200,000, more preferably 2,000 to 20,000, still more preferably 3,000 to 15,000, and particularly preferably 3,000 to 11,000. The dispersity (Mw/Mn) is usually 1.0 to 3.0, preferably 1.0 to 2.6, more preferably 1.0 to 2.0, and still more preferably 1.1 to 2.0.

The resin (A) may be used singly or in combination of two or more kinds thereof.

A content of the resin (A) in the total solid content of the composition of the embodiment of the present invention is generally 20% by mass or more. The content is preferably 40% by mass or more, more preferably 60% by mass or more, and still more preferably 80% by mass or more. An upper limit thereof is not particularly limited, but is preferably 99.5% by mass or less, more preferably 99% by mass or less, and still more preferably 97% by mass or less.

<(B) Polyester Having Acid-Decomposable Group>

The composition of the embodiment of the present invention contains (B) a polyester having an acid-decomposable group (also referred to as “a polyester (B)” or “(B) a component”).

As described above, since the polyester (B) of the embodiment of the present invention has an acid-decomposable group, the composition of the embodiment of the present invention has a high followability of an immersion liquid (typically ultrapure water) to an exposure apparatus during exposure (that is, having a large dynamic receding contact angle of an actinic ray-sensitive or radiation-sensitive film with respect to water) even in a case where a scanning speed for exposure is ultrahigh (for example, 700 mm/sec or more), and allows the polyester (B) to decompose by an acid generated from the photoacid generator during development to increase the hydrophilicity, leading to an increase in the hydrophilicity of an actinic ray-sensitive or radiation-sensitive film (that is, a decrease in the dynamic receding contact angle of the actinic ray-sensitive or radiation-sensitive film with respect to water), and has excellent LWR performance.

The polyester as the component (B) in the present invention is a polymer having an ester bond in the main chain. That is, the polyester as the component (B) in the present invention is not a polymer having an ester bond in a side chain of a polymer (for example, an acrylic resin) obtained by polymerizing monomers having an ethylenically unsaturated double bond.

Furthermore, the polyester as the component (B) in the present invention is a component which is different from the above-mentioned resin (A).

It is preferable that the polyester as the component (B) in the present invention is not a surfactant. The polyester (B) may have a carboxylate or sulfonate structure, or may not have the carboxylate or sulfonate structure. In addition, it is preferable that the polyester (B) does not have a nonionic hydrophilic group such as an ethyleneoxy group and a propyleneoxy group.

The acid-decomposable group is a group that decomposes by the action of an acid to increase a polarity. Examples of the acid-decomposable group include those described for the above-mentioned resin (A).

The polyester (B) may have an acid-decomposable group in the main chain, may have an acid-decomposable group in a side chain, or may have an acid-decomposable group in the main chain and the side chain.

As the polyester (B), a polyester having a structure represented by Formula (P1) is preferable.

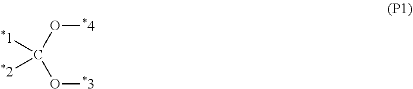

In Formula (P1), * 1 to *4 each represent a bonding position.

The polyester (B) preferably has at least one group represented by any of General Formulae (RZ-1) to (RZ-4).

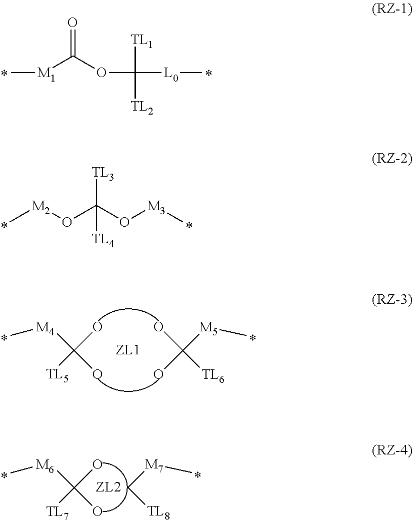

In General Formula (RZ-1), M₁ represents a single bond or a divalent linking group, TL₁ and TL₂ each independently represent a hydrogen atom, an alkyl group, a cycloalkyl group, an aryl group, or a halogen atom, and TL₁ and TL₂ may be bonded to each other to form a ring. L₀ represents a single bond or an alkylene group. L₀ and any one of TL₁ or TL₂ may be bonded to each other to form a ring. * represents a bonding position.

In General Formula (RZ-2), M₂ and M₃ each independently represent a single bond or a divalent linking group, TL₃ and TL₄ each independently represent a hydrogen atom, an alkyl group, a cycloalkyl group, or an aryl group, and TL₃ and TL₄ may be bonded to each other to form a ring. * represents a bonding position.

In General Formula (RZ-3), M₄ and M₅ each independently represent a single bond or a divalent linking group, and TL₅ and TL₆ each independently represent a hydrogen atom, an alkyl group, a cycloalkyl group, an aryl group, or a halogen atom. ZL1 represents a ring structure. ZL1 may represent a spirocyclic structure. * represents a bonding position.

In General Formula (RZ-4), M₆ and M₇ each independently represent a single bond or a divalent linking group, and TL₇ and TL₈ each independently represent a hydrogen atom, an alkyl group, a cycloalkyl group, an aryl group, or a halogen atom. ZL2 represents a ring structure. ZL2 may represent a spirocyclic structure. * represents a bonding position.

In General Formula (RZ-1), M₁ represents a single bond or a divalent linking group. In a case where M₁ represents a divalent linking group, it is preferable that M₁ represents an oxygen atom, an alkylene group, a cycloalkylene group, CR^{Z1}R^{Z2}, NR^{Z3}, or a divalent linking group formed by combination therefore, R^{Z1}, R^{Z2}, and R^{Z3} each Independently represent a hydrogen atom, an alkyl group, or a halogen atom, and R^{Z1} and R^{Z2} may be bonded to each other to form a ring.

The alkylene group as M₁ is preferably an alkylene group having 1 to 20 carbon atoms, and more preferably an alkylene group having 1 to 10 carbon atoms.

The alkylene group as M₁ may have a substituent, and preferred examples of the substituent include a cycloalkyl group, an alkyloxycarbonyl group, a fluoroalkyloxycarbonyl group, or a halogen atom.

The cycloalkylene group as M₁ is preferably a cycloalkylene group having 3 to 20 carbon atoms, and more preferably a cycloalkylene group having 4 to 15 carbon atoms.

The cycloalkylene group as M₁ may have a substituent, and preferred examples of the substituent include an alkyl group, an alkyloxycarbonyl group, a fluoroalkyloxycarbonyl group, or a halogen atom.

In a case where R^{Z1}, R^{Z2}, and R^{Z3} each represent the alkyl group, an alkyl group having 1 to 10 carbon atoms is preferable, and an alkyl group having 1 to 6 carbon atoms is more preferable.

The alkyl group as each of R^{Z1}, R^{Z2}, and R^{Z3} may have a substituent, and preferred examples of the substituent include a cycloalkyl group, an alkyloxycarbonyl group, a fluoroalkyloxycarbonyl group, and a halogen atom.

In a case where R^{Z1}, R^{Z2}, and R^{Z3} each represent the halogen atom, a fluorine atom, a chlorine atom, a bromine atom, or an iodine atom is preferable, and the fluorine atom is more preferable.

In General Formula (RZ-1), TL₁ and TL₂ each independently represent a hydrogen atom, an alkyl group, a cycloalkyl group, an aryl group, or a halogen atom, and TL₁ and TL₂ may be bonded to each other to form a ring.

The alkyl group as each of TL₁ and TL₂ is preferably an alkyl group having 1 to 20 carbon atoms, and more preferably an alkyl group having 1 to 10 carbon atoms.

The alkyl group as each of TL₁ and TL₂ may have a substituent, and preferred examples of the substituent include a cycloalkyl group and a halogen atom.

The cycloalkyl group as each of TL₁ and TL₂ is preferably a cycloalkyl group having 3 to 20 carbon atoms, and more preferably a cycloalkyl group having 4 to 15 carbon atoms.

The cycloalkyl group as each of TL₁ and TL₂ may have a substituent, and preferred examples of the substituent include an alkyl group and a halogen atom.

The aryl group as each of TL₁ and TL₂ is preferably an aryl group having 6 to 20 carbon atoms, and more preferably an aryl group having 6 to 15 carbon atoms.

The aryl group as each of TL₁ and TL₂ may have a substituent, and preferred examples of the substituent include an alkyl group and a halogen atom.

The halogen atom as each of TL₁ and TL₂ is preferably a fluorine atom, a chlorine atom, a bromine atom, or an iodine atom, and more preferably the fluorine atom.

TL₁ and TL₂ may be bonded to each other to form a ring, and the ring formed is preferably a cycloalkane ring (preferably having 3 to 10 carbon atoms).

In General Formula (RZ-1), L₀ represents a single bond or an alkylene group. L₀ and any one of TL₁ or TL₂ may be bonded to each other to form a ring.

The alkylene group as L₀ is preferably an alkylene group having 1 to 20 carbon atoms, and more preferably an alkylene group having 1 to 10 carbon atoms.

The alkylene group as L₀ may have a substituent, and preferred examples of the substituent include a cycloalkyl group, an alkyloxycarbonyl group, a fluoroalkyloxycarbonyl group, and a halogen atom.

L₀ and any one of TL₁ or TL₂ may be bonded to each other to form a ring, and the formed ring is preferably a cycloalkane ring (preferably having 3 to 10 carbon atoms).

In General Formula (RZ-2), M₂ and M₃ each represent a single bond or a divalent linking group. The detailed description of the preferred range and the like in a case where M₂ and M₃ each represent a divalent linking group is the same as that of M₁ in General Formula (RZ-1).

In General Formula (RZ-2), TL₃ and TL₄ each independently represent a hydrogen atom, an alkyl group, a cycloalkyl group, or an aryl group, and TL₃ and TL₄ may be bonded to each other to form a ring. The detailed description of the preferred ranges of TL₃ and TL₄ is the same as that of TL₁ and TL₂ in General Formula (RZ-1).

In General Formula (RZ-3), M₄ and M₅ each represent a single bond or a divalent linking group. The detailed description of the preferred range and the like in a case where M₄ and M₅ each represent a divalent linking group is the same as that of M₁ in General Formula (RZ-1).

In General Formula (RZ-3), TL₅ and TL₆ each independently represent a hydrogen atom, an alkyl group, a cycloalkyl group, an aryl group, or a halogen atom. The detailed description of the preferred ranges of TL₅ and TL₆ is the same as that of TL₁ and TL₂ in General Formula (RZ-1).

In General Formula (RZ-3), ZL1 represents a ring structure. ZL1 preferably represents a spirocyclic structure.

The group represented by General Formula (RZ-3) is preferably a group represented by General Formula (RZ-3-1).

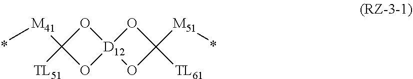

In General Formula (RZ-3-1), M₄₁ and M₅₁ each independently represent a single bond or a divalent linking group, and TL₅₁ and TL₆₁ each independently represent a hydrogen atom, an alkyl group, a cycloalkyl group, an aryl group, or a halogen atom. D₁₂ represents a carbon atom or a tetravalent hydrocarbon group. * represents a bonding position.

In General Formula (RZ-3-1), the detailed description of the preferred ranges of M₄₁, M₅₁, TL₅₁, and TL₆₁ is the same as that of M₄, M₅, TL₅, and TL₆ in General Formula (RZ-3).

In General Formula (RZ-3-1), D₁₂ represents a carbon atom or a tetravalent hydrocarbon group, and preferably a carbon atom or a hydrocarbon group having 2 to 10 carbon atoms.

In General Formula (RZ-4), M₆ and M7 represent a single bond or a divalent linking group. The detailed description of the preferred range and the like in a case where M₆ and M₇ each represent a divalent linking group is the same as that of M₁ in General Formula (RZ-1).

In General Formula (RZ-4), TL₇ and TL₈ each independently represent a hydrogen atom, an alkyl group, a cycloalkyl group, an aryl group, or a halogen atom. The detailed description of the preferred ranges of TL₇ and TL₈ is the same as that of TL₁ and TL₂ in General Formula (RZ-1).

The group represented by General Formula (RZ-4) is preferably a group represented by General Formula (RZ-4-1).

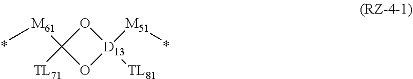

In General Formula (RZ-4-1), M₆₁ and M₇₁ each independently represent a single bond or a divalent linking group, and TL₇₁ and TL₈₁ each independently represent a hydrogen atom, an alkyl group, a cycloalkyl group, an aryl group, or a halogen atom. D₁₃ represents a carbon atom or a tetravalent hydrocarbon group. * represents a bonding position.

The detailed description of the preferred ranges of M₆₁, M₇₁, TL₇₁, and TL₈₁ in General Formula (RZ-4-1) is the same as that of M₄, M₅, TL₅, and TL₆ in General Formula (RZ-3).

In General Formula (RZ-4-1), D₁₃ represents a carbon atom or a tetravalent hydrocarbon group, and preferably a carbon atom or a hydrocarbon group having 2 to 10 carbon atoms.

It is also preferable that the polyester (B) has at least one group represented by any of General Formulae (QZ-1) to (QZ-4).

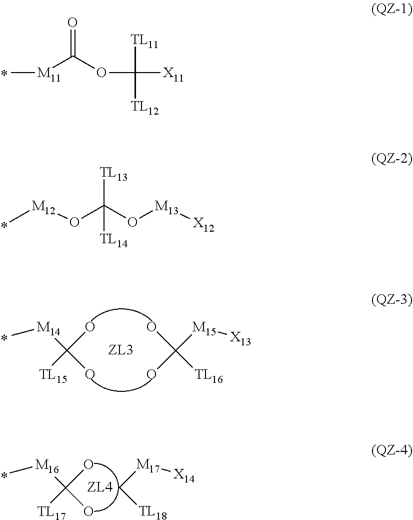

In General Formula (QZ-1), M₁₁ represents a single bond or a divalent linking group, TL₁₁ and TL₁₂ each independently represent a hydrogen atom, an alkyl group, a cycloalkyl group, an aryl group, or a halogen atom, and TL₁₁ and TL₁₂ may be bonded to each other to form a ring. X₁₁ represents a hydrogen atom, a halogen atom, or a monovalent organic group. X₁₁ may be bonded to at least one of TL₁₁ or TL₁₂ to form a ring. * represents a bonding position.

In General Formula (QZ-2), M₁₂ and M₁₃ each independently represent a single bond or a divalent linking group, TL₁₃ and TL₁₄ each independently represent a hydrogen atom, an alkyl group, a cycloalkyl group, or an aryl group, and TL₁₃ and TL₁₄ may be bonded to each other to form a ring. X₁₂ represents a hydrogen atom, a halogen atom, or a monovalent organic group. X₁₂ may be bonded to at least one of TL₁₃ or TL₁₄ to form a ring. * represents a bonding position.

In General Formula (QZ-3), M₁₄ and M₁₅ each independently represent a single bond or a divalent linking group, and T₁₅ and TL₁₆ each independently represent a hydrogen atom, an alkyl group, a cycloalkyl group, an aryl group, or a halogen atom. ZL3 represents a ring structure. ZL3 may represent a spirocyclic structure. X₁₃ represents a hydrogen atom, a halogen atom, or a monovalent organic group. * represents a bonding position.

In General Formula (QZ-4), M₁₆ and M₁₇ each independently represent a single bond or a divalent linking group, and TL₁₇ and TL₁₈ each independently represent a hydrogen atom, an alkyl group, a cycloalkyl group, an aryl group, or a halogen atom. ZL4 represents a ring structure. ZL4 may represent a spirocyclic structure. X₁₄ represents a hydrogen atom, a halogen atom, or a monovalent organic group. * represents a bonding position.

In General Formula (QZ-1), M₁₁ represents a single bond or a divalent linking group. The detailed description of the preferred range and the like in a case where M₁₁ represents a divalent linking group is the same as that of M₁ in General Formula (RZ-1).

In General Formula (QZ-1), TL₁₁ and TL₁₂ each independently represent a hydrogen atom, an alkyl group, a cycloalkyl group, or an aryl group, and TL₁₁ and TL₁₂ may be bonded to each other to form a ring. The detailed description of the preferred ranges of TL₁₁ and TL₁₂ is the same as that of TL₁ and TL₂ in General Formula (RZ-1).

In General Formula (QZ-1), X₁₁ represents a hydrogen atom, a halogen atom, or a monovalent organic group. As the monovalent organic group, an alkyl group, a cycloalkyl group, or an aryl group is preferable. X₁₁ may be bonded to at least one of TL₁₁ or TL₁₂ to form a ring. The detailed description of the preferred ranges of X₁₁ and the like is the same as that of TL₁ and TL₂ in General Formula (RZ-1). In a case where X₁₁ is bonded to at least one of TL₁₁ or TL₁₂ to form a ring, the ring formed is preferably a cycloalkane ring (preferably having 3 to 10 carbon atoms).

In General Formula (QZ-2), M₁₂ and M₁₃ represent a single bond or a divalent linking group. The detailed description of the preferred range and the like in a case where M₁₂ and M₁₃ each represent a divalent linking group is the same as that of M₁ in General Formula (RZ-1).

In General Formula (QZ-2), TL₁₃ and TL₁₄ each independently represent a hydrogen atom, an alkyl group, a cycloalkyl group, or an aryl group, and TL₁₃ and TL₁₄ may be bonded to each other to form a ring. The detailed description of the preferred ranges of TL₁₃ and TL₁₄ is the same as that of TL₁ and TL₂ in General Formula (RZ-1).

In General Formula (QZ-2), X₁₂ represents a hydrogen atom, a halogen atom, or a monovalent organic group. As the monovalent organic group, an alkyl group, a cycloalkyl group, or an aryl group is preferable. The detailed description of the preferred range of X₁₂ and the like is the same as that of TL₁ and TL₂ in General Formula (RZ-1).

In General Formula (QZ-3), M₁₄ and M₁₅ represent a single bond or a divalent linking group. The detailed description of the preferred range and the like in a case where M₁₄ and M₁₅ each represent a divalent linking group is the same as that of M₁ in General Formula (RZ-1).

In General Formula (QZ-3), TL₁₅ and TL₁₆ each independently represent a hydrogen atom, an alkyl group, a cycloalkyl group, an aryl group, or a halogen atom. The detailed description of the preferred ranges of TL₁₅ and TL₁₆ is the same as that of TL₁ and TL₂ in General Formula (RZ-1).

In General Formula (QZ-3), X₁₃ represents a hydrogen atom, a halogen atom, or a monovalent organic group. As the monovalent organic group, an alkyl group, a cycloalkyl group, or an aryl group is preferable. The detailed description of the preferred range of X₁₃ and the like is the same as that of TL₁ and TL₂ in General Formula (RZ-1).

In General Formula (QZ-3), ZL3 represents a ring structure. ZL3 preferably represents a spirocyclic structure.

The group represented by General Formula (QZ-3) is preferably a group represented by General Formula (QZ-3-1).

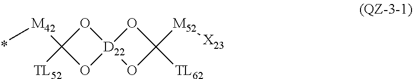

In General Formula (QZ-3-1), M₄₂ and M₅₂ each independently represent a single bond or a divalent linking group, and TL₅₂ and TL₆₂ each independently represent a hydrogen atom, an alkyl group, a cycloalkyl group, an aryl group, or a halogen atom. D₂₂ represents a carbon atom or a tetravalent hydrocarbon group. X₂₃ represents a hydrogen atom, a halogen atom, or a monovalent organic group. * represents a bonding position.

The detailed description of the preferred ranges of M₄₂, M₅₂, TL₅₂, and TL₆₂ in General Formula (QZ-3-1) is the same as that of M₄, M₅, TL₅, and TL₆ in General Formula (RZ-3), respectively.

The detailed description of the preferred range of X₂₃ and the like in General Formula (QZ-3-1) is the same as that of X₁₃ in General Formula (QZ-3).

In General Formula (QZ-3-1), D₂₂ represents a carbon atom or a tetravalent hydrocarbon group, and preferably a carbon atom or a hydrocarbon group having 2 to 10 carbon atoms.

In General Formula (QZ-4), M₁₆ and M₁₇ each represent a single bond or a divalent linking group. The detailed description of the preferred range and the like in a case where M₁₆ and M₁₇ each represent a divalent linking group is the same as that of M₁ in General Formula (RZ-1).

In General Formula (QZ-4), TL₁₇ and TL₁₈ each independently represent a hydrogen atom, an alkyl group, a cycloalkyl group, an aryl group, or a halogen atom. The detailed description of the preferred ranges of TL₁₇ and TL₁₈ is the same as that of TL₁ and TL₂ in General Formula (RZ-1).

In General Formula (QZ-4), X₁₄ represents a hydrogen atom, a halogen atom, or a monovalent organic group. As the monovalent organic group, an alkyl group, a cycloalkyl group, or an aryl group is preferable. The detailed description of the preferred range of X₁₄ and the like is the same as that of TL₁ and TL₂ in General Formula (RZ-1).

The group represented by General Formula (QZ-4) is preferably a group represented by General Formula (QZ-4-1).

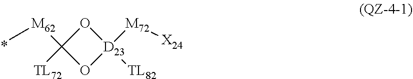

In General Formula (QZ-4-1), M₆₂ and M₇₂ each independently represent a single bond or a divalent linking group, and TL₇₂ and TL₈₂ each independently represent a hydrogen atom, an alkyl group, a cycloalkyl group, an aryl group, or a halogen atom. D₂₃ represents a carbon atom or a tetravalent hydrocarbon group. * represents a bonding position.

The detailed description of the preferred ranges of M₆₂, M₇₂, TL₇₂, and TL₈₂ in General Formula (QZ-4-1) is the same as that of M₄, M₅, TL₅, and TL₆ in General Formula (RZ-3), respectively.

In General Formula (QZ-4-1), the detailed description of the preferred range of X₂₄ and the like is the same as that of X₁₄ in General Formula (QZ-4).

In General Formula (QZ-4-1), D₂₃ represents a carbon atom or a tetravalent hydrocarbon group, preferably a carbon atom or a hydrocarbon group having 2 to 10 carbon atoms.

From the viewpoint that the DRCA of a film formed of the composition of the embodiment of the present invention with respect to water can be further increased, it is preferable that the polyester (B) contains a fluorine atom.

Furthermore, from the viewpoint that the DRCA can be increased during exposure, the DPCA can be reduced during development (particularly during development using an alkali developer), defects can be further reduced, and LWR performance can be further improved, it is preferable that the polyester (B) has an alkali-decomposable group.

The alkali-decomposable group is a group which decomposes by the action of an alkali to increase a polarity, and more specifically, a group that decomposes by the action of an alkali developer to increase the solubility in the alkali developer. As the alkali-decomposable group, for example, a group in which a hydrogen atom of an alkali-soluble group such as a —COOH group and an —OH group is substituted with a group that leaves by the action of alkali is preferable. More specific examples of the alkali-decomposable group include a lactone group, a carboxylic ester group (—COO—), an acid anhydride group (—C(O)OC(O)—), an acid imido group (—NHCONH—), a carboxylic acid thioester group (—COS—), a carbonic ester group (—OC(O)O—), a sulfuric ester group (—OSO₂O—), and a sulfonic ester group (—SO₂O—).

In a case where the polyester (B) has an alkali-decomposable group, it may have an alkali-decomposable group in a side chain, in the main chain, or in the side chain and the main chain.

In a case where the polyester (B) has an alkali-decomposable group in a side chain, it is preferable that the alkali-decomposable group is a monovalent group represented by General Formula (E1-1) or (E1-2).

In a case where the polyester (B) has an alkali-decomposable group in the main chain, it is preferable that the alkali-decomposable group is a divalent group represented by General Formula (E2-1) or (E2-2).

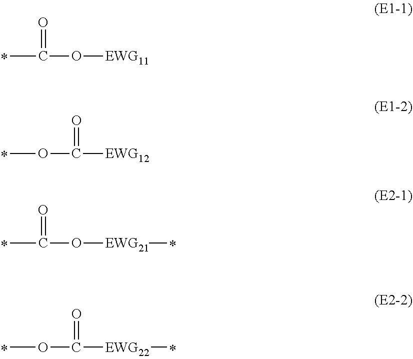

In General Formulae (E1-1), (E1-2), (E2-1), and (E2-2), EWG₁₁, EWG₁₂, EWG₂₁, and EWG₂₂ each represent an electron-withdrawing group.

Examples of the electron-withdrawing group as EWG₁₁ or EWG₁₂ include a halogen atom, a cyano group, a nitrile group, a nitro group, an alkyl halide group, a cycloalkyl halide group, an aryl halide group, or a monovalent group formed by combination thereof, or a monovalent group obtained by substituting an alkyl group or a cycloalkyl group with these groups.

The electron-withdrawing group as EWG₁₁ or EWG₁₂ may further include an oxy group, a carbonyl group, a sulfonyl group, a sulfinyl group, or a divalent group formed by combination thereof within the group.

The electron-withdrawing group as EWG₁₁ or EWG₁₂ is preferably an alkyl halide group, more preferably an alkyl halide group having 1 to 16 carbon atoms, and still more preferably an alkyl halide group having 1 to 8 carbon atoms. Further, the alkyl halide group is preferably a fluorinated alkyl group, and more preferably a perfluoroalkyl group.

The electron-withdrawing group as EWG₂₁ or EWG₂₂ is an alkylene halide group, a cycloalkylene halide group, an arylene halide group, an oxy group, a carbonyl group, a sulfonyl group, a sulfinyl group, or a divalent group formed by combination thereof, or a divalent group in which these groups are bonded to an alkylene group or a cycloalkylene group.

The electron-withdrawing group as EWG₂₁ or EWG₂₂ may be further substituted with a halogen atom, a cyano group, a nitrile group, a nitro group, an alkyl halide group, a cycloalkyl halide group, an aryl halide group, or a monovalent group obtained by combination thereof.

The electron-withdrawing group as EWG₂₁ or EWG₂₂ is preferably an alkylene halide group, more preferably an alkylene halide group having 1 to 16 carbon atoms, and still more preferably an alkylene halide group having 1 to 8 carbon atoms. Further, the alkylene halide group is preferably a fluorinated alkylene group, and more preferably a perfluoroalkylene group.

From the viewpoint of the contact angle, it is preferable that the polyester (B) has a group represented by General Formula (EZ-1) in a side chain.

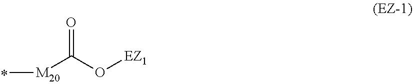

In General Formula (EZ-1), M₂₀ represents a single bond or a divalent linking group, and EZ₁ represents a monovalent organic group having an electron-withdrawing property.

In General Formula (EZ-1), M₂₀ represents a single bond or a divalent linking group. The detailed description of the preferred range and the like in a case where M₂₀ represents a divalent linking group is the same as that of M₁ in General Formula (RZ-1).

In General Formula (EZ-1), EZ₁ represents a monovalent organic group having an electron-withdrawing property, and examples thereof include an alkyl halide group, a cycloalkyl halide group, an aryl halide group, or a monovalent group formed by combination thereof, or a monovalent group obtained by substituting an alkyl group or a cycloalkyl group with these groups.

The monovalent organic group as EZ₁ may further include an oxy group, a carbonyl group, a sulfonyl group, a sulfinyl group, or a divalent group formed by combination thereof within the group.

EZ₁ is preferably an alkyl halide group, more preferably an alkyl halide group having 1 to 16 carbon atoms, and still more preferably an alkyl halide group having 1 to 8 carbon atoms. Further, the alkyl halide group is preferably a fluorinated alkyl group, and more preferably a perfluoroalkyl group.

The polyester (B) is preferably represented by General Formula (1).

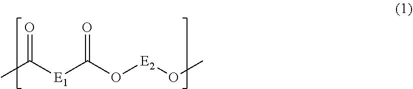

In General Formula (1), E₁ and E₂ each independently represent a chained aliphatic group which may include a heteroatom, an alicyclic group which may include a heteroatom, an aromatic group, or a group formed by combination thereof.

In General Formula (1), the chained aliphatic group as each of E₁ and E₂ is a divalent group, preferably an alkylene group, more preferably an alkylene group having 1 to 20 carbon atoms, and still more preferably an alkylene group having 4 to 12 carbon atoms. The chained aliphatic group may include a heteroatom (for example, an oxygen atom, a sulfur atom, or a nitrogen atom) in the chain, but it is preferable that it does not include a heteroatom. The chained aliphatic group may have a substituent, and as the substituent, a halogen atom, a cycloalkyl group, an alkyloxycarbonyl group, an alkylcarbonyloxy group, a cycloalkyloxycarbonyl group, a cycloalkylcarbonyloxy group, an aryloxycarbonyl group, an arylcarbonyloxy group, or the like is preferable, the halogen atom is more preferable, and the fluorine atom is particularly preferable.

In General Formula (1), the alicyclic group as each of E₁ and E₂ is a divalent group, preferably a cycloalkylene group or a spirocyclic group, more preferably a cycloalkylene group or a spirocyclic group having 4 to 20 carbon atoms, and still more preferably a cycloalkylene group having 6 to 12 carbon atoms or a spirocyclic group. Here, the spirocyclic group as the divalent group is a divalent group obtained by removing any two hydrogen atoms from the spirocyclic compound. The alicyclic group may include a heteroatom (for example, an oxygen atom, a sulfur atom, or a nitrogen atom) as a ring member. Particularly, the spirocyclic group including an oxygen atom is preferable. The alicyclic group may have a substituent, and as the substituent, a halogen atom, an alkyl group, an alkyloxycarbonyl group, a fluoroalkyloxycarbonyl group, or the like is preferable, and the fluoroalkyloxycarbonyl group is more preferable.

In General Formula (1), the aromatic group as each of E₁ and E₂ is a divalent group, preferably an arylene group or a heteroarylene group (divalent aromatic heterocyclic group), more preferably an arylene group, still more preferably an arylene group having 6 to 20 carbon atoms, and particularly preferably an arylene group having 6 to 12 carbon atoms. The aromatic group may have a substituent, and preferred examples of the substituent include a halogen atom, an alkyl group, an alkyloxycarbonyl group, and a fluoroalkyloxycarbonyl group.

E₁ and E₂ in General Formula (1) are each a divalent group formed by combination of two or more groups selected from a chained aliphatic group which may include a heteroatom, an alicyclic group which may include a heteroatom, and an aromatic group. Examples of the group from the combination include a group formed by combination of an alkylene group and a cycloalkylene group, a group formed by combination of an alkylene group and an arylene group, a group formed by combination of an alkylene group and a spirocyclic group, these groups which include a heteroatom in a chain or as a ring member, or these groups which have a substituent.

It is preferable that E₁ and E₂ in General Formula (1) are each independently a group represented by any of General Formulae (1a) to (1e).

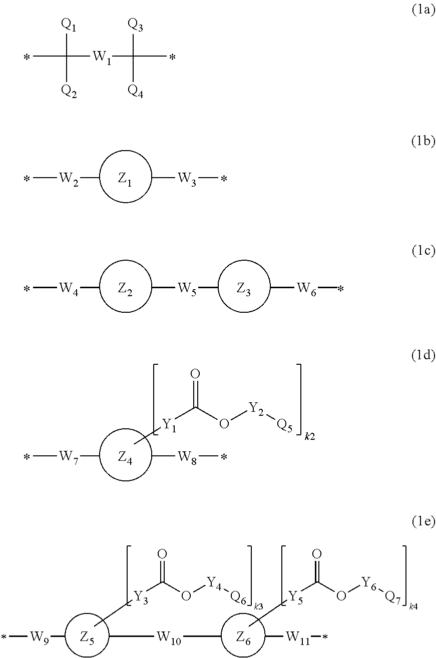

In General Formula (1a), Q₁ to Q₄ each independently represent a hydrogen atom, a halogen atom, or an alkyl group, and W₁ represents a single bond, an alkylene group, or a cycloalkylene group.

In General Formula (1b), W₂ and W₃ each independently represent a single bond, an alkylene group, or a cycloalkylene group, and Z₁ represents a cycloalkylene group, a spirocyclic group which may include a heteroatom, or an arylene group.

In General Formula (1c), W₄, W₅, and W₆ each independently represent a single bond, an alkylene group, or a cycloalkylene group, and Z₂ and Z₃ each independently represent a cycloalkylene group, a spirocyclic group which may include a heteroatom, or an arylene group.

In General Formula (1d), W₇ and W₈ each independently represent a single bond, an alkylene group, or a cycloalkylene group, Z₄ represents a cycloalkylene group, a spirocyclic group which may include a heteroatom, or an arylene group, Y₁ and Y₂ each independently represent a single bond or a divalent linking group, Q₅ represents a hydrogen atom, an alkyl group, a cycloalkyl group, or an aryl group, and k2 represents an integer of 1 or more. In a case where k2 represents an integer of 2 or more, a plurality of Y₁'s, a plurality of Y₂'s, and a plurality of Q₅'s may be the same as or different from each other.

In General Formula (1e), W₉, W₁₀, and W₁₁ each independently represent a single bond, an alkylene group, or a cycloalkylene group, Z₅ and Z₆ each independently represent a cycloalkylene group, a spirocyclic group which may include a heteroatom, or an arylene group, Y₃, Y₄, Y₅, and Y₆ each independently represent a single bond or a divalent linking group, Q₆ and Q₇ each independently represent a hydrogen atom, an alkyl group, a cycloalkyl group, or an aryl group, and k3 and k4 each independently represent an integer of 1 or more. In a case where k3 represents an integer of 2 or more, a plurality of Y₃'s, a plurality of Y₄'s, and a plurality of Q₆'s may be the same as or different from each other. In a case where k4 represents an integer of 2 or more, a plurality of Y₅'s, a plurality of Y₆'s, and a plurality of Q₇'s may be the same as or different from each other.

In General Formula (1a), Q₁ to Q₄ each independently represent a hydrogen atom, a halogen atom, or an alkyl group, and preferably the halogen atom or the alkyl group.

The halogen atom as each of Q₁ to Q₄ is preferably the fluorine atom.

The alkyl group as each of Q₁ to Q₄ is preferably an alkyl group having 1 to 6 carbon atoms, and more preferably an alkyl group having 1 to 3 carbon atoms. Incidentally, the alkyl group as each of Q₁ to Q₄ may have a substituent, and in the case where the alkyl group has a substituent, the substituent is preferably a halogen atom, and more preferably a fluorine atom.

In General Formula (1a), W₁ represents a single bond, an alkylene group, or a cycloalkylene group.

The alkylene group as W₁ is preferably an alkylene group having 1 to 20 carbon atoms, and more preferably an alkylene group having 1 to 12 carbon atoms.

The alkylene group as W₁ may have a substituent, and in a case where the alkylene group has a substituent, a halogen atom is preferable and a fluorine atom is more preferable as the substituent.

The cycloalkylene group as W₁ is preferably a cycloalkylene group having 4 to 20 carbon atoms, and more preferably a cycloalkylene group having 4 to 8 carbon atoms.

The cycloalkylene group as W₁ may have a substituent, and in a case where the cycloalkylene group has a substituent, a halogen atom is preferable, and a fluorine atom is more preferable as the substituent.

W₂ and W₃ in General Formula (1b) are the same as W₁ in General Formula (1a), respectively.

In General Formula (1b), Z₁ represents a cycloalkylene group, a spirocyclic group which may include a heteroatom, or an arylene group.

The cycloalkylene group as Z₁ is preferably a cycloalkylene group having 4 to 20 carbon atoms, and more preferably a cycloalkylene group having 4 to 10 carbon atoms.

The spirocyclic group as Z₁ is preferably a spirocyclic group having 4 to 30 carbon atoms, and more preferably a spirocyclic group having 6 to 20 carbon atoms.

The spirocyclic group as Z₁ may include a heteroatom, and preferably includes an oxygen atom as a ring member.

The arylene group as Z₁ is preferably an arylene group having 6 to 30 carbon atoms, and more preferably an arylene group having 6 to 12 carbon atoms.

The cycloalkylene group, the spirocyclic group which may include a heteroatom, or the arylene group, each represented by Z₁, may have a substituent, and as the substituent, a halogen atom, an alkyl group, an alkyloxycarbonyl group, a fluoroalkyloxycarbonyl group, or the like is preferable, and the fluoroalkyloxycarbonyl group is more preferable.

W₄, W₅, and W₆ in General Formula (1c) are the same as W₁ in General Formula (1a), respectively.

Z₂ and Z₃ are the same as Z₁ in General Formula (1b) mentioned above.

W₇ and W₈ in General Formula (1d) are the same as W₁ in General Formula (1a), respectively.

Z₄ is the same as Z₁ in General Formula (1b) mentioned above, but it is particularly preferable that Z₄ is not a divalent group obtained by removing any two hydrogen atoms of norbornane.

Q₅ represents a hydrogen atom, an alkyl group, a cycloalkyl group, or an aryl group.

The alkyl group as Q₅ is preferably an alkyl group having 1 to 6 carbon atoms, and more preferably an alkyl group having 1 to 3 carbon atoms.

The cycloalkyl group as Q₅ is preferably a cycloalkyl group having 4 to 20 carbon atoms, and more preferably a cycloalkyl group having 4 to 10 carbon atoms.

The arylene group as Q₅ is preferably an arylene group having 6 to 30 carbon atoms, and more preferably an arylene group having 6 to 12 carbon atoms.

In a case where Q₅ represents an alkyl group, a cycloalkyl group or an aryl group, it may have a substituent, and in a case where Q₅ has a substituent, the substituent is preferably a halogen atom, and more preferably a fluorine atom.

Y₁ and Y₂ each independently represent a single bond or a divalent linking group.

In a case where Y₁ and Y₂ represent the divalent linking group, —O—, —CO—, —COO—, an alkylene group (preferably having 1 to 15 carbon atoms, and more preferably having 1 to 10 carbon atoms), a cycloalkylene group (preferably having 3 to 15 carbon atoms, and more preferably having 5 to 10 carbon atoms), an arylene group (preferably having 6 to 15 carbon atoms, and more preferably having 6 to 10 carbon atoms), or a divalent linking group obtained by combination thereof is preferable.

k2 represents an integer of 1 or more, preferably an integer of 1 to 10, and more preferably an integer of 1 to 3.

W₉, W₁₀, and W₁₁ in General Formula (1e) are the same as W₁ in General Formula (1a), respectively.

Z₅ and Z₆ are the same as Z₁ in General Formula (1b) mentioned above, but it is particularly preferable that Z₅ and Z₆ are not a divalent group obtained by removing any two hydrogen atoms of norbornane.

Q₆ and Q₇ are the same as Q₅ in General Formula (1d), respectively.

Y₃ to Y₆ are the same as Y₁ and Y₂ in General Formula (1d), respectively.

k3 and k4 represent an integer of 1 or more, preferably an integer of 1 to 10, and more preferably an integer of 1 to 3.

The repetition number of the structure (repeating structural unit) represented by General Formula (1) in the polyester (B) is preferably 3 or more, more preferably 5 to 200, still more preferably 5 to 100, and particularly preferably 5 to 50. That is, the polyester (B) preferably has a structure represented by General Formula (1p).

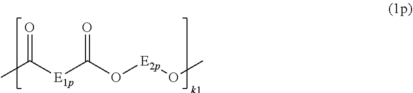

In General Formula (1p), E₁ₚ and E₂ₚ each independently represent a chained aliphatic group which may contain a heteroatom, an alicyclic group which may include a heteroatom, an aromatic group, or a group formed by combination thereof k1 represents the number of 3 or more.

k1 is an average value of all the polymers. k1 is preferably 3 or more, more preferably 5 to 200, still more preferably 5 to 100, and particularly preferably 5 to 50.

In General Formula (1p), E₁ₚ and E₂ₚ are the same as E₁ₚ and E₂ₚ in General Formula (1), respectively.

Specific preferred examples of the polyester (B) are shown below, but are not limited thereto.

PE-1 is a polyester having an acid-decomposable group in the main chain.

PE-2 is a polyester having an acid-decomposable group in the main chain and an alkali-decomposable group in a side chain.

PE-3 is a polyester having an acid-decomposable group in the main chain and an alkali-decomposable group in a side chain.

PE-4 is a polyester having an acid-decomposable group in a side chain and an alkali-decomposable group in the main chain.

PE-5 is a polyester having an acid-decomposable group in a side chain and an alkali-decomposable group in the main chain.

PE-6 is a polyester having an acid-decomposable group in the main chain and side chains and an alkali-decomposable group in the side chain.

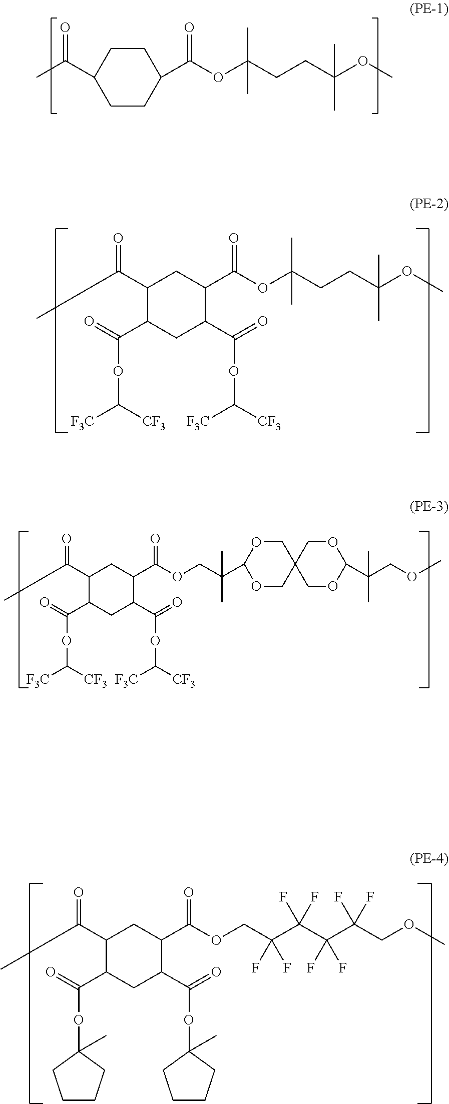

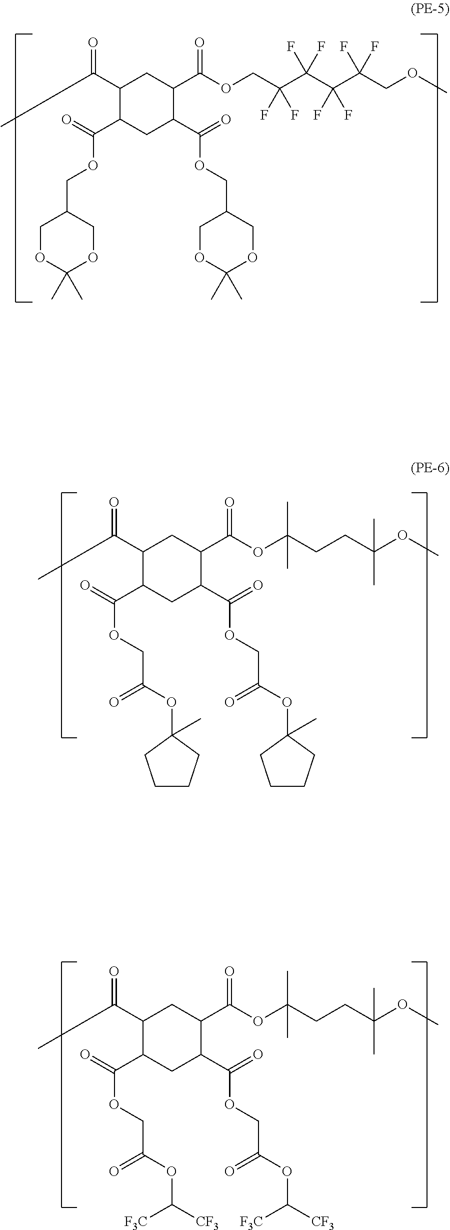

The weight-average molecular weight (Mw) of the polyester (B) is preferably 4,000 to 30,000, more preferably 6,000 to 20,000, and still more preferably 8,000 to 16,000. The dispersity (Mw/Mn) is usually 1.0 to 3.0, and preferably 1.5 to 2.6.

The polyester (B) can be obtained through synthesis by a known method. For example, it can be synthesized by a polycondensation reaction of a dicarboxylic acid halide and a diol, a polyaddition reaction of a dianhydride and a diol, a polycondensation reaction of a dicarboxylic acid and a diol, ring-opening polymerization of a cyclic lactone, and the like.

The polyesters (B) may be used singly or in combination of two or more kinds thereof.

The content of the polyester (B) in the composition of the embodiment of the present invention is preferably from 0.1% by mass to 30% by mass, more preferably from 0.1% by mass to 15% by mass, still more preferably from 0.5% by mass to 8% by mass, particularly preferably from 1% by mass to 6% by mass, and most preferably from 2% by mass to 4% by mass, with respect to the total solid content of the composition of the embodiment of the present invention.

<Photoacid Generator (C)>

The composition of the embodiment of the present invention contains a photoacid generator (also referred to as a “photoacid generator (C)” or an “acid generator”).

The photoacid generator is a compound that generates an acid upon irradiation with actinic rays or radiation.

As the photoacid generator, a compound that generates an organic acid upon irradiation with actinic rays or radiation is preferable. Examples thereof include a sulfonium salt compound, an iodonium salt compound, a diazonium salt compound, a phosphonium salt compound, an imidosulfonate compound, an oxime sulfonate compound, a diazodisulfone compound, a disulfone compound, and an o-nitrobenzyl sulfonate compound.

As the photoacid generators, known compounds that generate an acid upon irradiation with actinic rays or radiation can be used singly or as a mixture thereof, appropriately selected and used. For example, the known compounds disclosed in paragraphs <0125> to <0319> of the specification of US2016/0070167A1, paragraphs <0086> to <0094> of the specification of US2015/0004544A1, and paragraphs <0323> to <0402> of the specification of US2016/0237190A1 can be suitably used as the photoacid generator (C).

Suitable aspects of the photoacid generator (C) include a compound represented by General Formula (ZI), (ZII), or (ZIII).

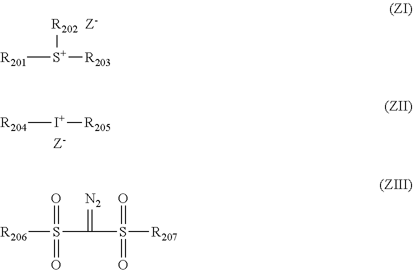

In General Formula (ZI),

R₂₀₁, R₂₀₂, and R₂₀₃ each independently represent an organic group.

The organic group as each of R₂₀₁, R₂₀₂, and R₂₀₃ generally has 1 to 30 carbon atoms, and preferably has 1 to 20 carbon atoms.

In addition, two of R₂₀₁ to R₂₀₃ may be bonded to each other to form a ring structure, and the ring may include an oxygen atom, a sulfur atom, an ester bond, an amide bond, or a carbonyl group. Examples of the group formed by the bonding of two of R₂₀₁ to R₂₀₃ include an alkylene group (for example, a butylene group and a pentylene group), and —CH₂—CH₂—O—CH₂—CH₂—.

Z⁻ represents an anion.

Suitable aspects of the cation in General Formula (ZI) include the corresponding groups in compounds (ZI-1), (ZI-2), (ZI-3), and (ZI-4) which will be described later.

Furthermore, the photoacid generator (C) may be a compound having a plurality of structures represented by General Formula (ZI). For example, the photoacid generator (C) may be a compound having a structure in which at least one of R₂₀₁, . . . , or R₂₀₃ of the compound represented by General Formula (ZI) and at least one of R₂₀₁, . . . , or R₂₀₃ of another compound represented by General Formula (ZI) are bonded via a single bond or a linking group.

First, the compound (ZI-1) will be described.

The compound (ZI-1) is an arylsulfonium compound in which at least one of R₂₀₁, . . . , or R₂₀₃ in General Formula (ZI) is an aryl group, that is, a compound having arylsulfonium as a cation.

In the arylsulfonium compound, any of R₂₀₁ to R₂₀₃ may be an aryl group, or some of R₂₀₁ to R₂₀₃ may be an aryl group, and the rest may be an alkyl group or a cycloalkyl group.

Examples of the arylsulfonium compound include a triarylsulfonium compound, a diarylalkyl sulfonium compound, an aryldialkylsulfonium compound, a diarylcycloalkyl sulfonium compound, and an aryldicycloalkylsulfonium compound.

As the aryl group of the arylsulfonium compound, a phenyl group or a naphthyl group is preferable, and the phenyl group is more preferable. The aryl group may be an aryl group which has a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium compound has two or more aryl groups, the two or more aryl groups may be the same as or different from each other.

The alkyl group or the cycloalkyl group contained in the arylsulfonium compound, as necessary, is preferably a linear alkyl group having 1 to 15 carbon atoms, a branched alkyl group having 3 to 15 carbon atoms, or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group if each of R₂₀₁ to R₂₀₃ may each independently have an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group as a substituent.

Next, the compound (ZI-2) will be described.

The compound (ZI-2) is a compound in which R₂₀₁ to R₂₀₃ in Formula (ZI) each independently represent an organic group having no aromatic ring. Here, the aromatic ring also includes an aromatic ring containing a heteroatom.

The organic group having no aromatic ring as each of R₂₀₁ to R₂₀₃ generally has 1 to 30 carbon atoms, and preferably has 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably the linear or branched 2-oxoalkyl group.

Preferred examples of the alkyl group and the cycloalkyl group of each of R₂₀₁ to R₂₀₃ include a linear alkyl group having 1 to 10 carbon atoms or branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, and a norbornyl group).

R₂₀₁ to R₂₀₃ may be further substituted with a halogen atom, an alkoxy group (for example, having 1 to 5 carbon atoms), a hydroxyl group, a cyano group, or a nitro group.

Next, the compound (ZI-3) will be described.

The compound (ZI-3) is a compound represented by General Formula (ZI-3) and having a phenacylsulfonium salt structure.

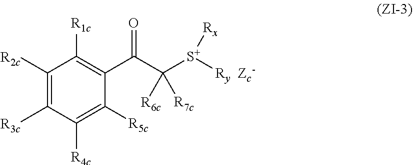

In General Formula (ZI-3),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more of R_{1c}, . . . , or R_{5c}, R_{5c} and R_{6c}, R_{6c} and R_{7c}, R_{5c} and Rₓ, or Rₓ and R_{y} may be bonded to each other to form a ring structure, and the ring structure may each independently include an oxygen atom, a sulfur atom, a ketone group, an ester bond, or an amide bond.

Examples of the ring structure include an aromatic or non-aromatic hydrocarbon ring, an aromatic or non-aromatic heterocycle, and a polycyclic fused ring in which two or more of these rings are combined. Examples of the ring structure include a 3- to 10-membered ring and the ring structure is preferably a 4- to 8-membered ring, and more preferably a 5- or 6-membered ring.

Examples of the group formed by the bonding of any two or more of R_{1c}, . . . , or R_{5c}, R_{6c} and R_{7c}, and Rₓ and R_{y} include a butylene group and a pentylene group.

As the group formed by the bonding of R_{5c} and R_{6c}, and R_{5c} and Rₓ, a single bond or an alkylene group is preferable. Examples of the alkylene group include a methylene group and an ethylene group.

Zc⁻ represents an anion.

Next, the compound (ZI-4) will be described.

The compound (ZI-4) is represented by General Formula (ZI-4).

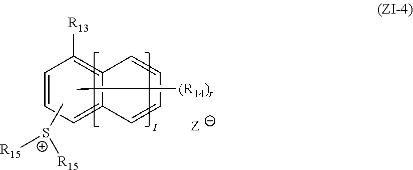

In General Formula (ZI-4),

l represents an integer of 0 to 2.

r represents an integer of 0 to 8.

R₁₃ represents a group having a hydrogen atom, a fluorine atom, a hydroxyl group, an alkyl group, a cycloalkyl group, an alkoxy group, an alkoxycarbonyl group, or a cycloalkyl group. Such a group may have a substituent.

R₁₄ represents a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. Such a group may have a substituent. In a case where R₁₄'s are present in a plural number, R₁₄'s each independently represent the group such as a hydroxyl group.

R₁₅'s each independently represent an alkyl group, a cycloalkyl group, or a naphthyl group. Such a group may have a substituent. Two of R₁₅'s may be bonded to each other to form a ring. In a case where two of R₁₅'s are bonded to each other to form a ring, the ring skeleton may include a heteroatom such as an oxygen atom and a nitrogen atom. In one aspect, it is preferable that two of R₁₅'s are alkylene groups and are bonded to each other to form a ring structure.

Z⁻ represents an anion.

In General Formula (ZI-4), the alkyl group in each of R₁₃, R₁₄, and R₁₅ is linear or branched, preferably has 1 to 10 carbon atoms, and is more preferably a methyl group, an ethyl group, an n-butyl group, a t-butyl group, or the like.

Next, General Formulae (ZII) and (ZIII) will be described.

In General Formulae (ZII) and (ZIII), R₂₀₄ to R₂₀₇ each independently represent an aryl group, an alkyl group, or a cycloalkyl group.

The aryl group of each of R₂₀₄ to R₂₀₇ is preferably a phenyl group or a naphthyl group, and more preferably the phenyl group. The aryl group of each of R₂₀₄ to R₂₀₇ may be an aryl group which has a heterocyclic structure having an oxygen atom, a nitrogen atom, a sulfur atom, or the like. Examples of the skeleton of the aryl group having a heterocyclic structure include pyrrole, furan, thiophene, indole, benzofuran, and benzothiophene.

Preferred examples of the alkyl group and the cycloalkyl group of each of R₂₀₄ to R₂₀₇ include a linear alkyl group having 1 to 10 carbon atoms or branched alkyl group having 3 to 10 carbon atoms (for example, a methyl group, an ethyl group, a propyl group, a butyl group, and a pentyl group), and a cycloalkyl group having 3 to 10 carbon atoms (for example, a cyclopentyl group, a cyclohexyl group, and a norbornyl group).

The aryl group, the alkyl group, and the cycloalkyl group of each of R₂₀₄ to R₂₀₇ may each independently have a substituent. Examples of the substituent which may be contained in the aryl group, the alkyl group, and the cycloalkyl group of each of R₂₀₄ to R₂₀₇ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z⁻ represents an anion.

As Z⁻ in General Formula (ZI), Z⁻ in General Formula (ZII), Zc⁻ in General Formula (ZI-3), and Z⁻ in General Formula (ZI-4), an anion represented by General Formula (3) is preferable.

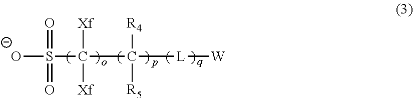

In General Formula (3),

o represents an integer of 1 to 3. p represents an integer of 0 to 10. q represents an integer of 0 to 10.

Xf's each independently represent a fluorine atom or an alkyl group substituted with at least one fluorine atom.

R₄ and R₅ each independently represent a hydrogen atom, a fluorine atom, an alkyl group, or an alkyl group substituted with at least one fluorine atom, and in a case where a plurality of R₄'s and R₅'s are present, they may be the same as or different from each other.

L represents a divalent linking group, and in a case where a plurality of L's are present, they may be the same as or different from each other.

W represents an organic group including a cyclic structure.

o represents an integer of 1 to 3. p represents an integer of 0 to 10. q represents an integer of 0 to 10.

Xf represents a fluorine atom or an alkyl group substituted with at least one fluorine atom. The alkyl group preferably has 1 to 10 carbon atoms, and more preferably has 1 to 4 carbon atoms. In addition, a perfluoroalkyl group is preferable as the alkyl group substituted with at least one fluorine atom.

Xf is preferably a fluorine atom or a perfluoroalkyl group having 1 to 4 carbon atoms. Xf is more preferably the fluorine atom or CF₃. In particular, it is preferable that both Xf's are fluorine atoms.

R₄ and R₅ each independently represent a hydrogen atom, a fluorine atom, an alkyl group, or an alkyl group substituted with at least one fluorine atom. In a case where a plurality of each of R₄'s and R₅'s are present, they may be the same as or different from each other.

The alkyl group represented by each of R₄ and R₅ may have a substituent, and preferably has 1 to 4 carbon atoms. R₄ and R₅ are each preferably a hydrogen atom.

Specific examples and suitable aspects of the alkyl group substituted with at least one fluorine atom are the same as the specific examples and the suitable aspects, respectively, of Xf in General Formula (3).

L represents a divalent linking group, and in a case where a plurality of L's are present, they may be the same as or different from each other.

Examples of the divalent linking group include —COO—(—C(═O)—O—), —OCO—, —CONH—, —NHCO—, —CO—, —O—, —S—, —SO—, —SO₂—, an alkylene group (preferably having 1 to 6 carbon atoms), a cycloalkylene group (preferably having 3 to 15 carbon atoms), an alkenylene group (preferably having 2 to 6 carbon atoms), and a divalent linking group formed by combination of a plurality of these groups. Among these, —COO—, —COO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

W represents an organic group including a cyclic structure. Among these, W is preferably a cyclic organic group.

Examples of the cyclic organic group include an alicyclic group, an aryl group, and a heterocyclic group.

The alicyclic group may be either monocyclic or polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among those, an alicyclic group having a bulky structure having 7 or more carbon atoms, such as a norbornyl group, a tricyclodecanyl group, a tetracyclodecanyl group, a tetracyclododecanyl group, and an adamantyl group, is preferable.

The aryl group may be either monocyclic or polycyclic. Examples of the aryl group include a phenyl group, a naphthyl group, a phenanthryl group, and an anthryl group.

The heterocyclic group may be either monocyclic or polycyclic. The polycyclic compound can further suppress acid diffusion. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. Examples of the lactone ring and the sultone ring include the lactone structure and the sultone structure exemplified in the aforementioned resin. As the heterocycle in the heterocyclic group, the furan ring, the thiophene ring, the pyridine ring, or the decahydroisoquinoline ring is particularly preferable.

The cyclic organic group may have a substituent. Examples of the substituent include an alkyl group (which may be either linear or branched, preferably having 1 to 12 carbon atoms), a cycloalkyl group (which may be any of a monocycle, a polycycle, and a spirocycle, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic ester group. Incidentally, the carbon constituting the cyclic organic group (carbon contributing to ring formation) may be carbonyl carbon.

Preferred examples of the anion represented by General Formula (3) include SO₃⁻—CF₂—CH₂—OCO-(L)q′—W, SO₃⁻—CF₂—CHF—CH₂—OCO-(L)q′—W, SO₃⁻—CF₂—COO-(L)q′—W, SO₃⁻—CF₂—CF₂—CH₂—CH₂-(L)q-W, or SO₃⁻—CF₂—CH(CF₃)—OCO-(L)q′—W. Here, L, q, and W are each the same as in General Formula (3). q′ represents an integer of 0 to 10.

In one aspect, as Z⁻ in General Formula (ZI), Z⁻ in General Formula (ZII), Zc⁻ in General Formula (ZI-3), and Z⁻ in General Formula (ZI-4), an anion represented by General Formula (4) is also preferable.

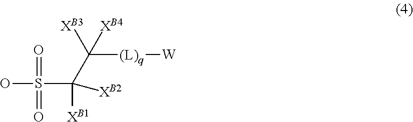

In General Formula (4),

X^{B1} and X^{B2} each independently represent a hydrogen atom or a monovalent organic group having no fluorine atom. X^{B1} and X^{B2} are each preferably the hydrogen atom.

X^{B3} and X^{B4} each independently represent a hydrogen atom or a monovalent organic group. It is preferable that at least one of X^{B3} or X^{B4} is a fluorine atom or a monovalent organic group having a fluorine atom, and it is more preferable that both X^{B3} and X^{B4} are fluorine atoms or monovalent organic groups having a fluorine atom. It is still more preferable that both X^{B3} and X^{B4} are fluorine-substituted alkyl groups. L, q, and W are the same as in General Formula (3).

As Z⁻ in General Formula (ZI), Z⁻ in General Formula (ZII), Zc⁻ in General Formula (ZI-3), and Z⁻ in General Formula (ZI-4), an anion represented by General Formula (5) is preferable.

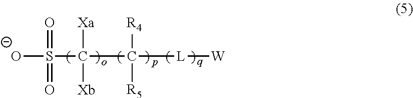

In General Formula (5), Xa's each independently represent a fluorine atom or an alkyl group substituted with at least one fluorine atom. Xb's each independently represent a hydrogen atom or an organic group having no fluorine atom. The definitions and preferred aspects of o, p, q, R₄, R₅, L, and W are each the same as those in General Formula (3).

Z⁻ in General Formula (ZI), Z⁻ in General Formula (ZII), Zc⁻ in General Formula (ZI-3), and Z⁻ in General Formula (ZI-4) may be a benzenesulfonate anion, and are each preferably a benzenesulfonate anion substituted with a branched alkyl group or a cycloalkyl group.

As Z⁻ in General Formula (ZI), Z⁻ in General Formula (ZII), Zc⁻ in General Formula (ZI-3), and Z⁻ in General Formula (ZI-4), an aromatic sulfonate anion represented by General Formula (SA1) is also preferable.

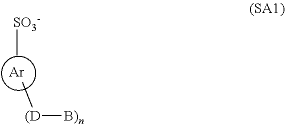

In Formula (SA1),

Ar represents an aryl group, and may further have a substituent other than a sulfonate anion and a -(D-B) group. Examples of the substituent which may be further contained include a fluorine atom and a hydroxyl group.

n represents an integer of 0 or more. n is preferably 1 to 4, more preferably 2 or 3, and most preferably 3.

D represents a single bond or a divalent linking group. Examples of the divalent linking group include an ether group, a thioether group, a carbonyl group, a sulfoxide group, a sulfone group, a sulfonic ester group, an ester group, and a group consisting of a combination of two or more of these.

B represents a hydrocarbon group.

Preferably, D is a single bond and B is an aliphatic hydrocarbon structure. It is more preferable that B is an isopropyl group or a cyclohexyl group.

Preferred examples of the sulfonium cation in General Formula (ZI) and the iodonium cation in General Formula (ZII) are shown below.

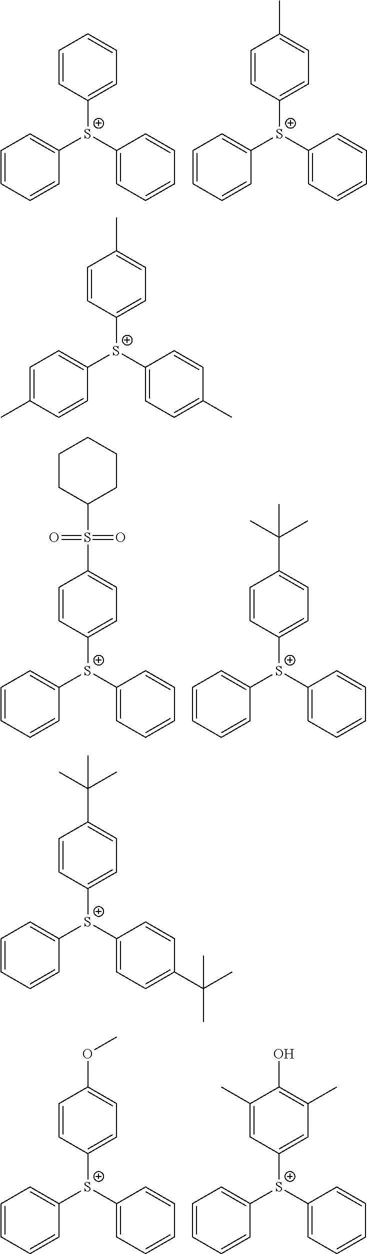

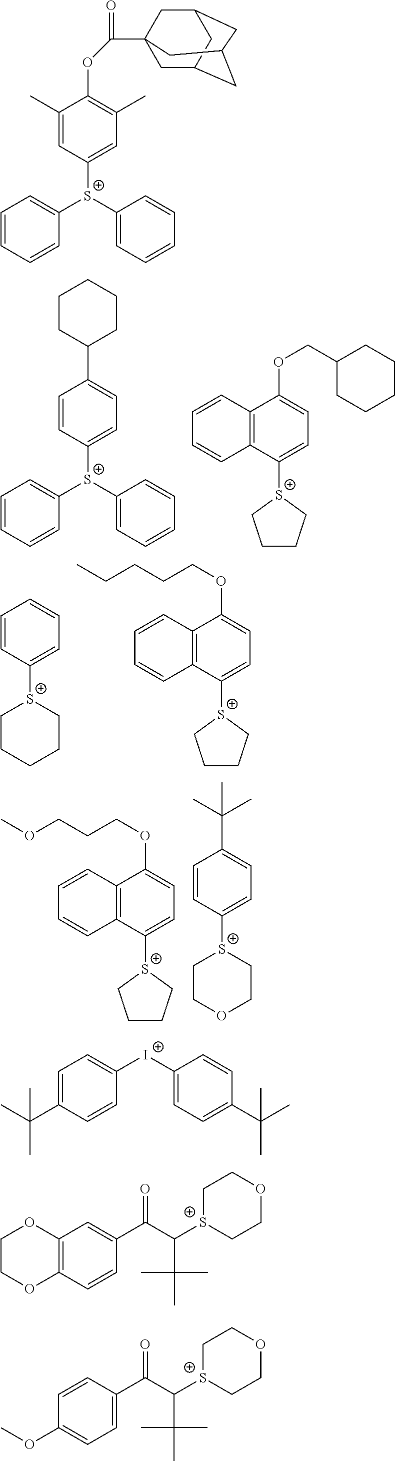

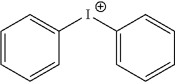

Preferred examples of the anion Z⁻ in each of General Formula (ZI) and General Formula (ZII), Zc⁻ in General Formula (ZI-3), and Z⁻ in General Formula (ZI-4) are shown below.

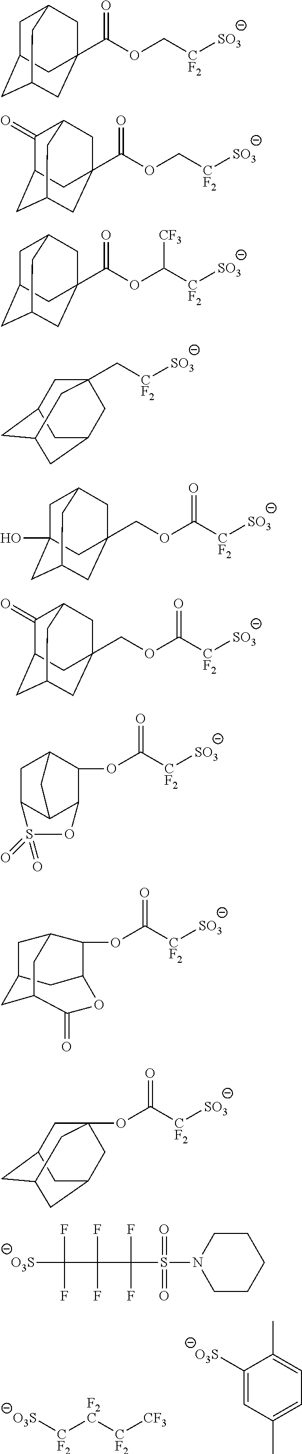

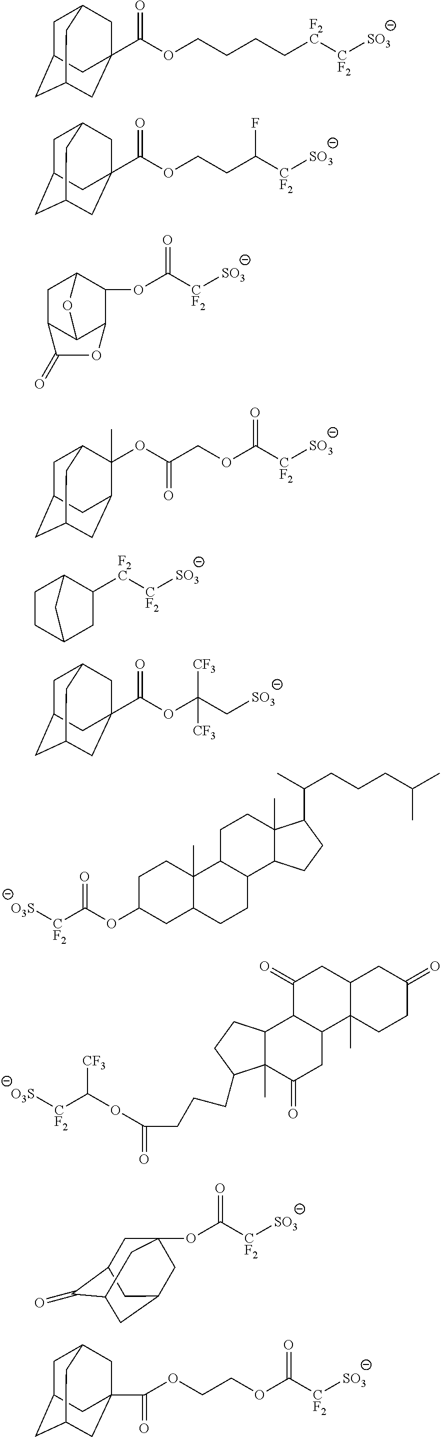

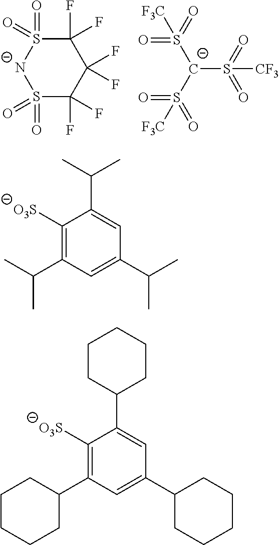

Any combination of the cations and the anions can be used as the photoacid generator.

The acid generator may be in a form of a low-molecular-weight compound or a form incorporated into a part of a polymer. Further, a combination of the form of a low-molecular-weight compound and the form incorporated into a part of a polymer may also be used.

The photoacid generator is preferably in the form of a low-molecular-weight compound.

In a case where the acid generator is in the form of a low-molecular-weight compound, the molecular weight is preferably 3,000 or less, more preferably 2,000 or less, and still more preferably 1,000 or less.

In a case where the acid generator is incorporated into a part of a polymer, it may be incorporated into a part of the resin (A) described above or in a resin other than the resin (A).

The acid generators may be used singly or in combination of two or more kinds thereof.

A content of the acid generator (in a case where the photoacid generators are present in a plurality of kinds, a total content thereof) in the composition of the embodiment of the present invention is preferably 0.1% to 35% by mass, more preferably 0.5% to 25% by mass, still more preferably 3% to 20% by mass, and particularly preferably 3% to 15% by mass, with respect to a total solid content of the composition of the embodiment of the present invention.

In a case where the compound represented by General Formula (ZI-3) or (ZI-4) is included as the acid generator, the content of the acid generator included in the composition (in a case where the acid generators are present in a plurality of kinds, a total content thereof) is preferably 5% to 35% by mass, and more preferably 7% to 30% by mass, with respect to the total solid content of the composition.

<Acid Diffusion Control Agent (D)>

The composition of the embodiment of the present invention preferably contains an acid diffusion control agent (D). The acid diffusion control agent (D) acts as a quencher that suppresses a reaction of the acid-decomposable resin in the unexposed area by excessive generated acids by trapping the acids generated from an acid generator and the like upon exposure. For example, a basic compound (DA), a basic compound (DB) having basicity reduced or lost upon irradiation with actinic rays or radiation, an onium salt (DC) which is a weak acid relative to an acid generator, a low-molecular-weight compound (DD) having a nitrogen atom and a group that leaves by the action of an acid, an onium salt compound (DE) having a nitrogen atom in the cationic moiety, can be used as the acid diffusion control agent. In the composition of the embodiment of the present invention, a known acid diffusion control agent can be appropriately used. For example, the known compounds disclosed in paragraphs <0627> to <0664> of the specification of US2016/0070167A1, paragraphs <0095> to <0187> of the specification of US2015/0004544A1, paragraphs <0403> to <0423> of the specification of US2016/0237190A1, and paragraphs <0259> to <0328> of the specification of US2016/0274458A1 can be suitably used as the acid diffusion control agent (D).

As the basic compound (DA), compounds having structures represented by Formulae (A) to (E) are preferable.

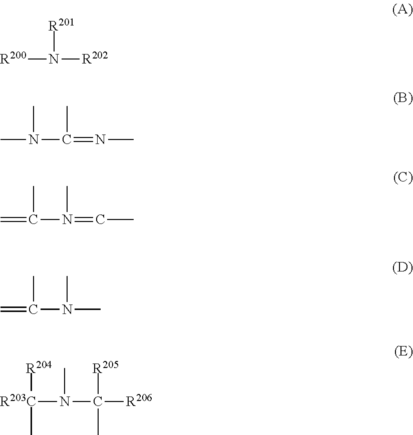

In General Formulae (A) and (E),

R²⁰⁰, R²⁰¹, and R²⁰² may be the same as or different from each other, and each independently represent a hydrogen atom, an alkyl group (preferably having 1 to 20 carbon atoms), a cycloalkyl group (preferably having 3 to 20 carbon atoms), or an aryl group (having 6 to 20 carbon atoms). R²⁰¹ and R²⁰² may be bonded to each other to form a ring.

R²⁰³, R²⁰⁴, R²⁰⁵, and R²⁰⁶ may be the same as or different from each other and each independently represent an alkyl group having 1 to 20 carbon atoms.

The alkyl group in each of General Formulae (A) and (E) may have a substituent or may be unsubstituted.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in each of General Formulae (A) and (E) are more preferably unsubstituted.

As the basic compound (DA), guanidine, aminopyrrolidine, pyrazole, pyrazoline, piperazine, aminomorpholine, aminoalkylmorpholine, piperidine, or the like is preferable; and a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond, or the like is more preferable.

The basic compound (DB) having basicity reduced or lost upon irradiation with actinic rays or radiation (hereinafter also referred to as a “compound (DB)”) is a compound which has a proton-accepting functional group, and decomposes under irradiation with actinic rays or radiation to exhibit deterioration in proton-accepting properties, no proton-accepting properties, or a change from the proton-accepting properties to acidic properties.

The proton-accepting functional group refers to a functional group having a group or an electron which is capable of electrostatically interacting with a proton, and for example, means a functional group with a macrocyclic structure, such as a cyclic polyether, or a functional group having a nitrogen atom having an unshared electron pair not contributing to π-conjugation. The nitrogen atom having an unshared electron pair not contributing to π-conjugation is, for example, a nitrogen atom having a partial structure represented by the following formula.

[symbol] [symbol] [symbol] Unshared electron pair

Preferred examples of the partial structure of the proton-accepting functional group include crown ether, azacrown ether, primary to tertiary amine, pyridine, imidazole, and pyrazine structures.

The compound (DB) decomposes upon irradiation with actinic rays or radiation to generate a compound exhibiting deterioration in proton-accepting properties, no proton-accepting properties, or a change from the proton-accepting properties to acidic properties. Here, exhibiting deterioration in proton-accepting properties, no proton-accepting properties, or a change from the proton-accepting properties to acidic properties means a change of proton-accepting properties due to the proton being added to the proton-accepting functional group, and specifically a decrease in the equilibrium constant at chemical equilibrium in a case where a proton adduct is generated from the compound (DB) having the proton-accepting functional group and the proton.

The proton-accepting properties can be confirmed by performing pH measurement.

The acid dissociation constant pKa of the compound generated by decomposition of the compound (DB) upon irradiation with actinic rays or radiation preferably satisfies pKa <−1, more preferably satisfies −13<pKa <−1, and still more preferably satisfies 13<pKa <−3.

The acid dissociation constant pKa refers to an acid dissociation constant pKa in an aqueous solution, and is defined, for example, in Chemical Handbook (II) (Revised 4th Edition, 1993, compiled by the Chemical Society of Japan, Maruzen Company, Ltd.). A lower value of the acid dissociation constant pKa indicates higher acid strength. Specifically, the acid dissociation constant pKa in an aqueous solution can be actually measured by using an infinite-dilution aqueous solution and measuring the acid dissociation constant at 25° C. Alternatively, the acid dissociation constant pKa can also be determined using the following software package 1 by computation from a value based on a Hammett substituent constant and the database of publicly known literature values. Any of the values of pKa described in the present specification indicate values determined by calculation using the software package.

Software Package 1: Advanced Chemistry Development (ACD/Labs) Software V 8.14 for Solaris (1994-2007 ACD/Labs).

In the composition of the embodiment of the present invention, the onium salt (DC) which is a weak acid relative to an acid generator can be used as the acid diffusion control agent.

In a case where the acid generator and the onium salt that generates an acid which is a weak acid relative to an acid generated from the acid generator are mixed and used, an acid generated from the acid generator upon irradiation with actinic rays or radiation produces an onium salt having a strong acid anion by discharging the weak acid through salt exchange in a case where the acid collides with an onium salt having an unreacted weak acid anion. In this process, the strong acid is exchanged with a weak acid having a lower catalytic ability, and thus, the acid is apparently deactivated and the acid diffusion can be controlled.

As the onium salt which is a weak acid relative to the acid generator, compounds represented by General Formulae (d1-1) to (d1-3) are preferable.

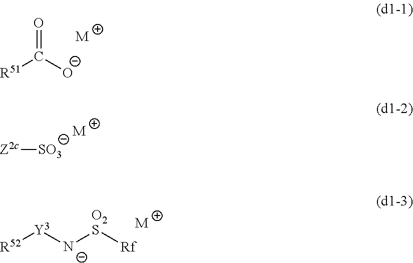

In the formula, R⁵¹ is a hydrocarbon group which may have a substituent, Z^{2c} is a hydrocarbon group having 1 to 30 carbon atoms, which may have a substituent (provided that carbon adjacent to S is not substituted with a fluorine atom), R⁵² is an organic group, Y³ is a linear, branched or cyclic alkylene group or an arylene group, Rf is a hydrocarbon group including a fluorine atom, and M⁺'s are each independently an ammonium cation, a sulfonium cation, or an iodonium cation.

Preferred examples of the sulfonium cation or iodonium cation represented by M⁺ include the sulfonium cation exemplified for General Formula (ZI) and the iodonium cation exemplified for General Formula (ZII).

The onium salt (DC) which is a weak acid relative to an acid generator may be a compound having a cationic moiety and an anionic moiety in the same molecule, in which the cationic moiety and the anionic moiety are linked by a covalent bond (hereinafter also referred to as a “compound (DCA)”).

The compound (DCA) is preferably a compound represented by any of General Formulae (C-1) to (C-3).

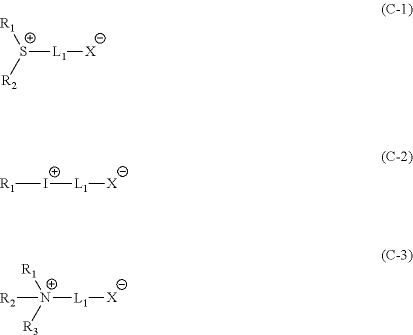

In General Formulae (C-1) to (C-3),

R₁, R₂, and R₃ each independently represent a substituent having 1 or more carbon atoms.

L₁ represents a divalent linking group that links a cationic moiety with an anionic moiety, or a single bond.

—X⁻ represents an anionic moiety selected from −COO⁻, —SO₃⁻, —SO₂⁻, and —N⁻—R₄. R₄ represents a monovalent substituent having at least one of a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to each other to form a ring structure. Further, in General Formula (C-3), two of R₁ to R₃ together represent one divalent substituent, and may be bonded to an N atom by a double bond.

Examples of the substituent having 1 or more carbon atoms in each of R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group. The alkyl group, a cycloalkyl group, or the aryl group is preferable.

Examples of L₁ as a divalent linking group include a linear or branched alkylene group, a cycloalkylene group, an arylene group, a carbonyl group, an ether bond, an ester bond, an amide bond, an urethane bond, an urea bond, and a group formed by a combination of two or more of these groups. L₁ is preferably the alkylene group, the arylene group, the ether bond, the ester bond, and the group formed by a combination of two or more of these groups.

The low-molecular-weight compound (DD) having a nitrogen atom and having a group that leaves by the action of an acid (hereinafter also referred to as a “compound (DD)”) is preferably an amine derivative having a group that leaves by the action of an acid on the nitrogen atom.

As the group that leaves by the action of an acid, an acetal group, a carbonate group, a carbamate group, a tertiary ester group, a tertiary hydroxyl group, or a hemiaminal ether group is preferable, and the carbamate group or the hemiaminal ether group is more preferable.

The molecular weight of the compound (DD) is preferably 100 to 1,000, more preferably 100 to 700, and still more preferably 100 to 500.

The compound (DD) may have a carbamate group having a protective group on the nitrogen atom. The protective group constituting the carbamate group is represented by General Formula (d-1).

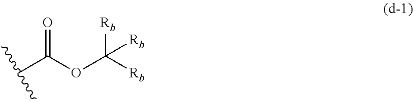

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be linked to each other to form a ring.

The alkyl group, the cycloalkyl group, the aryl group, or the aralkyl group represented by R_{b} may be each independently substituted with a functional group such as a hydroxyl group, a cyano group, an amino group, a pyrrolidino group, a piperidino group, a morpholino group, and an oxo group, an alkoxy group, or a halogen atom. The same applies to the alkoxyalkyl group represented by R_{b}.

As R_{b}, a linear or branched alkyl group, a cycloalkyl group, or an aryl group is preferable, and the linear or branched alkyl group, or the cycloalkyl group is more preferable.

Examples of the ring formed by the mutual linking of two of R_{b}'s include an alicyclic hydrocarbon, an aromatic hydrocarbon, a heterocyclic hydrocarbon, and derivatives thereof.

Examples of the specific structure of the group represented by General Formula (d-1) include, but are not limited to, the structures disclosed in paragraph <0466> of the specification of US2012/0135348A1.

The compound (DD) preferably has a structure represented by General Formula (6).

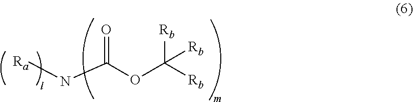

In General Formula (6),

l represents an integer of 0 to 2, m represents an integer of 1 to 3, and these satisfy 1+m=3.

Rₐ represents a hydrogen atom, an alkyl group, a cycloalkyl group, an aryl group, or an aralkyl group. In a case where 1 is 2, two of Ra's may be the same as or different from each other, and the two of Rₐ's may be linked to each other to form a heterocycle with the nitrogen atom in the formula. This heterocycle may include a heteroatom other than the nitrogen atom in the formula.

R_{b} has the same meaning as R_{b} in General Formula (d-1), and preferred examples are also the same.

In General Formula (6), the alkyl group, the cycloalkyl group, the aryl group, and the aralkyl group as Rₐ may be each independently substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (such the alkyl group, the cycloalkyl group, the aryl group, and the aralkyl group may be substituted with the groups as described above) of Rₐ include the same groups as the specific examples as described above with respect to R_{b}.

Specific structures of the particularly preferred compound (DD) in the present invention include, but are not limited to, the compounds disclosed in paragraph <0475> of the specification of US2012/0135348A1.

The onium salt compound (DE) having a nitrogen atom in the cationic moiety (hereinafter also referred to as a “compound (DE)”) is preferably a compound having a basic site including a nitrogen atom in the cationic moiety. The basic site is preferably an amino group, and more preferably an aliphatic amino group. All of the atoms adjacent to the nitrogen atom in the basic site are still more preferably hydrogen atoms or carbon atoms. In addition, from the viewpoint of improving basicity, it is preferable that an electron-withdrawing functional group (such as a carbonyl group, a sulfonyl group, a cyano group, and a halogen atom) is not directly linked to the nitrogen atom.

Preferred specific structures of the compound (DE) include, but are not limited to, the compounds disclosed in paragraph <0203> of US2015/0309408A1.

Preferred examples of the acid diffusion control agent (D) are shown below.

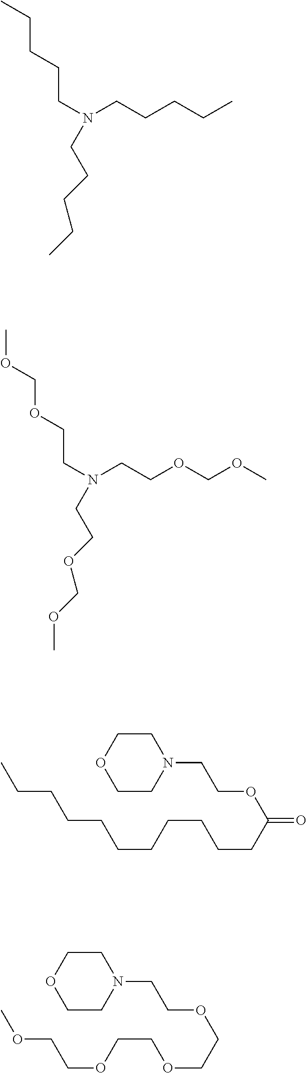

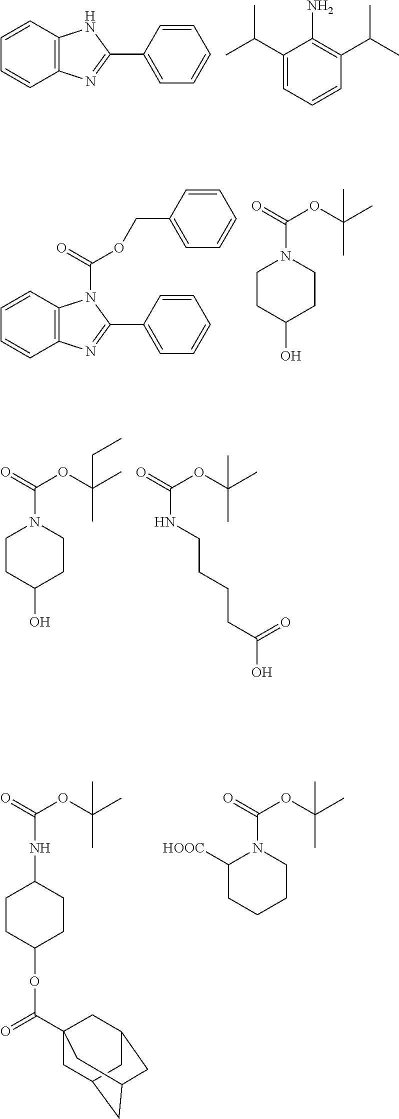

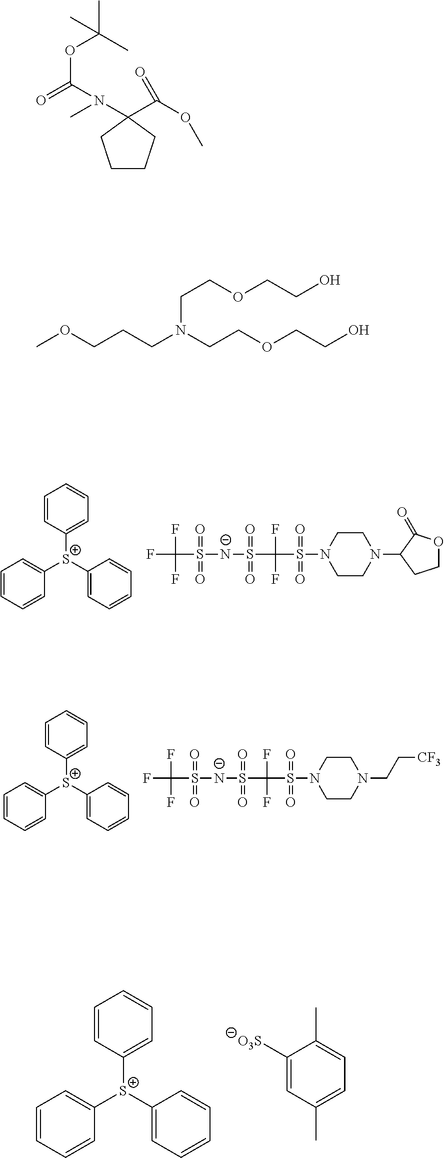

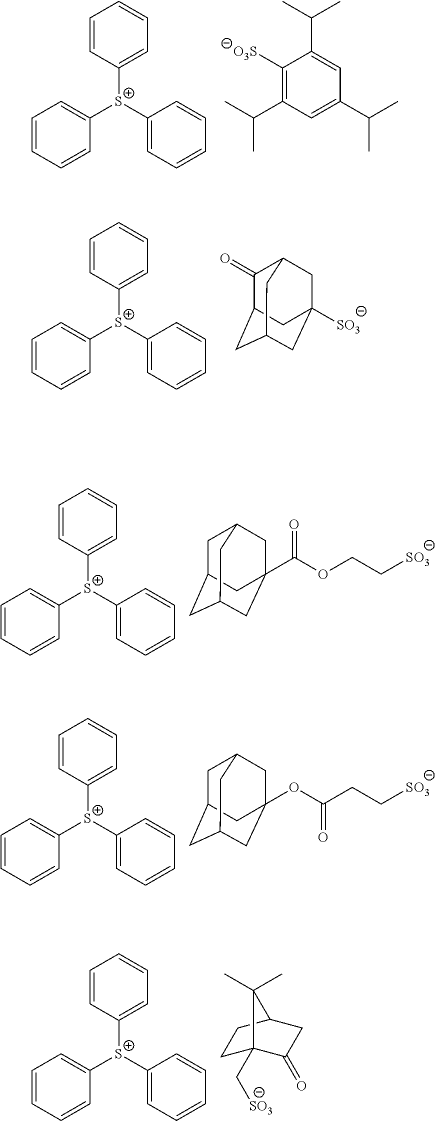

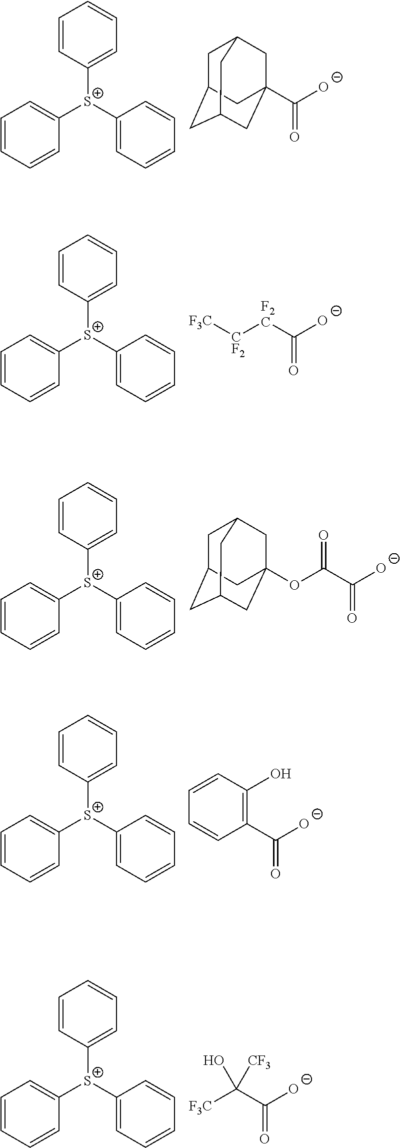

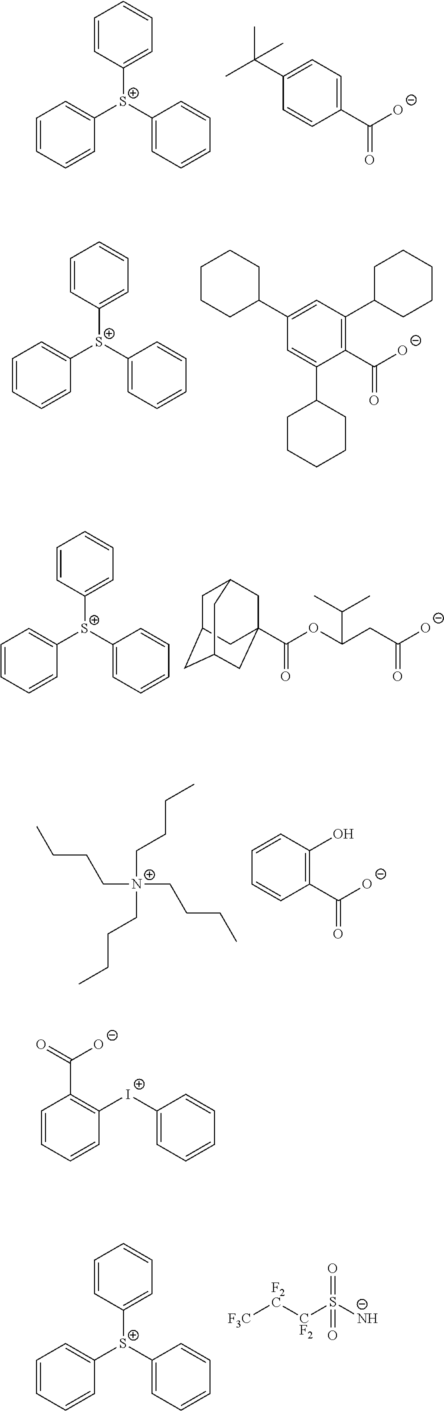

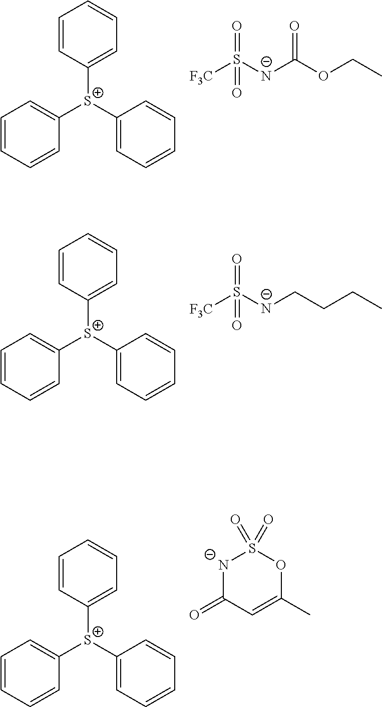

In the composition of the embodiment of the present invention, the acid diffusion control agents (D) may be used singly or in combination of two or more kinds thereof.

The content of the acid diffusion control agent (D) (in a case where the acid diffusion control agents are present in a plurality of kinds, a total content thereof) in the composition is preferably 0.1% to 20% by mass, and more preferably 1% to 15% by mass, with respect to the total solid content of the composition.

<Solvent (F)>

The composition of the embodiment of the present invention usually contains a solvent.

In the composition of the embodiment of the present invention, a known resist solvent can be appropriately used. For example, the known solvents disclosed in paragraphs <0665> to <0670> of the specification of US2016/0070167A1, paragraphs <0210> to <0235> of the specification of US2015/0004544A1, paragraphs <0424> to <0426> of the specification of US2016/0237190A1, and paragraphs <0357> to <0366> of the specification of US2016/0274458A1 can be suitably used.

Examples of the solvent which can be used in preparation of the composition include organic solvents such as alkylene glycol monoalkyl ether carboxylate, alkylene glycol monoalkyl ether, alkyl lactic ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

As the organic solvent, a mixed solvent obtained by mixing a solvent containing a hydroxyl group in the structure and a solvent containing no hydroxyl group may be used.

As the solvent containing a hydroxyl group and the solvent containing no hydroxyl group, the above-mentioned exemplary compounds can be appropriately selected, but as the solvent containing a hydroxyl group, alkylene glycol monoalkyl ether or alkyl lactate is preferable, and propylene glycol monomethyl ether (PGME), propylene glycol monoethyl ether (PGEE), methyl 2-hydroxyisobutyrate, or ethyl lactate is more preferable. Further, as the solvent containing no hydroxyl group, alkylene glycol monoalkyl ether acetate, alkyl alkoxypropionate, a monoketone compound which may contain a ring, a cyclic lactone, alkyl acetate, or the like is preferable, and among these, propylene glycol monomethyl ether acetate (PGMEA), ethyl ethoxypropionate, 2-heptanone, α-butyrolactone, cyclohexanone, cyclopentanone, or butyl acetate is more preferable, and propylene glycol monomethyl ether acetate, γ-butyrolactone, ethyl ethoxypropionate, cyclohexanone, cyclopentanone, or 2-heptanone are more preferable. As a solvent containing no hydroxyl group, propylene carbonate is also preferable.

A mixing ratio (mass ratio) of the solvent containing a hydroxyl group to the solvent containing no hydroxyl group is 1/99 to 99/1, preferably 10/90 to 90/10, and more preferably 20/80 to 60/40. A mixed solvent containing 50% by mass or more of the solvent containing no hydroxyl group is preferable from the viewpoint of coating evenness.

The solvent preferably includes propylene glycol monomethyl ether acetate, and may be a single solvent of propylene glycol monomethyl ether acetate or a mixed solvent of two or more kinds containing propylene glycol monomethyl ether acetate.

<Crosslinking Agent (G)>

The composition of the embodiment of the present invention may contain a compound (hereinafter also referred to as a crosslinking agent (G)) which crosslinks a resin by the action of an acid. As the crosslinking agent (G), a known compound can be appropriately used. For example, the known compounds disclosed in paragraphs <0379> to <0431> of the specification of US2016/0147154A1 and paragraphs <0064> to <0141> of the specification of US2016/0282720A1 can be suitably used as the crosslinking agent (G).

The crosslinking agent (G) is a compound having a crosslinkable group capable of crosslinking a resin, and examples of the crosslinkable group include a hydroxymethyl group, an alkoxymethyl group, an acyloxymethyl group, an alkoxymethyl ether group, an oxirane ring, and an oxetane ring.

The crosslinkable group is preferably a hydroxymethyl group, an alkoxymethyl group, an oxirane ring, or an oxetane ring.

The crosslinking agent (G) is preferably a compound (also including a resin) having two or more crosslinkable groups.

The crosslinking agent (G) is more preferably a phenol derivative having a hydroxymethyl group or an alkoxymethyl group, a urea compound (a compound having a urea structure) or a melamine compound (a compound having a melamine structure).

The crosslinking agents may be used singly or in combination of two or more kinds thereof.

A content of the crosslinking agent (G) is preferably 1% to 50% by mass, more preferably 3% to 40% by mass, and still more preferably 5% to 30% by mass, with respect to the total solid content of the resist composition.

<Surfactant (H)>

The composition of the embodiment of the present invention may or may not contain a surfactant. In a case where a surfactant is contained, a fluorine-based and/or silicon-based surfactant (specifically a fluorine-based surfactant, a silicon-based surfactant, or a surfactant having both a fluorine atom and a silicon atom) is preferable.

By allowing the composition of the embodiment of the present invention to contain the surfactant, in a case where an exposure light source of 250 nm or less, in particular, 220 nm or less is used, it is possible to obtain a resist pattern with good sensitivity and resolution and less adhesiveness and development defects.

Examples of the fluorine-based and/or silicon-based surfactants include the surfactants described in paragraph <0276> of the specification of US2008/0248425A.

In addition, other surfactants than the fluorine-based and/or silicon-based surfactants described in paragraph <0280> of the specification of US2008/0248425A can also be used.

These surfactants may be used singly or in combination of two or more kinds thereof.

In a case where the composition of the embodiment of the present invention contains a surfactant, a content of the surfactant is preferably 0.0001% to 2% by mass, and more preferably 0.0005% to 1% by mass, with respect to the total solid content of the composition.

<Resin (J)>

In a case where the composition of the embodiment of the present invention contains a crosslinking agent (G), the composition of the embodiment of the present invention preferably contains an alkali-soluble resin (J) having a phenolic hydroxyl group (hereinafter also referred to as a “resin (J)”). The resin (J) preferably contains a repeating unit having a phenolic hydroxyl group.

In this case, it is typical that a negative tone pattern is preferably formed.

Further, the crosslinking agent (G) may be in the state of being supported on the resin (J).

The resin (J) may contain the above-mentioned acid-decomposable group.

The repeating unit having a phenolic hydroxyl group contained in the resin (J) is not particularly limited, but is preferably a repeating unit represented by General Formula (II).

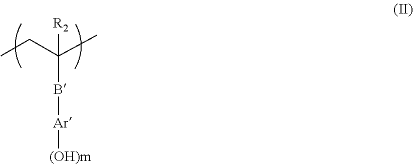

In General Formula (II),

R₂ represents a hydrogen atom, an alkyl group (preferably a methyl group) which may have a substituent, or a halogen atom (preferably a fluorine atom).

B′ represents a single bond or a divalent linking group.

Ar′ represents an aromatic ring group.

m represents an integer of 1 or more.

The resin (J) may be used singly or in combination of two or more kinds thereof.

The content of the resin (J) in the total solid content of the composition of the embodiment of the present invention is generally 30% by mass or more. The content of the resin (J) is preferably 40% by mass or more, and more preferably 50% by mass or more. An upper limit thereof is not particularly limited, but is preferably 99% by mass or less, more preferably 90% by mass or less, and still more preferably 85% by mass or less.

As the resin (J), the resins disclosed in paragraphs <0142> to <0347> of US2016/0282720A1 can be suitably used.

(Other Additives)

The composition of the embodiment of the present invention may contain an acid proliferation agent, a dye, a plasticizer, a photosensitizer, a light absorber, an alkali-soluble resin, a dissolution inhibitor, a dissolution accelerator, or the like.

<Preparation Method>

The film thickness of an actinic ray-sensitive film or a radiation-sensitive film formed of the composition of the embodiment of the present invention is preferably 90 nm or less, and more preferably 85 nm or less, from the viewpoint of improving resolving power. Such a film thickness can be obtained by setting the concentration of the solid content in the composition to an appropriate range to provide the composition with a suitable viscosity and improve the coating property or the film forming property.

The concentration of the solid content in the composition of the embodiment of the present invention is usually 1.0% to 10% by mass, preferably 2.0% to 5.7% by mass, and more preferably 2.0% to 5.3% by mass. The concentration of the solid content is a mass percentage of other resist components excluding the solvent with respect to the total mass of the composition.

The composition of the embodiment of the present invention is used by dissolving the components in a predetermined organic solvent, and preferably the mixed solvent, and filtering the solution through a filter and applying it onto a predetermined support (substrate). The pore size of a filter for use in filtration through the filter is preferably pore size of 0.1 μm or less, more preferably 0.05 μm or less, and still more preferably 0.03 μm or less. The filter is preferably a polytetrafluoroethylene-made, polyethylene-made, or nylon-made filter. In the filtration through a filter as shown in the specification of JP2002-062667A, circulating filtration may be performed or the filtration may be performed by connecting plural kinds of filters in series or in parallel. In addition, the composition may be filtered in plural times. Furthermore, the composition may be subjected to a deaeration treatment or the like before or after filtration through a filter.

<Applications>

The composition of the embodiment of the present invention relates to an actinic ray-sensitive or radiation-sensitive resin composition having properties changed by undergoing a reaction upon irradiation with actinic rays or radiation. More specifically, the composition of the embodiment of the present invention relates to an actinic ray-sensitive or radiation-sensitive resin composition which is used in a step of manufacturing a semiconductor such as an integrated circuit (IC), for manufacture of a circuit board for a liquid crystal, a thermal head, or the like, the manufacture of a mold structure for imprinting, other photofabrication steps, or production of a planographic printing plate or an acid-curable composition. A resist pattern formed in the present invention can be used in an etching step, an ion implantation step, a bump electrode forming step, a rewiring forming step, a microelectromechanical system (MEMS), or the like.

[Actinic Ray-Sensitive or Radiation-Sensitive Film and Pattern Forming Method]

The present invention also relates to a pattern forming method using the actinic ray-sensitive or radiation-sensitive resin composition. Hereinafter, the pattern forming method of the embodiment of the present invention will be described. Further, the actinic ray-sensitive or radiation-sensitive film (typically the resist film) of the embodiment of the present invention will be described together with the description of the pattern forming method. The actinic ray-sensitive or radiation-sensitive film of the present invention preferably has a dynamic receding contact angle with respect to water of 75° or more, and more preferably 80° or more before being exposed.

The pattern forming method of the embodiment of the present invention has:

(i) a step of forming an actinic ray-sensitive or radiation-sensitive film on a support with the above-mentioned actinic ray-sensitive or radiation-sensitive resin composition (film forming step),

(ii) a step of irradiating the actinic ray-sensitive or radiation-sensitive film with actinic rays or radiation (exposing step), and

(iii) a step of developing the actinic ray-sensitive or radiation-sensitive film irradiated with actinic rays or radiation using a developer (developing step).

The pattern forming method of the embodiment of the present invention is not particularly limited as long as it includes the steps (i) to (iii), and may further have the following steps.

In the pattern forming method of the embodiment of the present invention, the exposing method in the exposing step (ii) may be liquid immersion exposure.

The pattern forming method of the embodiment of the present invention preferably includes a prebaking (PB) step (iv) before the exposing step (ii).

The pattern forming method of the embodiment of the present invention preferably includes a post-exposure baking (PEB) step (v) after the exposing step (ii) and before the developing step (iii).

The pattern forming method of the embodiment of the present invention may include the exposing step (ii) a plurality of times.

The pattern forming method of the embodiment of the present invention may include the prebaking step (iv) a plurality of times.

The pattern forming method of the embodiment of the present invention may include the post-exposure baking step (v) a plurality of times.

In the pattern forming method of the embodiment of the present invention, the film forming step (i), the exposing step (ii), and the developing step (iii) described above can be performed by a generally known method.

In addition, a resist underlayer film (for example, spin on glass (SOG), spin on carbon (SOC), and an antireflection film) may be formed between the actinic ray-sensitive or radiation-sensitive film and the support, as desired. As the resist underlayer film, known organic or inorganic materials can be appropriately used.

A protective film (topcoat) may be formed on the actinic ray-sensitive or radiation-sensitive film. As the protective film, a known material can be appropriately used. For example, the compositions for forming a protective film disclosed in the specification of US2007/0178407A, the specification of US2008/0085466A, the specification of US2007/0275326A, the specification of US2016/0299432A, the specification of US2013/0244438A, or the specification of WO2016/157988A can be suitably used. The composition for forming a protective film preferably includes the above-mentioned acid diffusion control agent.

The protective film may be formed on the actinic ray-sensitive or radiation-sensitive film containing a hydrophobic resin.

As the hydrophobic resin, known resins can be appropriately selected and used singly or as a mixture. For example, the known resins disclosed in paragraphs <0451> to <0704> of the specification of US2015/0168830A1 and paragraphs <0340> to <0356> of the specification of US2016/0274458A1 can be suitably used as the hydrophobic resin. In addition, the repeating units disclosed in paragraphs <0177> to <0258> of the specification of US2016/0237190A1 are also preferable as the repeating units constituting the hydrophobic resin.

The support is not particularly limited, and a substrate which is generally used in a step of manufacturing a semiconductor such as an IC, and a process for manufacturing a circuit board for a liquid crystal, a thermal head, or the like, and other lithographic processes of photofabrication can be used. Specific examples of the support include an inorganic substrate such as silicon, SiO₂, and SiN.

For any of the prebaking step (iv) and the post-exposure baking step (v), the baking temperature is preferably 70° C. to 130° C., and more preferably 80° C. to 120° C.

For any of the prebaking step (iv) and the post-exposure baking step (v), the baking time is preferably 30 to 300 seconds, more preferably 30 to 180 seconds, and still more preferably 30 to 90 seconds.

The baking may be performed using a unit included in an exposure apparatus and a development device, or may also be performed using a hot plate or the like.

A light source wavelength used in the exposing step is not particularly limited, and examples thereof include infrared rays, visible light, ultraviolet rays, far ultraviolet rays, extreme ultraviolet rays (EUV), X-rays, and electron beams. Among those, far ultraviolet rays are preferable, and a wavelength thereof is preferably 250 nm or less, more preferably 220 nm or less, and still more preferably 1 to 200 nm. Specific examples thereof include a KrF excimer laser (248 nm), an ArF excimer laser (193 nm), an F₂ excimer laser (157 nm), X-rays, EUV (13 nm), and electron beams, and the KrF excimer laser, the ArF excimer laser, EUV, or the electron beams are preferable.

In the developing step (iii), the developer may be either an alkali developer or a developer containing an organic solvent (hereinafter also referred to as an organic developer).

As the alkali developer, a quaternary ammonium salt typified by tetramethylammonium hydroxide is usually used, but in addition to this, an alkaline aqueous solution such as an inorganic alkali, primary to tertiary amines, an alcoholamine, and a cyclic amine can also be used.

Furthermore, the alkali developer may contain an appropriate amount of alcohols and/or a surfactant. The alkali concentration of the alkali developer is usually 0.1% to 20% by mass. The pH of the alkali developer is usually 10 to 15.

A time period for performing development using the alkali developer is usually 10 to 300 seconds.

The alkali concentration, the pH, and the development time using the alkali developer can be appropriately adjusted depending on a pattern formed.

The organic developer is preferably a developer containing at least one organic solvent selected from the group consisting of a ketone-based solvent, an ester-based solvent, an alcohol-based solvent, an amide-based solvent, an ether-based solvent, and a hydrocarbon-based solvent.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butyrate, methyl 2-hydroxyisobutyrate, isoamyl acetate, isobutyl isobutyrate, and butyl propionate.

As the alcohol-based solvent, the amide-based solvent, the ether-based solvent, and the hydrocarbon-based solvent, the solvents disclosed in paragraphs <0715> to <0718> of the specification of US2016/0070167A1 can be used.

A plurality of the solvents may be mixed or the solvent may be used in admixture with a solvent other than those described above or water. The moisture content in the entire developer is preferably less than 50% by mass, more preferably less than 20% by mass, and still more preferably less than 10% by mass, and particularly preferably, moisture is not substantially contained.

The content of the organic solvent with respect to the organic developer is preferably from 50% by mass to 100% by mass, more preferably from 80% by mass to 100% by mass, still more preferably from 90% by mass to 100% by mass, and particularly preferably from 95% by mass to 100% by mass, with respect to the total amount of the developer.

The organic developer can contain an appropriate amount of a known surfactant, as desired.

The content of the surfactant is usually 0.001% to 5% by mass, preferably 0.005% to 2% by mass, and still more preferably 0.01% to 0.5% by mass, with respect to the total amount of the developer.

The organic developer may include the above-described acid diffusion control agent.

As the developing method, for example, a method in which a substrate is dipped in a tank filled with a developer for a certain period of time (a dip method), a method in which development is performed by heaping a developer up onto the surface of a substrate by surface tension, and then leaving it to stand for a certain period of time (a puddle method), a method in which a developer is sprayed on the surface of a substrate (a spray method), a method in which a developer is continuously jetted onto a substrate spun at a constant rate while scanning a developer jetting nozzle at a constant rate (a dynamic dispense method), or the like can be applied.

A combination of a step of performing development using an aqueous alkali solution (an alkali developing step) and a step of performing development using a developer including an organic solvent (an organic solvent developing step) may be used. Thus, a finer pattern can be formed since a pattern can be formed by keeping only a region with an intermediate exposure intensity from not being dissolved.

It is preferable that the method includes a step of performing washing using a rinsing liquid (a rinsing step) after the developing step (iii).

As the rinsing liquid used in the rinsing step after the developing step with an alkali developer, for example, pure water can be used. The pure water may contain an appropriate amount of a surfactant. In this case, after the developing step or the rinsing step, a treatment for removing the developer or the rinsing liquid adhering on a pattern by a supercritical fluid may be added. In addition, after the rinsing treatment or the treatment using a supercritical fluid, a heating treatment for removing moisture remaining in the pattern may be performed.

The rinsing liquid used in the rinsing step after the developing step with a developer including an organic solvent is not particularly limited as long as the rinsing liquid does not dissolve the resist pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent include the same solvents as those described for the developer including an organic solvent.

As the rinsing liquid used in the rinsing step in this case, a rinsing liquid containing a monohydric alcohol is more preferable.

Here, examples of the monohydric alcohol used in the rinsing step include linear, branched, or cyclic monohydric alcohols. Specific examples thereof include 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, and methyl isobutyl carbinol. Examples of the monohydric alcohol having 5 or more carbon atoms include 1-hexanol, 2-hexanol, 4-methyl-2-pentanol, 1-pentanol, 3-methyl-1-butanol, and methyl isobutyl carbinol.

The respective components in a plural number may be mixed or the components may also be used in admixture with an organic solvent other than the solvents.

The moisture content in the rinsing liquid is preferably 10% by mass or less, more preferably 5% by mass or less, and still more preferably 3% by mass or less. By setting the moisture content to 10% by mass or less, good development characteristics are obtained.

The rinsing liquid may contain an appropriate amount of a surfactant.

In the rinsing step, the substrate that has been subjected to development using an organic developer is subjected to a washing treatment using a rinsing liquid including an organic solvent. A method for the washing treatment method is not particularly limited, but for example, a method in which a rinsing liquid is continuously jetted on a substrate rotated at a constant rate (a rotation application method), a method in which a substrate is dipped in a tank filled with a rinsing liquid for a certain period of time (a dip method), a method in which a rinsing liquid is sprayed on a substrate surface (a spray method), and the like can be applied. Among those, it is preferable that a washing treatment is carried out using the rotation application method, and a substrate is rotated at a rotation speed of 2,000 to 4,000 rpm after washing, thereby removing the rinsing liquid from the substrate. Furthermore, it is also preferable that the method includes a baking step after the rinsing step (postbaking). The developer and the rinsing liquid remaining between and inside the patterns are removed by the baking step. In the baking step after the rinsing step, the baking temperature is typically 40° C. to 160° C., and preferably 70° C. to 95° C., and the baking time is typically 10 seconds to 3 minutes, and preferably 30 seconds to 90 seconds.

It is preferable that various materials (for example, a resist solvent, a developer, a rinsing liquid, a composition for forming an antireflection film, and a composition for forming a topcoat) used in the actinic ray-sensitive or radiation-sensitive resin composition of the embodiment of the present invention, and the pattern forming method of the embodiment of the present invention include no impurities such as metal components, isomers, and residual monomers. The content of the impurities included in these materials is preferably 1 part per million (ppm) or less, more preferably 100 parts per trillion (ppt) or less, and still more preferably 10 ppt or less, and particularly preferably, the impurities are not substantially included (no higher than a detection limit of a measurement device).

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made, polyethylene-made, or nylon-made filter is preferable. As the filter, a filter which has been washed with an organic solvent in advance may be used. In the step of filtration using a filter, plural kinds of filters connected in series or in parallel may be used. In a case of using the plural kinds of filters, a combination of filters having different pore diameters and/or materials may be used. In addition, various materials may be filtered plural times, and the step of filtering plural times may be a circulating filtration step. As the filter, a filter having a reduced amount of eluates as disclosed in the specification of JP2016-201426A is preferable.

In addition to the filtration using a filter, removal of impurities by an adsorbing material may be performed, or a combination of filtration using a filter and an adsorbing material may be used. As the adsorbing material, known adsorbing materials can be used, and for example, inorganic adsorbing materials such as silica gel and zeolite, and organic adsorbing materials such as activated carbon can be used. Examples of the metal adsorbing agent include those disclosed in the specification of JP2016-206500A.

In addition, as a method for reducing the impurities such as metals included in the various materials, metal content selects the less material as a raw material constituting the various materials, performing filtering using a filter of the raw material constituting the various materials, equipment the inner and a method such as performing distillation under conditions suppressing as much where available equal to contamination is lined with TEFLON (registered trademark). Preferred conditions for a glass lining treatment which is performed in all steps of manufacturing equipment for synthesizing various resist component materials (a resin, a photoacid generator, and the like), and filtration with a filter which is performed on raw materials constituting various materials preferable for reducing metals to a ppt order of magnitude are the same as the above-mentioned conditions.

In order to prevent impurities from being incorporated, it is preferable that the various materials are stored in the container described in US2015/0227049A, JP2015-123351A, JP2017-013804A, or the like.

A method for enhancing the surface roughness of a pattern may be applied to a pattern formed by the pattern forming method of the embodiment of the present invention. Examples of the method for enhancing the surface roughness of a pattern include the method of treating a resist pattern by plasma of a hydrogen-containing gas, as disclosed in the specification of US2015/0104957A. In addition, known methods as described in the specification of JP2004-235468A, the specification of US2010/0020297A, and Proc. of SPIE Vol. 8328 83280N-1 “EUV Resist Curing Technique for LWR Reduction and Etch Selectivity Enhancement” may be applied.

In addition, a resist pattern formed by the method can be used as a core material (core) of the spacer process disclosed in, for example, the specification of JP1991-270227A (JP-H03-270227A) and the specification of US2013/0209941A.

[Method for Manufacturing Electronic Device]

Moreover, the present invention further relates to a method for manufacturing an electronic device, the method including the above-described pattern forming method. The electronic device manufactured by the method for manufacturing an electronic device of an embodiment of the present invention is suitably mounted on electric or electronic equipment (for example, home electronics, office automation (OA)-related equipment, media-related equipment, optical equipment, and telecommunication equipment).

[Polyester]

The present invention also relates to a polyester having at least one group represented by any of General Formulae (RZ-1) to (RZ-4).

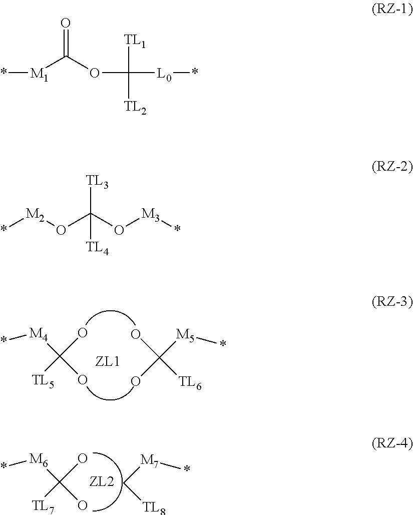

In General Formula (RZ-1), M₁ represents an oxygen atom, CR^{Z1}R^{Z2}, or NR^{Z3}, R^{Z1}, R^{Z2}, and R^{Z3} each independently represent a hydrogen atom, an alkyl group, or a halogen atom, and R^{Z1} and R^{Z2} may be bonded to each other to form a ring. TL₁ and TL₂ each independently represent a hydrogen atom, an alkyl group, a cycloalkyl group, an aryl group, or a halogen atom, and TL₁ and TL₂ may be bonded to each other to form a ring. L₀ represents a single bond or an alkylene group. L₀ and any one of TL₁ or TL₂ may be bonded to each other to form a ring. * represents a bonding position.

In General Formula (RZ-2), M₂ and M₃ each independently represent a single bond or a divalent linking group, TL₃ and TL₄ each independently represent a hydrogen atom, an alkyl group, a cycloalkyl group, or an aryl group, and TL₃ and TL₄ may be bonded to each other to form a ring. * represents a bonding position.

In General Formula (RZ-3), M₄ and M₅ each independently represent a single bond or a divalent linking group, and TL₅ and TL₆ each independently represent a hydrogen atom, an alkyl group, a cycloalkyl group, an aryl group, or a halogen atom. ZL1 represents a ring structure. ZL1 may represent a spirocyclic structure. * represents a bonding position.

In General Formula (RZ-4), M₆ and M₇ each independently represent a single bond or a divalent linking group, and TL₇ and TL₈ each independently represent a hydrogen atom, an alkyl group, a cycloalkyl group, an aryl group, or a halogen atom. ZL2 represents a ring structure. ZL2 may represent a spirocyclic structure. * represents a bonding position.

Details of General Formulae (RZ-1) to (RZ-4) are as described above.

Moreover, the present invention also relates to a polyester having at least one group represented by any of General Formulae (QZ-1) to (QZ-5).

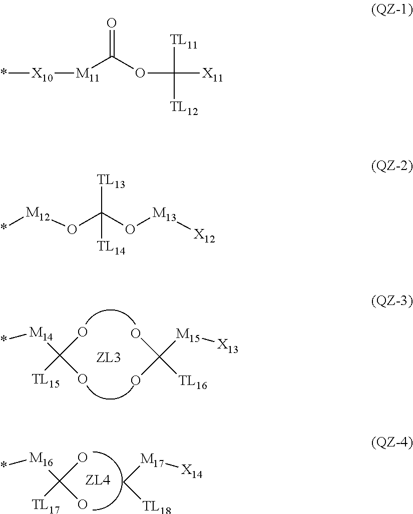

In General Formula (QZ-1), X₁₀ represents a single bond or a divalent linking group, M₁₁ represents an oxygen atom, CR^{Z4}R^{Z5}, or NR^{Z6}, and R^{Z4}, R^{Z5} and R^{Z6} each independently represent a hydrogen atom, an alkyl group, or a halogen atom, and R^{Z4} and R^{Z5} may be bonded to each other to form a ring. TL₁₁ and TL₁₂ each independently represent a hydrogen atom, an alkyl group, a cycloalkyl group, an aryl group, or a halogen atom, and TL₁₁ and TL₁₂ may be bonded to each other to form a ring. X₁₁ represents a hydrogen atom, a halogen atom, or a monovalent organic group. X₁₁ may be bonded to at least one of TL₁₁ or TL₁₂ to form a ring. * represents a bonding position.

In General Formula (QZ-2), M₁₂ and M₁₃ each independently represent a single bond or a divalent linking group, TL₁₃ and TL₁₄ each independently represent a hydrogen atom, an alkyl group, a cycloalkyl group, or an aryl group, and TL₁₃ and TL₁₄ may be bonded to each other to form a ring. X₁₂ represents a hydrogen atom, a halogen atom, or a monovalent organic group. X₁₂ may be bonded to at least one of TL₁₃ or TL₁₄ to form a ring. * represents a bonding position.

In General Formula (QZ-3), M₁₄ and M₁₅ each independently represent a single bond or a divalent linking group, and TL₁₅ and TL₁₆ each independently represent a hydrogen atom, an alkyl group, a cycloalkyl group, an aryl group, or a halogen atom. ZL3 represents a ring structure. ZL3 may represent a spirocyclic structure. X₁₃ represents a hydrogen atom, a halogen atom, or a monovalent organic group. * represents a bonding position.

In General Formula (QZ-4), M₁₆ and M₁₇ each independently represent a single bond or a divalent linking group, and TL₁₇ and TL₁₈ each independently represent a hydrogen atom, an alkyl group, a cycloalkyl group, an aryl group, or a halogen atom. ZL4 represents a ring structure. ZL4 may represent a spirocyclic structure. X₁₄ represents a hydrogen atom, a halogen atom, or a monovalent organic group. * represents a bonding position.

The details of General Formulae (QZ-1) to (QZ-5) are as described above.

Furthermore, the present invention also relates to a polyester having a group represented by General Formula (EZ-1) in the side chain.

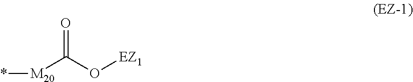

In General Formula (EZ-1), M₂₀ represents a single bond or a divalent linking group, and EZ₁ represents a monovalent organic group having an electron-withdrawing property.

General Formula (EZ-1) is as described above.

### EXAMPLES

Hereinbelow, the present invention will be described in more detail with reference to Examples. The materials, the amounts of materials used, the proportions, the treatment details, the treatment procedure, and the like shown in the Examples below may be modified as appropriate as long as the modifications do not depart from the spirit of the present invention. The scope of the present invention should not be construed as being limited to the Examples shown below.

<Synthesis of (PE-1)>

2.92 g of 2,5-dimethyl-2,5-hexanediol (manufactured by Tokyo Chemical Industry Co., Ltd.) and 30.0 g of super-dehydrated tetrahydrofuran were weighed into a flask purged with nitrogen, dissolved, and cooled to −78° C. 18.0 g of butyllithium (an about 15%-by-mass solution in hexane, about 1.6 mol/L) was added dropwise thereto over 1 hour. After the dropwise addition, 4.18 g of t-1,4-cyclohexanedicarboxylic acid dichloride (manufactured by Iharanikkei Chemical Industry Co., Ltd.) was added dropwise thereto, and the mixture was stirred for 30 minutes, then stirred at 0° C. for 1 hour, and stirred at room temperature (20° C.) for 8 hours. 20 g of tetrahydrofuran was added thereto and dissolved. This mixture was poured into 300 mL of water and filtered. The filtrate was recovered, dissolved in 30 mL of tetrahydrofuran, poured into 500 mL of water, filtered, washed with water, and dried at 40° C. for 1 day to obtain 5.3 g of a polyester (PE-1). The weight-average molecular weight and the dispersity (Mw/Mn) of the polyester (PE-1) were 11,200 and 1.95, respectively.

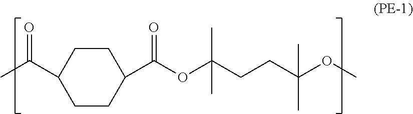

<Synthesis of (PE-2)>

2.92 g of 2,5-dimethyl-2,5-hexanediol (manufactured by Tokyo Chemical Industry Co., Ltd.) and 30.0 g of super-dehydrated tetrahydrofuran were weighed into a flask purged with nitrogen, dissolved, and cooled to −78° C. 18.0 g of butyllithium (an about 15%-by-mass solution in hexane, about 1.6 mol/L) was added dropwise thereto over 1 hour. After the dropwise addition, 4.48 g of 1,2,4,5-cyclohexanetetracarboxylic dianhydride (manufactured by Tokyo Chemical Industry Co., Ltd.) was added dropwise thereto, and the mixture was stirred for 30 minutes, then stirred at 0° C. for 1 hour, and stirred at room temperature for 8 hours. 20 g of tetrahydrofuran was added thereto and dissolved. This mixture was poured into 300 mL of water and filtered. The filtrate was recovered, dissolved in 30 mL of tetrahydrofuran, poured into 500 mL of water, filtered, washed with water, and dried at 40° C. for 1 day to obtain 9.2 g of a polyester (PE-2A). The weight-average molecular weight and the dispersity (Mw/Mn) of the polyester (PE-2A) were 10,500 and 1.97, respectively.

9.2 g of (PE-2A), 0.24 g of N,N-dimethylaminopyridine (manufactured by Wako Pure Chemical Industries, Ltd.), and 22.2 g of super-dehydrated tetrahydrofuran were weighed and dissolved at 45° C. under stirring. Subsequently, 8.4 g of 1-(3-dimethylaminopropyl)-3-ethylcarbodiimide hydrochloride (manufactured by Tokyo Chemical Industry Co., Ltd.) and 10.8 g of 1,1,1,3,3,3-hexafluoro-2-propanol (manufactured by Tokyo Chemical Industry Co., Ltd.) were added thereto, and the mixture was reacted at 45° C. for 10 hours. After the reaction, the mixture was cooled to room temperature, 300 mL of ethyl acetate was added thereto, and washed with 100 mL of 0.01 mol/L aqueous hydrochloric acid, with 300 mL of water, and then with 200 mL of a saturated aqueous sodium chloride solution, and dried with sodium sulfate, and then while filtering with a filter paper, the mixture was transferred to an eggplant-shaped flask and concentrated using an evaporator. This concentrate was dissolved in 30 mL of tetrahydrofuran, poured into 500 mL of water, filtered, and vacuum-dried at 40° C. for 8 hours to obtain 8.9 g of a polyester (PE-2). The weight-average molecular weight and the dispersity (Mw/Mn) of the polyester (PE-2) were 12,700 and 2.11, respectively.

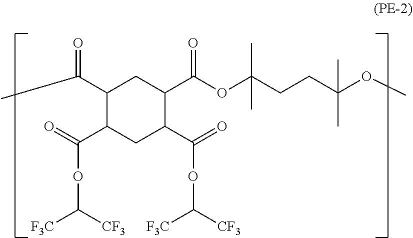

<Synthesis of (PE-3)>

4.48 g of 1,2,4,5-cyclohexanetetracarboxylic dianhydride (manufactured by Tokyo Chemical Industry Co., Ltd.), 4.40 g of 3,9-bis(1,1-dimethyl-2-hydroxyethyl)2,4,8,10-tetraoxaspiro[5.5]undecane (manufactured by Tokyo Chemical Industry Co., Ltd.), 0.24 g of N,N-dimethylaminopyridine (manufactured by Wako Pure Chemical Industries, Ltd.), 3.32 g of pyridine (manufactured by Wako Pure Chemical Industries, Ltd.), and 16.5 g of super-dehydrated tetrahydrofuran were weighed into a three-neck flask equipped with a condenser and a stirrer, and stirred at room temperature. Subsequently, the internal temperature was raised to 60° C. and the reaction was performed for 10 hours. The mixture was cooled to room temperature, neutralized by the addition of 4.42 g of methanesulfonic acid (manufactured by Wako Pure Chemical Industries, Ltd.), then poured into 500 mL of water, filtered, and dried to obtain 7.8 g of (PE-3A). The weight-average molecular weight of (PE-3A) was 12,100.

7.8 g of (PE-3A), 5.24 g of 1,1,1,3,3,3-hexafluoro-2-propanol (manufactured by Tokyo Chemical Industry, Co., Ltd.), 0.24 g of N,N-dimethylaminopyridine, and 25.0 g of super-dehydrated tetrahydrofuran (manufactured by Wako Pure Chemical Industries, Ltd.) was weighed and dissolved under stirring at 45° C. Subsequently, 8.4 g of 1-(3-dimethylaminopropyl)-3-ethylcarbodiimide hydrochloride (manufactured by Tokyo Chemical Industry Co., Ltd.) was added thereto, and the mixture was reacted at 45° C. for 10 hours. After the reaction, the mixture was cooled to room temperature, 300 mL of ethyl acetate was added thereto, the mixture was washed twice with 200 mL of water, washed with 200 mL of a saturated aqueous sodium chloride solution, and dried over sodium sulfate, and then while filtering with a filter paper, the mixture was transferred to an eggplant-shaped flask and concentrated using an evaporator. This concentrate was dissolved in 30 mL of tetrahydrofuran, poured into 500 mL of water, filtered, and vacuum-dried at 40° C. for 8 hours to obtain 7.9 g of a polyester (PE-3). The weight-average molecular weight and the dispersity (Mw/Mn) of the polyester (PE-3) were 13,200 and 2.13, respectively.

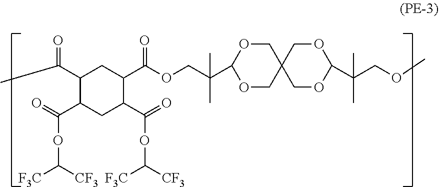

<Synthesis of (PE-4)>

6.00 g of 1-methylcyclopentanol (manufactured by Tokyo Chemical Industry Co., Ltd.) and 40.0 g of super-dehydrated tetrahydrofuran were weighed into a flask purged with nitrogen, dissolved, and cooled to −78° C. 45 mL of butyllithium (an about 15%-by-mass solution in hexane, about 1.6 mol/L) was added dropwise thereto over 1 hour. After the dropwise addition, 6.72 g of 1,2,4,5-cyclohexanetetracarboxylic dianhydride (manufactured by Tokyo Chemical Industry Co., Ltd.) was portionwise added thereto, and the mixture was stirred for 30 minutes, then stirred at 0° C. for 1 hour, and stirred at room temperature for 8 hours. 20 g of tetrahydrofuran was added thereto and dissolved. This mixture was poured into 300 mL of water, 0.5 mol/L aqueous hydrochloric acid was added thereto until pH reached 7, and the neutralized, and filtered. The filtrate was recovered, dissolved in 40 mL of tetrahydrofuran, poured into 500 mL of water, filtered, washed with water, and dried at 40° C. for 1 day to obtain 8.8 g of (PE-4A) which is a polyester raw material.

8.49 g of (PE-4A), 0.24 g of N,N-dimethylaminopyridine (manufactured by Wako Pure Chemical Industries, Ltd.), and 22.2 g of super-dehydrated tetrahydrofuran were weighed and dissolved at 45° C. under stirring. Subsequently, 8.4 g of 1-(3-dimethylaminopropyl)-3-ethylcarbodiimide hydrochloride (manufactured by Tokyo Chemical Industry Co., Ltd.) and 5.2 g of 2,2,3,3,4,4,5,5-octafluoro-1,6-hexanediol (manufactured by Tokyo Chemical Industry Co., Ltd.) were added thereto, and the mixture was reacted at 45° C. for 10 hours. After the reaction, the mixture was cooled to room temperature, 300 mL of ethyl acetate was added thereto, the mixture was washed twice with 200 mL of water, washed with 200 mL of a saturated aqueous sodium chloride solution, and dried over sodium sulfate, and then while filtering with a filter paper, the mixture was transferred to an eggplant-shaped flask and concentrated using an evaporator. This concentrate was dissolved in 30 mL of tetrahydrofuran, poured into 500 mL of water, filtered, and vacuum-dried at 40° C. for 8 hours to obtain 9.8 g of a polyester (PE-4). The weight-average molecular weight and the dispersity (Mw/Mn) of the polyester (PE-4) were 11,400 and 2.08, respectively.

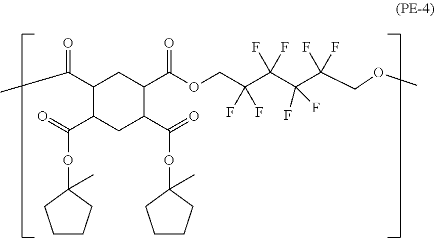

<Synthesis of (PE-5)>

5.2 g of 2,2,3,3,4,4,5,5-octafluoro-1,6-hexanediol (manufactured by Tokyo Chemical Industry Co., Ltd.), 4.48 g of 1,2,4,5-cyclohexanetetracarboxylic dianhydride (manufactured by Tokyo Chemical Industry Co., Ltd.), 0.32 g of N,N-dimethylaminopyridine (manufactured by Wako Pure Chemical Industries, Ltd.), 3.32 g of pyridine (manufactured by Wako Pure Chemical Industries, Ltd.), and 18.0 g of super-dehydrated tetrahydrofuran were weighed into a three-neck flask equipped with a condenser and a stirrer, stirred at room temperature, and then stirred at 60° C. for 8 hours. 20 g of tetrahydrofuran was added thereto and dissolved. 300 mL of water and 100 mL of 0.5 mol/L aqueous hydrochloric acid were added thereto and the mixture was filtered. The filtrate was recovered, dissolved in 30 mL of tetrahydrofuran, poured into 500 mL of water, filtered, washed with water, and dried at 40° C. for 1 day to obtain 8.2 g of (PE-5A) which is a polyester raw material. The weight-average molecular weight of (PE-5A) was 12,500.

8.2 g of (PE-5A), 0.24 g of N,N-dimethylaminopyridine (manufactured by Wako Pure Chemical Industries, Ltd.), and 22.2 g of super-dehydrated tetrahydrofuran were weighed and dissolved at 45° C. under stirring. Subsequently, 8.4 g of 1-(3-dimethylaminopropyl)-3-ethylcarbodiimide hydrochloride (manufactured by Tokyo Chemical Industry Co., Ltd.) and 6.0 g of a compound-A (manufactured by Tokyo Chemical Industry Co., Ltd.) were added thereto, and the mixture was reacted at 45° C. for 10 hours. After the reaction, the mixture was cooled to room temperature, 300 mL of ethyl acetate was added thereto, the mixture was washed twice with 200 mL of water, washed with 200 mL of a saturated aqueous sodium chloride solution, and dried over sodium sulfate, and then while filtering with a filter paper, the mixture was transferred to an eggplant-shaped flask and concentrated using an evaporator. This concentrate was dissolved in 30 mL of tetrahydrofuran, poured into 500 mL of water, filtered, and vacuum-dried at 40° C. for 8 hours to obtain 7.8 g of a polyester (PE-5). The weight-average molecular weight and the dispersity (Mw/Mn) of the polyester (PE-5) were 13,800 and 2.24, respectively.

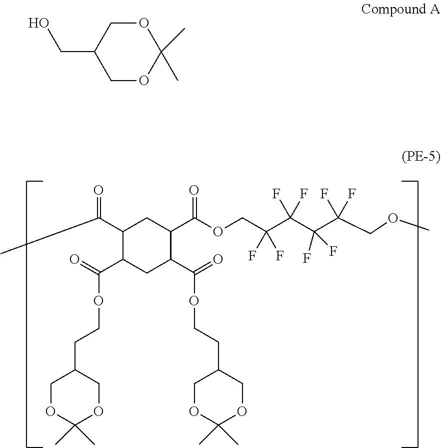

<Synthesis of (PE-6)>

2.92 g of 2,5-dimethyl-2,5-hexanediol (manufactured by Tokyo Chemical Industry Co., Ltd.) and 30.0 g of super-dehydrated tetrahydrofuran were weighed into a flask purged with nitrogen, dissolved, and cooled to −78° C. 18.0 g of butyllithium (an about 15%-by-mass solution in hexane, about 1.6 mol/L) was added dropwise thereto over 1 hour. After the dropwise addition, 1.2.4.5-cyclohexanetetracarboxylic dianhydride 4.48 g (manufactured by Tokyo Chemical Industry Co., Ltd.) was added thereto, and the mixture was stirred for 30 minutes, then stirred at 0° C. for 1 hour, and stirred at room temperature for 8 hours. 20 g of tetrahydrofuran was added thereto and dissolved. This mixture was poured into 300 mL of water and filtered. The filtrate was recovered, dissolved in 30 mL of tetrahydrofuran, poured into 500 mL of water, filtered, washed with water, and dried at 40° C. for 1 day to obtain 9.2 g of a polyester (PE-6A). The weight-average molecular weight and the dispersity (Mw/Mn) of the polyester (PE-6A) were 10,500 and 1.97, respectively.

9.2 g of (PE-6A), 0.24 g of N,N-dimethylaminopyridine (manufactured by Wako Pure Chemical Industries, Ltd.), 2.76 g of potassium carbonate, and 30.0 g of super-dehydrated N-methylpyrrolidone were weighed and stirred at 45° C. Subsequently, 6.4 g of a compound-B and 4.4 g of a compound-C were added thereto and the mixture was reacted at 60° C. for 10 hours. After the reaction, the mixture was cooled to room temperature, 300 mL of ethyl acetate was added thereto, washed with 200 mL of water, and then washed with 100 mL of 0.01 mol/L aqueous hydrochloric acid, with 300 mL of water, and then with 200 mL of a saturated aqueous sodium chloride solution, and dried with sodium sulfate, and then while filtering with a filter paper, the mixture was transferred to an eggplant-shaped flask and concentrated using an evaporator. This concentrate was dissolved in 30 mL of tetrahydrofuran, poured into 500 mL of water, filtered, and vacuum-dried at 40° C. for 8 hours to obtain 12.3 g of a polyester (PE-6). The weight-average molecular weight and the dispersity (Mw/Mn) of the polyester (PE-6) were 14,700 and 2.21, respectively.

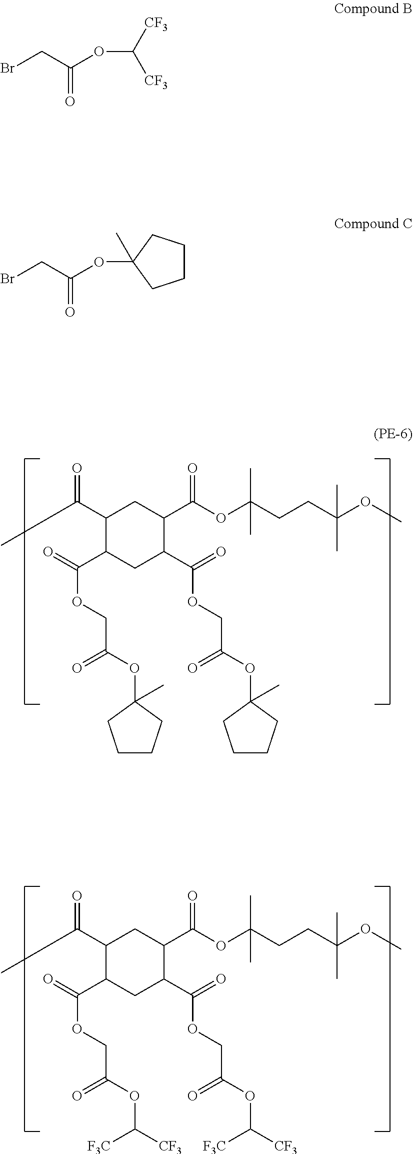

<Synthesis of (R-1A)>

Monomers (a) and (b) were used as monomers in a three-neck flask equipped with a condenser and a stirrer, the mixture was mixed so that a molar ratio (monomer (a):monomer (b)) was adjusted to 75:25, and methyl isobutyl ketone was added thereto in the amount of 1.2 mass-times the total amount of the monomers to obtain a solution. Azobis(2,4-dimethylvaleronitrile) as an initiator was added to this solution in an amount of 3% by mole with respect to the total amount of the monomers, and the mixture was heated at 70° C. for about 5 hours. The obtained reaction mixture was poured into a large amount of a methanol/water mixed solvent to precipitate a resin, and this resin was filtered to obtain (R-1A) having a weight-average molecular weight of 12,000.

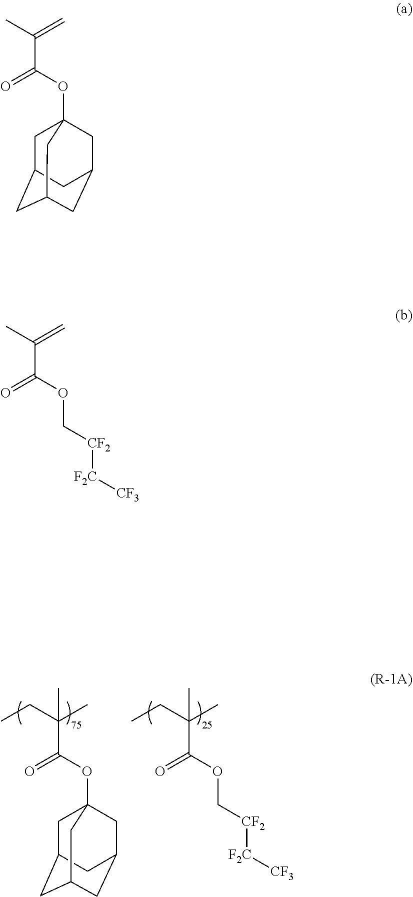

<Synthesis of (R-2A)>

5.2 g of 2,2,3,3,4,4,5,5-octafluoro-1,6-hexanediol (manufactured by Tokyo Chemical Industry Co., Ltd.), 0.32 g of N,N-dimethylaminopyridine (manufactured by Wako Pure Chemical Industries, Ltd.), 3.32 g of pyridine (manufactured by Wako Pure Chemical Industries, Ltd.), and 16.0 g of super-dehydrated tetrahydrofuran were weighed into a three-neck flask equipped with a condenser and a stirrer, and stirred at room temperature. Subsequently, 3.38 g of dimethylmalonyl dichloride (manufactured by Tokyo Chemical Industry Co., Ltd.) was added thereto, and the mixture was reacted at room temperature for 2 hours and then stirred at 45° C. for 8 hours. The mixture was transferred to a separatory funnel, 300 mL of ethyl acetate was added thereto, washed with 100 mL of water, and then washed with 100 mL of 0.5 mol/L aqueous hydrochloric acid, with 100 mL of water, and then with 200 mL of a saturated aqueous sodium chloride solution, and dried with sodium sulfate, and then while filtering with a filter paper, the mixture was transferred to an eggplant-shaped flask and concentrated using an evaporator to obtain 6.9 g of (R-2A). The weight-average molecular weight and the dispersity (Mw/Mn) of (R-2A) were 13,300 and 2.31, respectively.

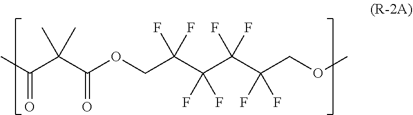

[Preparation and Coating of Coating Liquid of Resist Composition]

The respective components shown in Table 1 below were dissolved in a solvent shown in Table 1 to prepare a solution having a solid content concentration of 4% by mass, and the solution was filtered through a polyethylene filter having a pore size of 0.05 μm to obtain a resist composition of each of Examples and Comparative Examples.

In addition, the amounts of the respective components used are shown in Table 1. The resin (A) was used in an amount of 1 g, and the additive polymer, the photoacid generator, the basic compound, the surfactant, and the solvent to be added were used in the amounts (mg) described in Table 1.

An organic antireflection coating agent ARC29SR (manufactured by Brewer Science, Inc.) was applied onto a silicon wafer and baked at 205° C. for 60 seconds to form an antireflection film having a film thickness of 98 nm, and the resist composition of each of Examples and Comparative Examples shown in Table 1 below was applied thereonto and baked at 100° C. for 60 seconds to form a resist film having a film thickness of 90 nm.

(2) ArF Exposure and Development

The obtained wafer was exposed through a 6% halftone mask having a 1:1 line-and-space pattern with a line width of 100 nm, using an ArF excimer laser liquid immersion scanner (XT1700i, manufactured by ASML, NA 1.20, C-Quad, outer sigma: 0.730, inner sigma: 0.630, XY deflection). Ultrapure water was used as the immersion liquid. Thereafter, after heating at 120° C. for 60 seconds, the wafer was developed with an aqueous tetramethylammonium hydroxide solution (2.38% by mass) for 30 seconds, rinsed with pure water, and then spin-dried to obtain a resist pattern.

(3) Evaluation

Using a scanning electron microscope (S-9220 manufactured by Hitachi, Ltd.), the obtained resist pattern was evaluated for development defects and LWR by the following methods. The dynamic receding contact angles (DRCA) before exposure and after development were measured by the following method. The results are shown in Table 1 below.

[LWR]

The resist pattern manufactured above was observed with a scanning electron microscope (S-9220, manufactured by Hitachi, Ltd.); with respect to the range of 2 μm edge in the longitudinal direction of the line pattern, the distance from the reference line where the edge should be present was measured at 50 points; and the standard deviation was determined and 3σ was computed. A smaller value thereof indicates better performance.

[Development Defect]

Using a defect inspection device KLA2360 (trade name) manufactured by KLA Tencor Co., Ltd., the pattern (at an exposure scanning speed of 700 mm/sec) formed as described above on a silicon wafer (12-inch diameter) was measured in a random mode by setting the pixel size of the defect inspection apparatus to 0.16 μm and the threshold value to 20. The development defects extracted from a difference produced in a case of superposing pixel units on a reference image were detected and the number of development defects per unit area (pieces/cm²) was computed. Incidentally, 1 inch is 0.0254 m. A value of less than 0.2 is defined as A, a value of 0.2 or more and less than 0.5 is defined as B, a value of 0.5 or more and less than 1.0 is defined as C, and a value of 1.0 or more is defined as D. A smaller value thereof indicates better performance.

[Dynamic Receding Contact Angle (DRCA) Before Exposure]

The prepared resist composition was applied onto a silicon wafer (8-inch diameter) and baked at 120° C. for 60 seconds to form a resist film having a film thickness of 120 nm. Subsequently, the wafer was placed on a wafer stage of a contact angle meter (manufactured by Nikon Corporation). The droplet was brought into contact with the resist film while the droplet of pure water was discharged from the syringe and held. Next, the wafer stage was moved at a speed of 250 mm/sec with the syringe fixed. The receding angle of the droplet during the movement of the stage was measured, and the value at which the contact angle was stable was taken as the dynamic receding angle. The measurement of the contact angle was performed at 23±3° C. Incidentally, 1 inch is 0.0254 m.

[Dynamic Receding Contact Angle (DRCA) after Post-Exposure Baking]

The prepared resist composition was applied onto a silicon wafer (8-inch diameter) and baked at 120° C. for 60 seconds to form a resist film having a film thickness of 120 nm. The formed resist film was exposed using an ArF excimer laser liquid immersion scanner (manufactured by ASML; XT1700i, NA1.20, C-Quad, outer sigma 0.730, inner sigma 0.630, XY deflection). Thereafter, baking was performed at 120° C. for 60 seconds to obtain a resist film having a film thickness of 120 nm. Subsequently, the wafer was placed on a wafer stage of a contact angle meter (manufactured by Nikon Corporation). The droplet was brought into contact with the resist film while the droplet of pure water was discharged from the syringe and held. Next, the wafer stage was moved at a speed of 250 mm/sec with the syringe fixed. The receding angle of the droplet during the movement of the stage was measured, and the value at which the contact angle was stable was taken as the dynamic receding angle. The measurement of the contact angle was performed at 23±3° C.

<Synthesis Example: Synthesis of Resin (A-1)>

Under a nitrogen stream, 8.6 g of cyclohexanone was placed in a three-neck flask and heated to 80° C. 9.8 g of 2-adamantyl isopropyl methacrylate, 4.4 g of dihydroxyadamantyl methacrylate, 8.9 g of norbornane lactone methacrylate, and a solution in which a polymerization initiator V-601 (manufactured by Wako Pure Chemical Industries, Ltd.) was dissolved in 79 g of cyclohexanone to a concentration of 8% by mole with respect to the monomers were added dropwise thereto over 6 hours. After the completion of the dropwise addition, the reaction was further performed at 80° C. for 2 hours. The reaction solution was left to be cooled and then added dropwise to a mixed solution of 800 mL of hexane/200 mL of ethyl acetate over 20 minutes, and the precipitated powder was collected by filtration and dried to obtain 19 g of a resin (A-1). The weight-average molecular weight in terms of standard polystyrene and the dispersity (Mw/Mn) of the obtained resin were 8,800 and 1.9, respectively.

In a similar manner, another resin (A) shown below was synthesized.

The structures, the weight-average molecular weights (Mw), and the dispersities (Mw/Mn) of the resin (A) used in Examples are shown below. The ratio of the repeating units in each resin is a molar ratio.

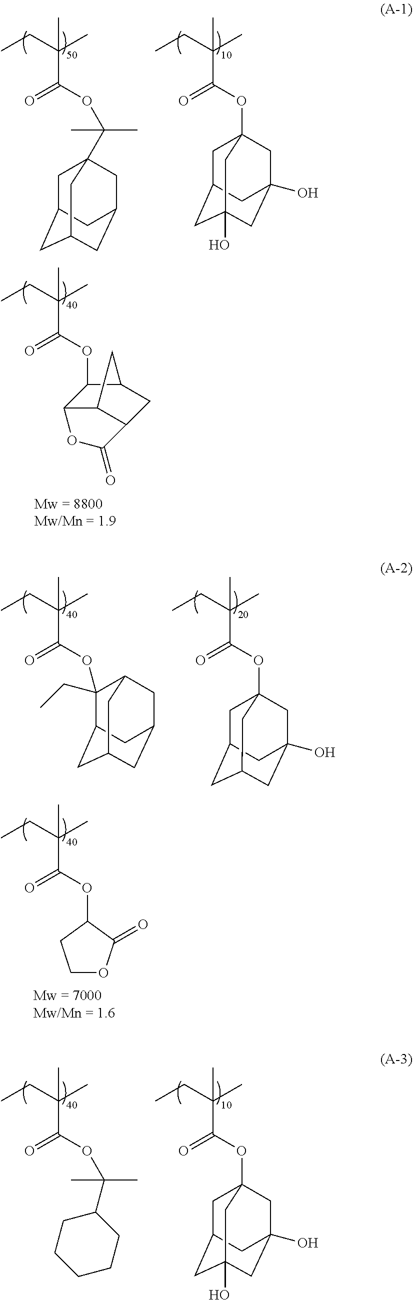

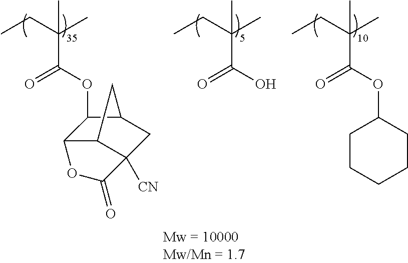

The photoacid generator used is as follows.

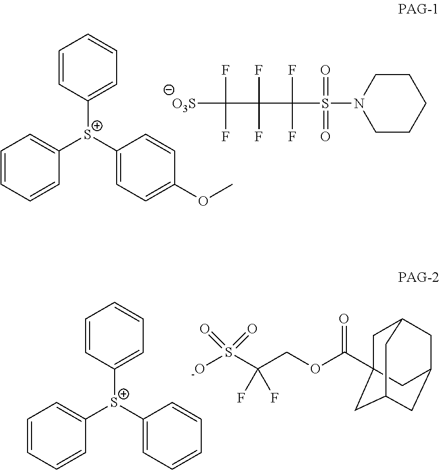

The basic compounds used are as follows.

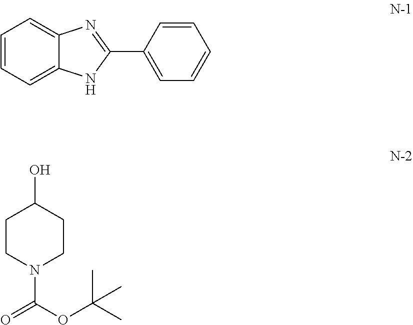

The surfactants used are as follows.

W-1: MEGAFACE F176 (Dainippon Ink and Chemicals, Inc., fluorine type)

W-2: TROYSOL S-366 (manufactured by Troy Chemical Co., Ltd.)

The solvents used are as follows.

SL-2: Propylene glycol monomethyl ether acetate (PGMEA: 1-Methoxy-2-acetoxypropane)

SL-5: γ-Butyrolactone

TABLE 1

| | | | | | | | | | DRCA | DRCA after | |
|---|---|---|---|---|---|---|---|---|---|---|---|
| | | Additive | Resin | Photoacid | Basic | | | | before | post-exposure | |
| | Resist | polymer | (A) | generator | compound | Surfactant | Solvent | LWR | exposure | baking | Development |
| | composition | (mg) | (1 g) | (mg) | (mg) | (mg) | (g) | (nm) | (°) | (°) | defects |
| Example 1 | 1 | PE-1 | A-1 | PAG-2 | N-1 | W-1 | SL-2/SL-5 | 6.5 | 75 | 68 | A |
| | | 25 | | 100.0 | 80 | 1 | 26/2.9 | | | | |
| Example 2 | 2 | PE-2 | A-1 | PAG-2 | N-1 | W-1 | SL-2/SL-5 | 6.1 | 82 | 62 | A |
| | | 25 | | 100.0 | 70 | 0.5 | 26/2.9 | | | | |
| Example 3 | 3 | PE-2 | A-1 | PAG-1 | N-2 | W-2 | SL-2/SL-5 | 6.0 | 83 | 62 | A |
| | | 25 | | 100.0 | 100 | 1 | 26/2.9 | | | | |
| Example 4 | 4 | PE-2 | A-1 | PAG-2 | N-2 | W-1 | SL-2/SL-5 | 6.1 | 82 | 63 | A |
| | | 25 | | 100.0 | 100 | 1 | 26/2.9 | | | | |
| Example 5 | 5 | PE-3 | A-1 | PAG-1 | N-2 | W-2 | SL-2/SL-5 | 6.3 | 81 | 60 | A |
| | | 25 | | 100.0 | 100 | 0.8 | 26/2.9 | | | | |
| Example 6 | 6 | PE-3 | A-1 | PAG-1 | N-1 | W-1 | SL-2/SL-5 | 6.2 | 83 | 59 | A |
| | | 25 | | 100.0 | 100 | 1 | 26/2.9 | | | | |
| Example 7 | 7 | PE-3 | A-1 | PAG-1 | N-1 | — | SL-2/SL-5 | 6.1 | 81 | 60 | A |
| | | 25 | | 100.0 | 100 | | 26/2.9 | | | | |
| Example 8 | 8 | PE-4 | A-1 | PAG-2 | N-1 | W-1 | SL-2/SL-5 | 6.2 | 84 | 58 | A |
| | | 25 | | 100.0 | 70 | 1 | 26/2.9 | | | | |
| Example 9 | 9 | PE-4 | A-1 | PAG-2 | N-2 | — | SL-2/SL-5 | 6.0 | 84 | 58 | A |
| | | 25 | | 100.0 | 100 | | 26/2.9 | | | | |
| Example 10 | 10 | PE-4 | A-2 | PAG-2 | N-1 | W-1 | SL-2/SL-5 | 6.4 | 86 | 57 | A |
| | | 25 | | 100.0 | 100 | 1 | 26/2.9 | | | | |
| Example 11 | 11 | PE-4 | A-3 | PAG-2 | N-1 | W-1 | SL-2/SL-5 | 6.3 | 85 | 56 | A |
| | | 25 | | 100.0 | 100 | 1 | 26/2.9 | | | | |
| Example 12 | 12 | PE-5 | A-1 | PAG-1 | N-1 | W-1 | SL-2/SL-5 | 6.2 | 80 | 63 | A |
| | | 25 | | 100.0 | 100 | 0.5 | 26/2.9 | | | | |
| Example 13 | 13 | PE-6 | A-1 | PAG-2 | N-2 | W-1 | SL-2/SL-5 | 6.1 | 85 | 57 | A |
| | | 25 | | 100.0 | 100 | 1 | 26/2.9 | | | | |
| Comparative | R1 | R-1A | A-1 | PAG-1 | N-1 | W-1 | SL-2/SL-5 | 6.8 | 69 | 68 | C |
| Example 1 | | 25 | | 100.0 | 100 | 1 | 26/2.9 | | | | |
| Comparative | R2 | R-1A | A-1 | PAG-1 | N-1 | W-1 | SL-2/SL-5 | 8.5 | 75 | 73 | D |
| Example 2 | | 80 | | 100.0 | 100 | 1 | 26/2.9 | | | | |
| Comparative | R3 | R-2A | A-1 | PAG-1 | N-1 | W-1 | SL-2/SL-5 | 7.2 | 81 | 78 | B |
| Example 3 | | 20 | | 100.0 | 100 | 1 | 26/2.9 | | | | |

As seen from Table 1, in Examples 1 to 13 in which the polyester (B) of the embodiment of the present invention was used as the additive polymer, a high DRCA before exposure was exhibited, the development defects decreased, the LWR performance was excellent, as compared with Comparative Examples 1 and 2 in which an acrylic fluorine-containing resin was used as the additive polymer. In addition, as compared to Comparative Example 3 in which a polyester having no acid-decomposable group was used as the additive polymer, the DRCA of the film after post-exposure baking was small, the hydrophilicity was excellent, the development defects decreased, and the LWR performance was excellent.

What is claimed is:

1. An actinic ray-sensitive or radiation-sensitive resin composition comprising:
(A) a resin having a group that decomposes by the action of an acid to increase a polarity;
(B) a polyester having an acid-decomposable group; and
(C) a photoacid generator.

2. The actinic ray-sensitive or radiation-sensitive resin composition according to claim 1,
wherein a content of the polyester (B) is from 0.1% by mass to 15% by mass with respect to a total solid content of the actinic ray-sensitive or radiation-sensitive resin composition.

3. The actinic ray-sensitive or radiation-sensitive resin composition according to claim 1,
wherein the polyester (B) has at least one group represented by any of General Formulae (RZ-1) to (RZ-4), 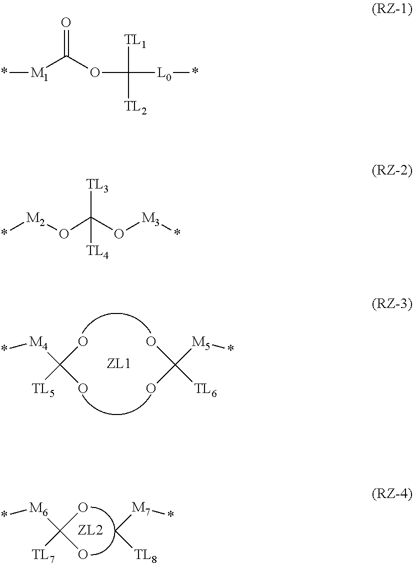
in General Formula (RZ-1), M₁ represents a single bond or a divalent linking group, TL₁ and TL₂ each independently represent a hydrogen atom, an alkyl group, a cycloalkyl group, an aryl group, or a halogen atom, TL₁ and TL₂ may be bonded to each other to form a ring, L₀ represents a single bond or an alkylene group, L₀ and any one of TL₁ or TL₂ may be bonded to each other to form a ring, and * represents a bonding position,
in General Formula (RZ-2), M₂ and M₃ each independently represent a single bond or a divalent linking group, TL₃ and TL₄ each independently represent a hydrogen atom, an alkyl group, a cycloalkyl group, or an aryl group, TL₃ and TL₄ may be bonded to each other to form a ring, and * represents a bonding position,
in General Formula (RZ-3), M₄ and M₅ each independently represent a single bond or a divalent linking group, TL₅ and TL₆ each independently represent a hydrogen atom, an alkyl group, a cycloalkyl group, an aryl group, or a halogen atom, ZL1 represents a ring structure, ZL1 may represent a spirocyclic structure, and * represents a bonding position, and
in General Formula (RZ-4), M₆ and M₇ each independently represent a single bond or a divalent linking group, TL₇ and TL₈ each independently represent a hydrogen atom, an alkyl group, a cycloalkyl group, an aryl group, or a halogen atom, ZL2 represents a ring structure, ZL2 may represent a spirocyclic structure, and * represents a bonding position.

4. The actinic ray-sensitive or radiation-sensitive resin composition according to claim 1,
wherein the polyester (B) has at least one group represented by any of General Formulae (QZ-1) to (QZ-4), 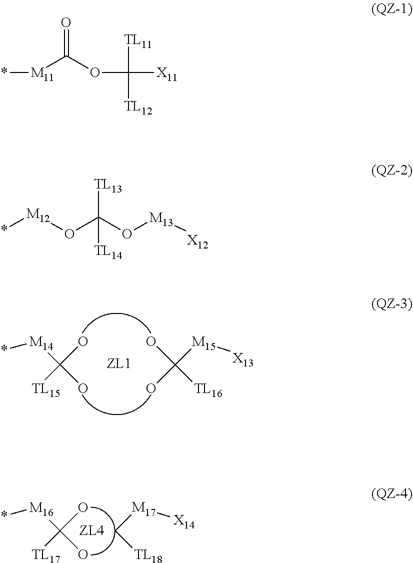
in General Formula (QZ-1), M₁₁ represents a single bond or a divalent linking group, TL₁₁ and TL₁₂ each independently represent a hydrogen atom, an alkyl group, a cycloalkyl group, an aryl group, or a halogen atom, TL₁₁ and TL₁₂ may be bonded to each other to form a ring, X₁₁ represents a hydrogen atom, a halogen atom, or a monovalent organic group, X₁₁ may be bonded to at least one of TL₁₁ or TL₁₂ to form a ring, and * represents a bonding position,
in General Formula (QZ-2), M₁₂ and M₁₃ each independently represent a single bond or a divalent linking group, TL₁₃ and TL₁₄ each independently represent a hydrogen atom, an alkyl group, a cycloalkyl group, or an aryl group, TL₁₃ and TL₁₄ may be bonded to each other to form a ring, X₁₂ represents a hydrogen atom, a halogen atom, or a monovalent organic group, X₁₂ may be bonded to at least one of TL₁₃ or TL₁₄ to form a ring, and * represents a bonding position,
in General Formula (QZ-3), M₁₄ and M₁₅ each independently represent a single bond or a divalent linking group, TL₁₅ and TL₁₆ each independently represent a hydrogen atom, an alkyl group, a cycloalkyl group, an aryl group, or a halogen atom, ZL3 represents a ring structure, ZL3 may represent a spirocyclic structure, X₁₃ represents a hydrogen atom, a halogen atom, or a monovalent organic group, and * represents a bonding position, and
in General Formula (QZ-4), M₁₆ and M₁₇ each independently represent a single bond or a divalent linking group, TL₁₇ and TL₁₈ each independently represent a hydrogen atom, an alkyl group, a cycloalkyl group, an aryl group, or a halogen atom, ZL4 represents a ring structure, ZL4 may represent a spirocyclic structure, X₁₄ represents a hydrogen atom, a halogen atom, or a monovalent organic group, and * represents a bonding position.

5. The actinic ray-sensitive or radiation-sensitive resin composition according to claim 1,
wherein the polyester (B) has a group represented by General Formula (EZ-1) in a side chain, 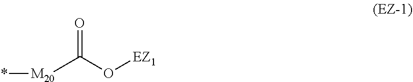
in General Formula (EZ-1), M₂₀ represents a single bond or a divalent linking group, and EZ₁ represents a monovalent organic group having an electron-withdrawing property.

6. The actinic ray-sensitive or radiation-sensitive resin composition according to claim 1,
wherein the polyester (B) is represented by General Formula (1), 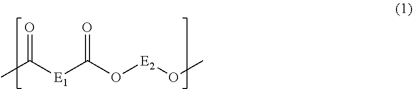
in General Formula (1), E₁ and E₂ each independently represent a chained aliphatic group which may include a heteroatom, an alicyclic group which may include a heteroatom, an aromatic group, or a group formed by combination thereof.

7. The actinic ray-sensitive or radiation-sensitive resin composition according to claim 6,
wherein E₁ and E₂ in General Formula (1) are each independently a group represented by any of General Formulae (1a) to (1e), 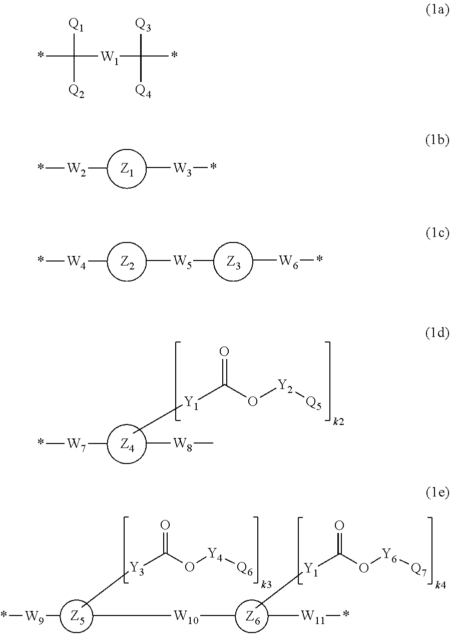
in General Formula (1a), Q₁ to Q₄ each independently represent a hydrogen atom, a halogen atom, or an alkyl group, and W₁ represents a single bond, an alkylene group, or a cycloalkylene group,
in General Formula (1b), W₂ and W₃ each independently represent a single bond, an alkylene group, or a cycloalkylene group, and Z₁ represents a cycloalkylene group, a spirocyclic group which may include a heteroatom, or an arylene group,
in General Formula (1c), W₄, W₅, and W₆ each independently represent a single bond, an alkylene group, or a cycloalkylene group, and Z₂ and Z₃ each independently represent a cycloalkylene group, a spirocyclic group which may include a heteroatom, or an arylene group,
in General Formula (1d), W₇ and W₈ each independently represent a single bond, an alkylene group, or a cycloalkylene group, Z₄ represents a cycloalkylene group, a spirocyclic group which may include a heteroatom, or an arylene group, Y₁ and Y₂ each independently represent a single bond or a divalent linking group, Q₅ represents a hydrogen atom, an alkyl group, a cycloalkyl group, or an aryl group, k2 represents an integer of 1 or more, and in a case where k2 represents an integer of 2 or more, a plurality of Y₁'s, a plurality of Y₂'s, and a plurality of Q₅'s may be the same as or different from each other, and
in General Formula (1e), W₉, W₁₀, and W₁₁ each independently represent a single bond, an alkylene group, or a cycloalkylene group, Z₅ and Z₆ each independently represent a cycloalkylene group, a spirocyclic group which may include a heteroatom, or an arylene group, Y₃, Y₄, Y₅, and Y₆ each independently represent a single bond or a divalent linking group, Q₆ and Q₇ each independently represent a hydrogen atom, an alkyl group, a cycloalkyl group, or an aryl group, k3 and k4 each independently represent an integer of 1 or more, in a case where k3 represents an integer of 2 or more, a plurality of Y₃'s, a plurality of Y₄'s, and a plurality of Q₆'s may be the same as or different from each other, and in a case where k4 represents an integer of 2 or more, a plurality of Y₅'s, a plurality of Y₆'s, and a plurality of Q₇'s may be the same as or different from each other.

8. The actinic ray-sensitive or radiation-sensitive resin composition according to claim 1,
wherein the polyester (B) contains a fluorine atom.

9. An actinic ray-sensitive or radiation-sensitive film formed of the actinic ray-sensitive or radiation-sensitive resin composition according to claim 1.

10. A pattern forming method comprising:
forming an actinic ray-sensitive or radiation-sensitive film with the actinic ray-sensitive or radiation-sensitive resin composition according to claim 1;
irradiating the actinic ray-sensitive or radiation-sensitive film with actinic rays or radiation; and
developing the actinic ray-sensitive or radiation-sensitive film irradiated with the actinic rays or radiation using a developer.

11. The pattern forming method according to claim 10,
wherein the developer is an alkali developer or a developer including an organic solvent.

12. A method for manufacturing an electronic device, comprising the pattern forming method according to claim 10.

13. A polyester comprising at least one group represented by any of General Formulae (RZ-1) to (RZ-4), 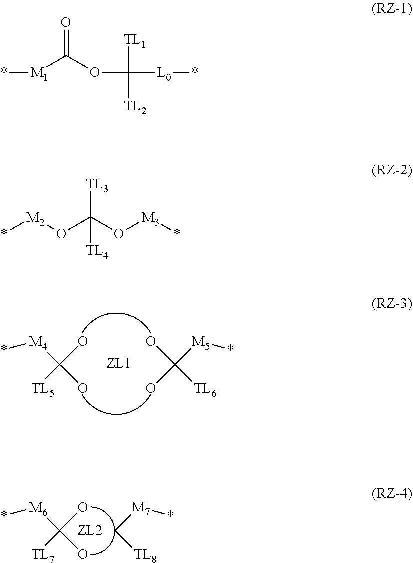
in General Formula (RZ-1), M₁ represents an oxygen atom, CR^{Z1}R^{Z2}, and or NR^{Z3}, and R^{Z1}, R^{Z2}, and R^{Z3} each independently represent a hydrogen atom, an alkyl group, or a halogen atom, R^{Z1} and R^{Z2} may be bonded to each other to form a ring, TL₁ and TL₂ each independently represent a hydrogen atom, an alkyl group, a cycloalkyl group, an aryl group, or a halogen atom, TL₁ and TL₂ may be bonded to each other to form a ring, L₀ represents a single bond or an alkylene group, L₀ and any one of TL₁ or TL₂ may be bonded to each other to form a ring, and * represents a bonding position,
in General Formula (RZ-2), M₂ and M₃ each independently represent a single bond or a divalent linking group, TL₃ and TL₄ each independently represent a hydrogen atom, an alkyl group, a cycloalkyl group, or an aryl group, TL₃ and TL₄ may be bonded to each other to form a ring, and * represents a bonding position,
in General Formula (RZ-3), M₄ and M₅ each independently represent a single bond or a divalent linking group, TL₅ and TL₆ each independently represent a hydrogen atom, an alkyl group, a cycloalkyl group, an aryl group, or a halogen atom, ZL1 represents a ring structure, ZL1 may represent a spirocyclic structure, and * represents a bonding position, and
in General Formula (RZ-4), M₆ and M₇ each independently represent a single bond or a divalent linking group, TL₇ and TL₈ each independently represent a hydrogen atom, an alkyl group, a cycloalkyl group, an aryl group, or a halogen atom, ZL2 represents a ring structure, ZL2 may represent a spirocyclic structure, and * represents a bonding position.

14. A polyester having at least one group represented by any of General Formulae (QZ-1) to (QZ-4), 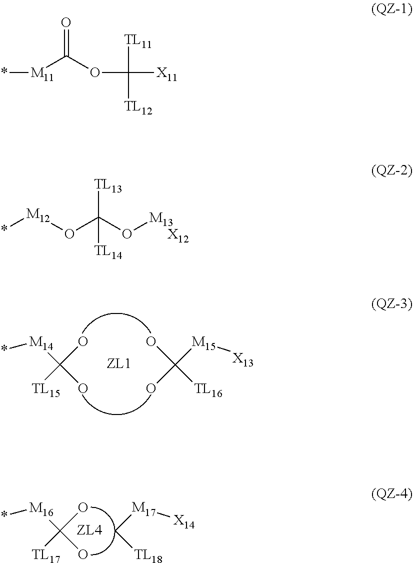
in General Formula (QZ-1), X₁₀ represents a single bond or a divalent linking group, M₁₁ represents an oxygen atom, CR^{Z4}R_{Z5}, or NR^{Z6}, and R^{Z4}, R^{Z5}, and R^{Z6} each independently represent a hydrogen atom, an alkyl group, or a halogen atom, R^{Z4} and R^{Z5} may be bonded to each other to form a ring, TL₁₁ and TL₁₂ each independently represent a hydrogen atom, an alkyl group, a cycloalkyl group, an aryl group, or a halogen atom, TL₁₁ and TL₁₂ may be bonded to each other to form a ring, X₁₁ represents a hydrogen atom, a halogen atom, or a monovalent organic group, X₁₁ may be bonded to at least one of TL₁₁ or TL₁₂ to form a ring, and * represents a bonding position,
in General Formula (QZ-2), M₁₂ and M₁₃ each independently represent a single bond or a divalent linking group, TL₁₃ and TL₁₄ each independently represent a hydrogen atom, an alkyl group, a cycloalkyl group, or an aryl group, TL₁₃ and TL₁₄ may be bonded to each other to form a ring, X₁₂ represents a hydrogen atom, a halogen atom, or a monovalent organic group, X₁₂ may be bonded to at least one of TL₁₃ or TL₁₄ to form a ring, and * represents a bonding position,
in General Formula (QZ-3), M₁₄ and M₁₅ each independently represent a single bond or a divalent linking group, T₁₅ and TL₁₆ each independently represent a hydrogen atom, an alkyl group, a cycloalkyl group, an aryl group, or a halogen atom, ZL3 represents a ring structure, ZL3 may represent a spirocyclic structure, X₁₃ represents a hydrogen atom, a halogen atom, or a monovalent organic group, and * represents a bonding position, and
in General Formula (QZ-4), M₁₆ and M₁₇ each independently represent a single bond or a divalent linking group, TL₁₇ and TL₁₈ each independently represent a hydrogen atom, an alkyl group, a cycloalkyl group, an aryl group, or a halogen atom, ZL4 represents a ring structure, ZL4 may represent a spirocyclic structure, X₁₄ represents a hydrogen atom, a halogen atom, or a monovalent organic group, and * represents a bonding position.

15. A polyester having a group represented by General Formula (EZ-1) in a side chain, 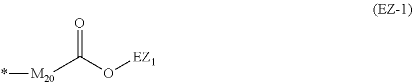
in General Formula (EZ-1), M₂₀ represents a single bond or a divalent linking group, and EZ₁ represents a monovalent organic group having an electron-withdrawing property.
